(19) United States
(12) Patent Application Publication
(10) Pub. No.: US 2019/0245155 A1
(43) Pub. Date: Aug. 8, 2019

(54) METHODS, PRODUCTS, AND SYSTEMS RELATING TO MAKING, PROVIDING, AND USING NANOCRYSTALLINE CELLULOSE SUPERLATTICE SOLAR CELLS TO PRODUCE ELECTRICITY

(71) Applicant: Stephan Heath, Littleton, CO (US)

(72) Inventor: Stephan Heath, Littleton, CO (US)

(21) Appl. No.: 16/256,874

(22) Filed: Jan. 24, 2019

Related U.S. Application Data
(60) Provisional application No. 62/621,552, filed on Jan. 24, 2018.

(51) Int. Cl. H01L 51/00

(52) U.S. Cl. CPC H01L 51/0093; H01L 51/004; H01L 51/4246; H01L 51/0076; H01L 51/0096; H01L 51/0048

(57) ABSTRACT

Nanocrystalline superlattice solar cells including nanocrystalline cellulose (NCC) that overcomes one or more of the problems existing in the art are provided including nanocrystalline superlattice solar cells that will add one or more layers to the nanocrystalline solar cell to produce electricity that can be used for solar energy devices, solar energy-storage systems, applications, products and services utilizing NCC in the construction of one or more of the nanocrystalline superlattice layers of the solar cell.

### FIELD

The present subject matter relates to methods, apparatus, products, and/or systems relating to making, providing and using one or more layers of the nanocrystalline superlattice solar cells including nanocrystalline cellulose (NCC) in combination with other nanocrystalline materials to produce electricity.

### BACKGROUND

The power output of the Sun that reaches the Earth could provide as much as ten thousand times more energy than the combined output of all the commercial power plants on the planet, according to the National Academy of Engineering. The problem is how to harvest more of that energy from the Sun. Today's commercial solar cells, usually made from silicon, are still relatively expensive to produce and they generally manage to harness only a fraction of the sunlight that strikes them. The efficiency of silicon solar cells is typically limited to around 20% to 25%. The rest of the sunlight that strikes a silicon solar cell is wasted as unusable energy. This contributes to the high cost of solar-generated electricity from silicon solar cells compared to power generated by conventional fossil-fuel-burning plants.

A new solar cell technology can reduce the amount of sunlight that is reflected away from a new type of solar cell and wasted as unusable energy. This new solar cell nanotechnology material is known as nanocrystalline cellulose (NCC) that can be added to one or more layers to the nanocrystalline superlattice solar cell including nanocrystalline cellulose (NCC) in combination with other nanocrystalline materials to produce electricity.

### SUMMARY

Alternative optional embodiments of the present subject matter can provide a new and improved nanocrystalline superlattice solar cells including nanocrystalline cellulose (NCC) that overcomes one or more of the problems existing in the art. More specifically, embodiments of the present subject matter provide new and improved nanocrystalline superlattice solar cells that will add one or more layers to the nanocrystalline solar cell to produce electricity that can be used for solar energy devices, solar energy storage systems, applications, products and services utilizing NCC in the construction of one or more of the nanocrystalline superlattice layers of the solar cell.

In one embodiment the nanocrystalline superlattice solar cells can include a substrate on which an n+ layer is deposited. On top of this n+ doped layer can be deposited a superlattice having alternating amorphous nanocrystalline (NC) cellulose, nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures. On top of the nanocrystalline superlattice is deposited a P-doped nanocrystalline or amorphous layer to complete the basic solar cell structure. The nanocrystalline solar cell is completed by depositing a transparent conductor on the top p+ layer.

In one embodiment the nanocrystalline superlattice optionally includes alternating layers of amorphous silicon, polycrystalline, copper indium diselenide, cadmium telluride, gallium arsenide, gallium phosphide, carbon solar cells. (a-(Si,alloy):H) nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, nanocrystalline (NC) polymers structures and/or nanocrystalline (NC) silicon. The percent percentage content of metal alloy in the amorphous layer can optionally be held constant across the amorphous layer, or can optionally be graded with an increasing metal allow content as the amorphous layer is deposited. The grading can optionally be continuous or discontinuous, and can optionally vary from a starting % of metal alloys to an ending % of metal alloys across the amorphous layer. The starting metal alloy content can optionally be 0% or greater, and the ending percentage can optionally be 100% or less. The number of alternating layers can optionally vary as desired, and typically w ill be 50 layers or less. In one embodiment the first amorphous layer of the nanocrystalline superlattice is thinner than subsequent amorphous layers and does not contain any metal alloy content whatsoever.

Other aspects, objectives and advantages of the present subject matter will become more apparent from the following detailed description when taken in conjunction with the accompanying drawings. Alternative embodiments of the present subject matter can optionally include a method for producing nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity that include a combination of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures.

The method can optionally include one or more of:
a method for producing nanocrystalline superlattice solar cells for nanocrystalline (NC) solar energy devices, solar energy storage systems, applications, products or services, the NC solar energy devices, solar energy storage systems, applications, products and services configured to produce electricity to electrical current, the NC solar energy devices, solar energy storage systems, applications, products and services including a combination of at least two of: nanocrystalline cellulose (NCC), nanocrystalline (NC) materials, nanocrystalline (NC) carbon, nanocrystalline (NC) carbon nanotubes, nanocrystalline (NC) metals and alloys, nanocrystalline (NC) polymers and/or nanocrystalline (NC) polymers structures, the method including:
(a) combining at least two nanocrystalline (NC) components with at least one substrate to provide an NCC substrate composition,
   wherein said NC component is selected from at least one nanocrystalline cellulose (NCC), at least one nanocrystalline (NC) material, and/or at least one nanocrystalline (NC) substrate,
   wherein one or more of said NC components is provided in at least a partially dry form; and
   wherein said NCC substrate composition includes
      (i) an NCC core structure as a central component including at least one of said NC component and optionally at least a portion of said substrate; and
      (ii) at least one branched polymer including:
         (A) at least one first polymer chain extending from said NCC core and including at least one of said at least two NC components; and
         (B) at least one second polymer chain diverting away from the first polymer chain and including at least one of said at least two NC components;
(b) processing the NCC substrate composition using at least one of vapor processing, solid state processing, liquid processing, spray pyrolysis, electrochemical deposition, gas phase deposition, and laser processing to provide a processed NCC substrate composition;
(c) combining the processed NCC substrate composition with at least two nanoparticle-based materials to form an NCC substrate product that is configured to process visible and/or UV light wavelengths for generation of electrical current when incorporated into one or more solar energy devices,
wherein the at least two nanoparticle-based materials are selected from at least two of the following nanocrystalline based: metal, non-metal, plastic, polymer, multiscale structure, thin film, ceramic, coating, perovskite, photovoltaic, photothermal or photoelectrochemical solar material, silicon crystal, carbon crystal, metal hydride, amorphous metal, silicon, polycrystalline, copper indium diselenide, cadmium telluride, gallium arsenide, gallium phosphide, carbon solar cells, perovskite solar cells, copper alloy, cobalt alloy, silver alloy, aluminum, steel, kevlar, cast iron, tungsten, chromium, titanium, indium, gallium and nitrogen, or an alloy thereof.

The method can optionally further include adding to the nanocrystalline (NC) composition at least one of a nanocrystalline (NC) plastic, polymers or nanostructure; a plastic, a form or alloy of metal, a form or alloy of nanocrystalline copper, nanocrystalline aluminum, nanocrystalline steel, kevlar, cast iron, tungsten, chromium, titanium, a fiber, or a composite, wherein the adding results in at least a 10% increase in at least one the tensile strength or hardness of the resulting nanocrystalline (NC) product material.

The method can optionally further include wherein the at least one first polymer chain or the at least one second polymer chain includes or further includes one or more monomers.

The method can optionally include one or more of:

(a) combining at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, in at least partially dry form with at least one substrate provide an NCC substrate composition including at least one branched polymer having at least a first polymer chain extending from an NCC core and at least one branch diverting away from the first polymer chain;

(b) processing the NCC substrate composition using at least one of vapor processing, solid state processing, liquid processing, spray pyrolysis, electrochemical deposition, gas phase deposition, laser processing and combining the NCC substrate composition with at least two nanoparticle-based materials, nanocrystalline metals and alloys, non-metals, synthetic metals, plastics, polymers, liquid polymers, liquid crystal polymers, liquid carbon polymers, composite gel polymers, multiscale structures, thin film, nanocrystalline ceramics, nanocrystalline coatings, perovskites, photovoltaic, photothermal and photoelectrochemical solar materials, silicon crystals, metal hydrides, amorphous metals, silicon, polycrystalline, copper indium diselenide, cadmium telluride, gallium arsenide, gallium phosphide, carbon solar cells, perovskite solar cells, copper alloy, cobalt alloy, silver alloy, aluminum, steel, kevlar, cast iron, tungsten, chromium, titanium, indium, gallium and nitrogen, or an alloy thereof to form an NCC substrate product that is configured to process visible and/or UV light wavelengths for generation of electrical current when incorporated into one or more of solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity.

The method can optionally further include adding to the nanocrystalline (NC) composition at least one of a nanocrystalline (NC) plastic, polymers or nanostructure; a plastic, a form or alloy of metal, a form or alloy of nanocrystalline copper, nanocrystalline aluminum, nanocrystalline steel, kevlar, cast iron, tungsten, chromium, titanium, a fiber, or a composite, wherein the adding results in at least a 10% increase in at least one the tensile strength or hardness of the resulting nanocrystalline (NC) product material.

Alternative embodiments of the present subject matter optionally relate to methods, apparatus, products, and/or systems relating to making or using nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity that include a combination of:
(i) one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, nanocrystalline (NC) polymers structures, and/or nanocrystalline (NC) plastics, nanocrystalline (NC) polymers or nanocrystalline (NC) nanotubes including of cellulose nanocomposites, nanomaterials, nanostructures or nanocrystalline (NC) layers that have been processed into one or more layers to the nanocrystalline solar cell including of solid, flake, particles, liquid, non-liquid, spray dried, non-spray dried, bulk, cellulose, coating applications, composite material, components, powder, paste, metalization paste, pulp, fibers, foam, gel, resin, wax, wood chips, wood pulp, bamboo pulp, bleached pulp, wood-based fibers, plant fibers, pulp fibers, extract, seeds, encapsulated, grains, tablets, or other forms, optionally with vapor processing, solid state processing, liquid processing, spray pyrolysis, electrochemical deposition, gas phase deposition, laser processing or other processing methods in combination with:
(ii) other nanocrystalline (NC) materials:
   that can optionally be combined with nanoparticles of nanocrystalline to provide for nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity using a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, nano flakes, films, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity.
(iii) nanoparticles of metals, non-metals, synthetic metals, plastics, polymers, liquid polymers, liquid crystal polymers, liquid carbon polymers, composite gel polymers, multiscale structures, thin film, nanocrystalline ceramics, nanocrystalline coatings, perovskites, photovoltaic, photothermal and photoelectrochemical solar materials, silicon crystal cells, metal hydrides, amorphous metals, silicon, polycrystalline, copper indium diselenide, cadmium telluride, gallium arsenide, gallium phosphide, carbon solar cells, perovskite solar cells, copper alloy, cobalt alloy, silver alloy, aluminum, steel, kevlar, cast iron, tungsten, chromium, titanium, mechanical alloying or other types of alloys, composite nanocrystalline (NC) coating agents, structural bulk materials, metals or elements, ultra hard nanocrystalline (NC) coating applications, solar plastic products and/or other forms of nanocrystals of cellulose materials that can optionally be combined with nanoparticles of nanocrystalline to provide nanocrystalline (NC) coating applications, compressibility and strength, corrosion resistance, nanocrystalline (NC) coating applications and thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for electricity current, higher electrical resistance, increased specific thermal capacity, thermal expansion, tensile strength or hardness, ductility & toughness, electrical properties, magnetic and chemical properties, absorption properties, catalytic properties, barrier properties, nanocrystalline cores for making nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar films, dye-sensitized solar cells, solar energy batteries, solar energy consumer products, solar powered products for the home, solar energy storage systems, solar products or solar energy devices using a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, nano flakes, films, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity.

The present subject matter can optionally provide wherein the nanocrystalline (NC) solar energy products (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity that include a combination of two or more of nanocrystalline cellulose (NCC), nanocrystalline (NC) materials, nanocrystalline (NC) carbon, nanocrystalline (NC) carbon nanotubes, nanocrystalline (NC) lay ers, nanocrystalline (NC) metals and alloys, nanocrystalline (NC) plastics, nanocrystalline (NC) polymers or nanocrystalline (NC) nanotubes including of cellulose nanocomposites, nanomaterials, nanostructures or nanocrystalline (NC) lay ers that can optionally be combined with nanocrystalline (NC) materials to produce electricity for nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar films, dye-sensitized solar cells, solar energy batteries, solar energy consumer products, solar powered products for the home, solar energy storage systems, solar products or solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar accessories or using a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, (NCC) solar crystal cells, nano flakes, films, nanoparticles, nanocomposite, nanomaterials, nanostructures or nanocrystalline (NC) layers for for electricity by creating magnetic, electric, or electromagnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity that can optionally provide:
(a) for one or more of ultra-hard nanocrystalline (NC) coating applications, fiber optic nanocrystalline (NC) coating applications, sensor coating applications, and the like;
(b) solar power without the use of semiconductors and absorption of light to produce charge separation, wherein in glass or transparent solar, the light goes into a material, then gets absorbed and creates thermal; and/or wherein the light can be shone through a material that does not conduct electricity, such as glass. The ultraviolet (UV) light traveling through a non-conductive material, the isolated magnetic properties are enhanced significantly. The glass or transparent solar panel turns UV and near infrared light into electrical current, and the like.
(c)

for one or more of microchip, biocompatible device, microfluidics, computer chips, thin film solar panels, solar glass panels, flexible solar screens, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar film, flexible solar products, flexible nano solar energy products, flexible electronic solar energy displays, flexible solar energy devices, flat panel solar powered display s, bendable solar energy batteries, solar energy consumer products, solar powered products for the home, wearable solar energy batteries, solar energy consumer products, solar powered products for the home, solar smart products, smart glass products, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar film, hand-held portable solar powered devices, solar energy devices, solar energy storage systems, applications, products and services, and the like.
(d) one or more of electronics, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar film, flexible solar products, flexible nano solar energy products, flexible electronic solar energy display s, flexible solar energy devices, solar energy batteries, solar energy consumer products, solar powered products for the home, solar magnetic data storage, solar powered telecommunication and data communication components, solar electronic applications with a higher quality energy storage capacity for use in a variety of commercial and portable solar consumer electronic products, solar energy devices, solar energy storage systems, applications, products and services, and the like;
(e) one or more of advanced reinforced coating applications, composite materials, kinetic energy penetrators, high energy density solar energy batteries, solar energy consumer products, solar powered products for the home, solar powered cell phones or other hand-held solar powered devices, solar toys, solar watches, high power solar magnets, high sensitivity sensors, electrochromic display solar energy devices, nanocrystalline (NC) coating applications, nano liquid crystal solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles coating applications, solar film materials to produce solar windows, solar powered cars, solar powered lights, solar powered gadgets, solar powered roof tiles, solar storage system, solar energy storage systems, solar panels, solar glass panels, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar powered shingles, photovoltaic solar powered shingles, solar powered roadways, solar powered roadways and/or other solar building applications, solar paint, solar paint additives cells, solar energy devices, Nano coatings, computer chips, thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, electrochromic display solar energy devices, solar energy storage systems, applications, products and services, and the like;
(f) one or more of nanoscale thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices and other surfaces can make them anti-reflective, self-cleaning, resistant to ultraviolet (UV) or infrared light, or electrically conductive;
(g) one or more of Nano-engineered materials in solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices that includes thin film solar panels, solar glass panels, high-power rechargeable solar battery systems; thermoelectric materials to produce temperature control; thin film smart solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, solar energy storage systems, applications, products and services, and the like;
(h) one or more of specialized solar paint, solar paint additives cells and sealing products; solar powered shingles, photovoltaic solar powered shingles, solar powered roadways, solar powered gadgets, solar powered roof tiles, solar materials, photovoltaic solar powered shingles, photovoltaic solar powered shingles, solar powered roadways, thin film solar windows and/or other solar building applications; nanoscale transistors that are fester, more powerful, and increasingly energy-efficient and ability to store computer's memory on a single tiny chip; displays for solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or many new solar powered devices, laptop computers, cell phones, digital cameras, and other devices incorporate nanostructured polymer films known as organic light-emitting diodes, or OLEDs. OLED screens offer brighter images in a flat format, as well as wider viewing angles, lighter weight, better picture density, lower power consumption, and longer lifetimes; other computing and electronic products include flash memory chips for solar powered iPod nanos, solar energy devices, solar energy storage systems, applications, products and services, and the like;
(i) one or more of structural components for making solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, hard chrome nanocrystalline (NC) coating applications, and the like;
(j) one or more of thin film solar panels, solar glass panels, flexible solar screens, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, flexible solar products, flexible nano solar energy products, flexible electronic solar energy displays, flexible solar energy devices, flat panel solar powered displays, bendable solar energy batteries, solar energy consumer products, solar powered products for the home, wearable solar energy batteries, solar energy consumer products, solar powered products for the home, solar smart products, smart glass products, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, hand-held portable solar powered devices, solar energy devices, solar energy storage systems, applications, products and services, and the like;
(k) one or more of nanoparticles of metals, non-metals, synthetic metals, plastics, polymers, liquid crystal polymers, liquid carbon polymers, composite gel polymers, multiscale structures, thin film, nanocrystalline ceramics, nanocrystalline coatings, perovskites, photovoltaic, photothermal and photoelectrochemical solar materials, silicon crystals, metal hydrides, amorphous metals, silicon, polycrystalline, copper indium diselenide, cadmium telluride, gallium arsenide, gallium phosphide, carbon solar cells, perovskite solar cells, copper alloy, cobalt alloy, silver alloy, aluminum, steel, Kevlar, cast iron, tungsten, chromium, titanium, mechanical alloying or other types of alloys, composite nanocrystalline (NC) coating agents, structural bulk materials, metals or elements, ultra-hard nanocrystalline (NC) coating applications, solar plastic products, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, metal replacement, solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, solar components, electronics, nanocrystalline (NC) injection molding applications, nanocrystalline (NC) applications, nanocomposites, nanomaterials, nanostructures or nanocrystalline (NC) layers, and the like;
(l) combined with nanocrystalline (NC) materials, e.g., but not limited to, one or more of plastic, nanocrystalline (NC) metals and alloys, nanocrystalline (NC) polymers and/or nanocrystalline (NC) polymers structures, glass, aluminum, steel, Kevlar, cast iron, fibers, alloys and/or other composites that can optionally increase strength and/or hardness and/or used for construction applications and multiple of other nanocrystalline (NC) applications, nanocomposites, nanomaterials, nanostructures or nanocrystalline (NC) layers;
(m) wherein the nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity optionally includes one or more polymer, liquid polymer, polyionic graphene, metal oxides, and reactive compounds, materials, compositions, films, and solar panel components;
(n) one or more thermochromic glazings, materials, and coatings can optionally be used in solar products, systems, and methods of the present subject matter, including but not limited to, compounds, materials, compositions, films, and solar panel components; and/or
(o) one or more electrically switchable polymer-dispersed liquid crystal materials, liquid carbon materials and semiconductor materials as films, coating, deposited, and composite materials, can optionally be used in solar products, systems, and methods of the present subject matter, including but not limited to, compounds, materials, compositions, coatings, films, and solar panel components.

Polymer, liquid polymer, polyionic graphene, metal oxides, and reactive compounds, materials, compositions, films, and solar panel components, can optionally be used according to the present subject matter in solar products according to the present subject matter, e.g., as disclosed and incorporated by reference herein from US patent and application numbers: U.S. Pat. No. 9,393,589; 20140242321; 20140220351; 20140218792; U.S. Pat. No. 8,689,726; 20140079922; 20140079884; 20130273242; 20130183516; 20130108832; U.S. Pat. Nos. 8,277,899; 8,234,998; 20120194819; 20120082831; 20120028005; 20110274767; 20110135888; 20110089018; 20110014366; 20100315693; 20100304150; 20100209593; 20100208349; 20100098902; 20100092377; 20100003499; 20090209665; 20090161220; 20090155545; 20090153953; 20090015908; 20080299036; 20080060302; U.S. Pat. No. 7,311,943; 20070104922; 20070054194; 20070032869; 20060234032; 20060029634; 20050025976; 20050019550; U.S. Pat. No. 6,627,175; 20030167878; 20010048975; 20010046564; U.S. Pat. Nos. 6,221,112; 5,925,228; 5,264,058; 5,091,258; 5,019,197; 4,973,511; 4,410,501; 3,978,264; 20100104810; 20090163619; 20090155545; 20090038512; 20080230752; 20080188381; 20080185498; 20080108730; 20070165903; 20070100026; 20070058260; 20060254315; 20060235086; 20060191442; 20060137601; 20030125416; 20020143073; 20020054680; U.S. Pat. Nos. 7,030,175; 7,008,567; 6,894,086; 6,782,115; 6,753,191; 6,525,136; 6,337,131; 6,299,979; 6,187,599; 6,165,389; 6,114,023; 5,932,309; 5,854,078; 5,824,733; 5,783,120; 5,711,884; 5,624,731; 5,527,386; 5,330,685; 5,281,370; 5,266,238; 5,122,905; and/or 4,833,172.

Thermochromic glazings, materials, and coatings can optionally be used in solar products, systems, and methods of the present subject matter, including but not limited to, compounds, materials, compositions, films, and solar panel components, according to the present subject matter, e.g., as disclosed and incorporated by reference herein from US patent and application numbers: U.S. Pat. No. 9,075,253; US20140268291; US20140327953; U.S. Pat. No. 9,146,408; US20140346415; U.S. Pat. Nos. 6,084,702; 7,304,008; US20040182284; U.S. Pat. Nos. 6,446,402; 6,440,592; 8,422,113; US20070048438; US20140001029; U.S. Pat. No. 8,889,219; US20120263930; US20110260123; U.S. Pat. No. 7,817,328; US20110080631; U.S. Pat. No. 8,154,788; and 9,442,313.

Electrically switchable polymer-dispersed liquid crystal materials, liquid carbon materials and semiconductor materials as films, coating, deposited, and composite materials, can optionally be used in solar products, systems, and methods of the present subject matter, including but not limited to, compounds, materials, compositions, coatings, films, and solar panel components, according to the present subject matter, e.g., as disclosed and incorporated by reference herein from US patent and application numbers: US20130118478; US20110304012; U.S. Pat. Nos. 8,767,153; 7,820,907; 7,077,984; US20110007255; US20130069197; US20070284556; US20140080040; U.S. Pat. Nos. 6,867,888; 7,583,423; 7,312,906; 7,265,882; US20140243488; U.S. Pat. Nos. 7,413,678; 9,166,073; 7,265,903; US20140021034; U.S. Pat. Nos. 6,049,366; and 7,256,915.

To satisfy the long-felt but unsolved needs identified above, at least one embodiment of the present subject matter is directed towards a method of making or using a nanocrystalline (NC) product including one or more of an NC: cellulose material, polymer, or plastic. Such a method optionally includes one or more of the steps of: providing an at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes, and adding the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes to a substrate, component, or additive in the dry or wet end of a nanocrystalline (NC) product making process, wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is substantially distributed on, near, or adjacent to the surface of the substrate. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be distributed with the use of a size press or other suitable manufacturing device component.

The method can optionally include a method for producing nanocrystalline (NC) superlattice solar cells, solar panels, solar glass, transparent solar panels, solar windows, solar tiles, doubled-sided solar panels, solar powered cars, solar powered lights, solar automotive paint solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices for for electricity that include a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, nanocrystalline (NC) carbon nanotubes, optionally including one or more:
(a) combining at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes with at least one substrate, component, or additive, in at least a partial dry form, to provide a Nanocrystalline (NC) composition, wherein the at least one NC cellulose material, polymer, or plastic, is substantially distributed on the surface of the substrate, component, or additive, and wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is a branched polymer having at least a first polymer chain extending from a nanocrystalline cellulose (NCC) core and at least one branch diverting away from the first polymer chain; and
(b) processing the nanocrystalline (NC) composition using at least vapor processing, solid state processing, liquid processing, spray pyrolysis, electrochemical deposition, gas phase deposition, laser processing or other processing methods to form a nanocrystalline (NC) product including one or more of a solid, flake, particles, liquid, non-liquid, spray dried, non-spray dried, bulk, cellulose, coating applications, composite material, components, powder, paste, metallization paste, pulp, fibers, foam, gel, resin, wax, wood chips, wood pulp, bamboo pulp, bleached pulp, wood-based fibers, plant fibers, pulp fibers, extract, seeds, encapsulated, grains, tablets or other forms wherein the nanocrystalline (NC) product reflect specific wavelengths that can optionally penetrate one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, nano flakes, films, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices.

The method can optionally further include wherein the nanocrystalline (NC) product includes a combination of two or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures.

The method can optionally further include providing the nanocrystalline (NC) product or device in one or more of: thin film solar panels, solar glass panels, flexible solar screens, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, flexible solar products, flexible nano solar energy products, flexible electronic solar energy displays, flexible solar energy devices, flat panel solar powered displays, bendable solar energy batteries, solar energy consumer products, solar powered products for the home, wearable batteries, components for solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, hand-held portable solar energy devices, solar components, solar energy batteries, solar energy consumer products, solar powered products for the home, solar magnetic data storage, solar powered telecommunication and data communication components, thin film coating applications, solar ceramic products, electrochromic display solar energy devices, nanocrystalline (NC) coating applications, nano liquid crystal solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles coating applications, solar film materials to produce solar windows, solar powered cars, solar powered lights, solar powered gadgets, solar powered roof tiles, solar storage system, solar energy storage systems, solar panels, solar glass panels, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar powered shingles, photovoltaic solar powered shingles, solar powered roadways, solar powered roadways and/or other solar building applications, solar paint, solar paint additives cells, solar energy devices, Nano coatings, computer chips, thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, electrochromic display solar energy devices, electronics, flexible solar screens, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, flexible solar products, flexible nano solar energy products, flexible electronic solar energy displays, flexible solar energy devices, flat panel solar powered displays, bendable solar energy batteries, solar energy consumer products, solar powered products for the home, wearable batteries, nanoparticles of metals, non-metals, synthetic metals, plastics, polymers, liquid polymers, liquid crystal polymers, liquid carbon polymers, composite gel polymers, multiscale structures, thin film, nanocrystalline ceramics, nanocrystalline coatings, perovskites, photovoltaic, photothermal and photoelectrochemical solar materials, silicon crystals, metal hydrides, amorphous metals, silicon, polycrystalline, copper indium diselenide, cadmium telluride, gallium arsenide, gallium phosphide, carbon solar cells, perovskite solar cells, copper alloy, cobalt alloy, silver alloy, metallic materials, metals or elements, ultra-hard nanocrystalline (NC) coating applications, solar ceramic products, solar plastic products, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, metal replacement compositions and the like.

The method can optionally further include wherein the combining step (a) further includes adding to the composition at least one material selected from a plastic, a form or alloy of metal, a form or alloy of nanocrystalline copper, solar material enhanced with nanoparticles of metal, nanocrystalline aluminum, nanocrystalline steel, Kevlar, cast iron, tungsten, chromium, titanium, mechanical alloying or other types of alloys, a fiber, or a composite, wherein the adding results in at least a 10% increase in at least one the tensile strength or hardness of the resulting nanocrystalline (NC) product material.

The method can optionally further include wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes includes at least one first branch of the at least one first polymer chain bonded to a nanocrystalline cellulose (NCC) core and the first polymer chain is made up of one or more monomers selected from one or more of:
vinyl acetate, acrylic acid, sodium acrylate, ammonium acrylate, methyl acrylate, acrylamide, acrylonitrile, N,N-di methyl acrylamide, 2-acrylamido-2-methylpropane-1-sulfonic acid, sodium 2-acrylamido-2-methylpropane-1-sulfonate, 3-acrylamidopropyl-trimethyl-ammonium chloride, diallyl dimethylammonium chloride, 2-(dimethylamino)ethyl acrylate, 2-(acryloyloxy)-N,N,N-trimethylethanaminium chloride, N,N-dimethylaminoethyl acrylate benzyl chloride quaternary salt, 2-(acryloyloxy)-N,N,N-trimethylethanaminium methyl sulfate, 2-(dimethylamino)ethyl methacrylate, 2-(methacryloyloxy)-N,N,N-trimethylethanaminium chloride, 3-(dimethylamino)propyl methacrylamide, 2-(methacryloyloxy)-N,N,N-trimethylethanaminium methyl sulfate, methacrylic acid, methacrylic anhydride, methyl methacrylate, methacryloyloxy ethyl trimethyl ammonium chloride, 3-methacrylamidopropyl-trimethyl-ammonium chloride, hexadecyl methacrylate, octadecyl methacrylate, docosyl acrylate, n-vinyl pyrrolidone, 2-vinyl pyridine, 4-vinyl pyridine, epichlorohydrin, n-vinyl formamide, n-vinyl acetamide, 2-hydroxyethyl acrylate glycidyl methacrylate, 3-(allyloxy)-2-hydroxypropane-1-sulfonate, 2-(allyloxy)ethanol, ethylene oxide, propylene oxide, 2,3-epoxypropyltrimethylammonium chloride, (3-glycidoxypropyl)trimethoxy silane, epichlorohydrin-dimethylamine, vinyl sulfonic acid sodium salt, sodium 4-styrene sulfonate, caprolactam and any combination thereof;
non-ionic, water-soluble monomers selected from one or more of: acrylamide, methacrylamide, N,N-dimethylacrylamide, N,N-diethylacrylamide, N-isopropylacrylamide, N-vinylformamide, N-vinylmethylacetamide, N-vinyl pyrrolidone, 2-vinyl pyridine, 4-vinyl pyridine, epichlorohydrin, acrylonitrile, hydroxyethyl methacrylate, hydroxy ethyl acrylate, hydroxypropyl acrylate, hydroxypropyl methacrylate, hexadecyl methacrylate, octadecyl methacrylate, glycidyl methacrylate, 3-(glycidoxypropyl)trimethoxy silane, 2-allyloxy ethanol, docosyl acrylate, N-t-butylacrylamide, N-methylolacrylamide, epichlorohydrin-dimethylamine, caprolactam, and any combination thereof;
anionic monomers selected from one or more of acrylic acid; methacrylic acid, 2-acrylamido-2-methylpropanesulfonic acid (AMPS), sodium vinyl sulfonate, styrene sulfonate, maleic anhydride, maleic acid, sulfonate itaconate, sulfopropyl acrylate, polymerizable carboxylic or sulphonic acids, crotonic acid, sulfomethylated acrylamide, allylsulfonate, sodium vinyl sulfonate, itaconic acid, acrylamidomethyl butanoic acid, fumaric acid, vinylphosphonic acid, vinylsulfonic acid, vinylsulfonic acid sodium salt, allylphosphonic acid, 3-(allyloxy)-2-hydroxypropane sulfonate, sulfomethyalted acryamide, phosphono-methylated acrylamide, ethylene oxide, propylene oxide, and any salts or combinations thereof; and
cationic monomers selected from one or more of dialkylaminoalkyl acrylates, methacrylates and their quaternary or acid salts.

The method can optionally further include wherein at least one second branch of the first polymer chain includes a different selection of monomers than the at least one first branch of the at least one first polymer chain, the different selection being different in at least one selected from monomer type, or monomer ratio.

The method can optionally further include wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes increases the dry or wet strength of the substrate, component, or additive.

The method can optionally further include wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes increases the wet web strength of the substrate, component, or additive.

The method can optionally further include wherein the combining step (a) includes blending the nanocrystalline cellulose (NCC), nanocrystalline (NC) materials, nanocrystalline (NC) carbon, nanocrystalline (NC) carbon nanotubes, nanocrystalline (NC) layers, alloys, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes with a polymer to provide a blend, and adding the blend to the substrate, component, or additive, wherein the blend is substantially distributed on the surface of the substrate, component, or additive, and wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes includes a nanocrystalline cellulose (NCC)-core which is essentially the nanocrystalline (NC) crystallites having a diameter of 5-10 nm.

The method can optionally further include wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is combined in step (a) at the wet end and/or in the dry end of the combining.

The method can optionally further include wherein the nanocrystalline cellulose (NCC), nanocrystalline (NC) materials, nanocrystalline (NC) carbon, nanocrystalline (NC) carbon nanotubes, nanocrystalline (NC) layers, alloys, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added in the combining step (a) as: (i) a coating outside of the substrate, component, or additive; or (ii) dispersed within the substrate, component or additive.

The method can optionally further include wherein the nanocrystalline cellulose (NCC), nanocrystalline (NC) materials, nanocrystalline (NC) carbon, nanocrystalline (NC) carbon nanotubes, nanocrystalline (NC) layers, alloys, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes includes one or more of linear, branched, or cyclic polymers extending from the nanocrystalline cellulose (NCC) core or a nanocrystalline cellulose (NCC) graft polymer.

The method can optionally further include wherein the nanocrystalline cellulose (NCC) is selected from one or more of naturally occurring crystals obtained by separating the crystalline cellulose regions from the amorphous cellulose regions of a plant fiber.

The method can optionally further include wherein the nanocrystalline (NC) crystallites are 100-500 nm length and include between 85% and 97% of the nanocrystalline cellulose (NCC).

The method can optionally further include wherein the combining step (a) includes one or more of:
providing an aqueous mixture including partially hydrolyzed forms of the nanocrystalline cellulose (NCC), nanocrystalline (NC) materials, nanocrystalline (NC) carbon, nanocrystalline (NC) carbon nanotubes, nanocrystalline (NC) layers, alloys, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes in a dissolution media;
providing a solution including the substrate, component or additive in a polar organic solvent;
combining the mixture with the solution to form a precipitate; and washing the precipitate with water to remove solvent and dissolution media and produce a wet composite of the nanocrystalline (NC) composition; and
drying the wet composite to produce a dry composite as the nanocrystalline (NC) composition.

The method can optionally further include wherein the washing step is carried out continuously or as a batch process selected from one or more of mixing and separating; washing of a cake of the nanocrystalline (NC) composition; dialysis; or combinations thereof.

The method can optionally further include wherein the washing step is carried out until the wet composite has a pH between 6 and 7.

The method can optionally further include wherein the drying step is carried out at one or more selected from room temperature, heating, cooling; atmospheric pressure, and reduced pressure.

The method can optionally further include wherein the dry composite produced is rigid and has (i) a storage modulus of between 1-5 and 20-35 gigapascals, at a temperature of 20 degrees C., or (ii) a storage modulus between 0.1-1 gigapascals and 10-20 gigapascals, at a temperature of 100 degrees Centigrade.

The method can optionally further include wherein dry composite is porous and has a density of 0.01 to 10 grams per cubic centimeter and a residual weight of about 1-20% at a temperature of 400 degrees C. and combinations thereof.

The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be a polymer grafted on to at least one NC core component, compound, or moiety. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be a branched or linear polymer having a first polymer chain extending from an NCC core and at least one branch diverting away from the first polymer chain. The branch can optionally be constructed out of one or more different combinations of monomers than the first polymer chain, the different selection being optionally different in one or more of monomer type, monomer ratio, or both. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally increase the dry or wet strength of the substrate, component, or additive.

The present subject matter can optionally include a method of making a nanocrystalline (NC) composite or product, including: (a) providing an aqueous mixture including partially hydrolyzed cellulose in a dissolution media; (b) providing a solution including a aliphatic polyester in a polar organic solvent; (c) combining the mixture with the solution to form a precipitate; and (d) washing the precipitate with water to remove solvent and dissolution media and form a wet composite; and then (e) drying the wet composite to form a dry composite.

In one or more optional embodiments, the combining step, and the washing step, can optionally be carried out in a form or mold; and the method further includes the step of: (e) releasing the composite from the form or mold to produce a composite product (optionally having a shape corresponding to the shape of the form or mold), and then optionally (f) cutting or grinding the product to further define the features thereof. Other optional embodiments include a shaped product produced by a process as described herein or known in the art or a particulate nanocrystalline (NC) composite produced by the process described herein.

The method can optionally further include wherein the form or alloy of metal is selected from iron or titanium based nanocrystalline magnetic materials that absorb or reflect electromagnetic energy in the range of 10 to 100 kHz that are provided with crystal diameters in the range of 10-15 nm.

The method can optionally further include wherein the iron or titanium based nanocrystalline magnetic material is selected from a FeSiBNbCu alloy, dialectic TiO2 powder, or BaTiO3 powder.

The method can optionally further include a method for blocking or absorbing electromagnetic (EM) radiation, including one or more of:

providing a nanocrystalline (NC) product providing by a method hereof;

blocking or absorbing EM radiation using the nanocrystalline (NC) product.

The method can optionally further include wherein said nanocrystalline (NC) product is selected from one or more of solar ceramic products, electrochromic display solar energy devices, nanocrystalline (NC) coating applications, nano liquid crystal solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles coating applications, solar film materials to produce solar windows, solar powered cars, solar powered lights, solar powered gadgets, solar powered roof tiles, solar storage system, solar energy storage systems, solar panels, solar glass panels, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar powered shingles, photovoltaic solar powered shingles, solar powered roadways, solar powered roadways and/or other solar building applications, solar paint, solar paint additives cells, solar energy devices, Nano coatings, computer chips, thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, and power tool housings can make them simultaneously lightweight, stiff, durable, and resilient, nanoscale additives to or surface of nanoscale thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices and other surfaces can make them anti-reflective, self-cleaning, resistant to ultraviolet (UV) or infrared light, or electrically conductive. Nano-engineered materials in solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices include thin film solar panels, solar glass panels, high-power rechargeable solar battery systems; thermoelectric materials to produce temperature control; thin film smart solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, solar energy storage systems, applications, products and services, and the like.

The present subject matter can also optionally include, but it not limited to, using or adding nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes with manganese phosphates are of considerable industrial interesting properties nowadays because of their wide applications in laser host, ceramic, dielectric, electric, magnetic, and catalytic processes, including but not limited to, manganese (III) phosphates such as Manganese dihydrogenphosphate dihydrate (Mn(H2PO4)2·2H2O), MnP3O9, MnPO4.H2O, MnPO4, MnHP2O7 and Mn3(PO4)3, which can be made according to known methods, as known in the art, e.g., Danvirutai et al., Journal of Alloys and Compounds 457 (2008) pp. 75-80, entirely incorporated by reference. The present subject matter can also optionally include compositions and methods using the nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes including of the present subject matter for use in one or more of sources or compounds including one or more of calcium, carbon, hydrogen, magnesium, nitrogen, oxygen, phosphorus, potassium, or sulphur, and/or micronutrients can include one or more of sources or compounds including one or more of boron, chloride, cobalt, copper, iron, molybdenum, manganese, nickel, silicon, sodium, and/or zinc.

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes can optionally be used in batteries, e.g., NiMH, or Lithium (Li) batteries or rechargeable solar energy batteries or super capacitors, as nanocrytalline metal hydrides, including, but not limited to, one or more of structure, electrochemical and electronic properties of nanocrystalline and polycrystalline TiFe—, LaNi5- and Mg2Ni-type phases, which can optionally be prepared by mechanical alloying (MA) followed by annealing or by induction melting method, respectively. The properties of hydrogen host materials can be modified substantially by alloying to obtain the desired storage characteristics, e.g., respective replacement of Fe in TiFe by Ni and/or by Mg, Cr, Mn, Co, Mo, Zr, or for Li batteries, e.g., LiMn2O4, γ-Fe₂O₃, fluorine-doped tin oxide and potassium manganese oxyiodide or nanocrystalline solid solutions AlySn1-y02-y/2 (y=0.57, 0.4) as electrode materials to produce lithium-ion batteries (e.g., Becker et al. Journal of Power Sources, Volume 229, 1 Can optionally 2013, Pages 149-158), which can improve not only the discharge capacity but also the cycle life of these electrodes, e.g., nanocrystalline TiFe0.125Mg0.125Ni(0.75) powder, e.g., cobalt substituting nickel in LaNi4-xMn0.75Al0.25Cox alloy greatly improves the discharge capacity and cycle life of LaNi5 material, e.g., nanocrystalline LaNi3.75Mn0.75Al0.25Co0.25 powder.

Super capacitors and batteries can optionally include nanocrystalline transition metal nitrides (TMN) based on vanadium nitride, that can optionally deliver a specific capacitance of 1,340 F/g when tested at low scan rates of 2 mV/s and 554 F/g when tested at high charging rates of 100 mV/s in the presence of a 1M KOH electrolyte; and/or using nanostructured vanadium nitride and controlled oxidation of the surface at the nanoscale can optionally be in super capacitors used in e.g., cars, camcorders and lawn mowers to industrial backup power systems at hospitals and airports.

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes can optionally be used in inverter components and materials such as nanocrystalline soft magnetic materials, e.g., of Fe-based soft magnetic material.

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes including of the present subject matter can also optionally include nanocomposites fabricated by gelation and electro spinning, which can have advantages for improving mechanical properties of both nanocomposite hydrogels and electrospun nanocomposite fibers/mats, as used in the present subject matter, which can optionally include, as known in the art, including multifunctional properties, nanocomposite hydrogels from CNCs and other stimuli responsive polymers, liquid polymers, liquid crystal polymers, liquid carbon polymers, composite gel polymers, and other applications, e.g., hydrophilicity, biodegradability, biocompatibility, low cost, and non-toxicity. Electrospun nanocomposite fibers can optionally include improved fabrication, morphology, mechanical and/or thermal properties with designed and improved functional characteristics and properties, such as, but not limited to energy-related materials, sensor, barrier films, and solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, as known in the art.

The foregoing and other objects and aspects of the present subject matter are explained in greater detail in the drawings herein and the specification set forth below. The disclosures of all United States Patent references cited herein are to be incorporated by reference herein in their entirety.

### BRIEF DESCRIPTION OF THE DRAWINGS

The accompanying drawings incorporated in and forming a part of the specification illustrate several aspects of the present subject matter and, together with the description, explain the principles of the present subject matter. In the drawings:

FIG. 1 is a simplified structure diagram of an embodiment of a nanocrystalline superlattice solar cells constructed in accordance with the teachings of the present subject matter;

FIG. 2 is a simplified valence diagram illustrating the bandgap differences between the amorphous nanocrystalline (NC) carbon, nanocrystalline (NC) carbon nanotubes, nanocrystalline (NC) carbon, nanocrystalline (NC) carbon nanotubes, nanocrystalline (NC) layers of an embodiment of a superlattice constructed in accordance with the teachings of the present subject matter;

FIG. 3 is an alternate embodiment of a nanocrystalline superlattice solar cells constructed in accordance with the teachings of the present subject matter;

FIG. 4 is a simplified valence diagram showing decreasing bandgap energy with increasing Germanium content across an amorphous layer of an embodiment of the nanocrystalline superlattice constructed in accordance with the teachings of the present subject matter;

FIG. 5 is a simplified structure diagram illustrating construction of an alternate embodiment of an amorphous layer of a superlattice constructed in accordance with the teachings of the present subject matter utilizing discreet step increases of Germanium content among sub-layers thereof;

FIG. 6 is a simplified valence diagram illustrating the discreet reduction in bandgap across the amorphous layer of FIG. 5; and

FIG. 7 is a graphical illustration comparing the normalized QE of a device constructed in accordance with the teachings of the present subject matter with a prior nanocrystalline superlattice solar cells.

While the present subject matter will be described in connection with certain preferred embodiments, there is no intent to limit it to those embodiments. On the contrary, the intent is to cover all alternatives, modifications and equivalents as included within the spirit and scope of the present subject matter as defined by the appended claims.

### DETAILED DESCRIPTION

Alternative optional embodiments of the present subject matter can provide a new and improved nanocrystalline superlattice solar cells including nanocrystalline cellulose (NCC) that overcomes one or more of the problems existing in the art. More specifically, embodiments of the present subject matter provide new and improved nanocrystalline superlattice solar cells that will add one or more lay ers to the nanocrystalline solar cell that will produce electricity on one or more of the nanocrystalline superlattice lay ers of the solar cell for for electricity that can be used for solar energy devices, solar energy storage systems, applications, products and services, including without limitation, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles NCC in the construction of one or more of the nanocrystalline superlattice layers of the solar cell in combination with other materials such as silicon, polycrystalline, copper indium diselenide, cadmium telluride, gallium arsenide, gallium phosphide, carbon solar cells, in the construction of one or more of the nanocrystalline superlattice layers of the solar cell.

In one embodiment the nanocrystalline superlattice solar cells includes a substrate on which an n+ layer is deposited. On top of this n+ doped layer is deposited a superlattice having alternating amorphous nanocrystalline (NC) carbon, nanocrystalline (NC) carbon nanotubes, nanocrystalline (NC) layers. On top of the nanocrystalline superlattice is deposited a P-doped nanocrystalline or amorphous layer to complete the basic solar cell structure. The nanocrystalline solar cell is completed by depositing a transparent conductor on the top p+ layer.

In one embodiment the nanocrystalline superlattice includes alternating lay ers of amorphous silicon, polycrystalline, copper indium diselenide, cadmium telluride, gallium arsenide, gallium phosphide, carbon solar cells, (a-(Si,alloy):H) nanocrystalline (NC) carbon, nanocrystalline (NC) carbon nanotubes, nanocrystalline (NC) carbon, nanocrystalline (NC) carbon nanotubes, nanocrystalline (NC) silicon. The percentage content of metal alloy in the amorphous layer can optionally be held constant across the amorphous layer, or can optionally be graded with an increasing metal allow content as the amorphous layer is deposited. The grading can optionally be continuous or discontinuous, and can optionally vary from a starting % of metal alloy to an ending % of metal alloy across the amorphous layer. The starting metal alloy content can optionally be 0% or greater, and the ending percentage can optionally be 100% or less. The number of alternating lay ers can optionally vary as desired, and typically will be 50 lay ers or less. In one embodiment, the first amorphous layer of the nanocrystalline superlattice is thinner than subsequent amorphous lay ers and does not contain any metal alloy content whatsoever.

Alternative embodiments of the present subject matter optionally relate to methods, apparatus, products, and/or systems relating to making or using nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar films, dye-sensitized solar cells, solar energy batteries, solar energy consumer products, solar powered products for the home, solar energy storage systems, solar products or solar energy devices for for electricity that include a combination of one or more of nanocrystalline cellulose (NCC), nanocrystalline (NC) materials, nanocrystalline (NC) carbon, nanocrystalline (NC) carbon nanotubes, nanocrystalline (NC) lay ers, nanocrystalline (NC) metals and alloys, nanocrystalline (NC) plastics, nanocrystalline (NC) polymers or nanocrystalline (NC) nanotubes including of cellulose nanocomposites, nanomaterials, nanostructures or nanocrystalline (NC) lay ers that have been processed into one or more lay ers to the nanocrystalline solar cell including of solid, flake, particles, liquid, non-liquid, spray dried, non-spray dried, bulk, cellulose, coating applications, composite material, components, powder, paste, metallization paste, pulp, fibers, foam, gel, resin, wax, wood chips, wood pulp, bamboo pulp, bleached pulp, wood-based fibers, plant fibers, pulp fibers, extract, seeds, encapsulated, grains, tablets or other forms with vapor processing, solid state processing, liquid processing, spray pyrolysis, electrochemical deposition, gas phase deposition, laser processing or other processing methods that can optionally be combined with nanocrystalline (NC) materials to produce electricity for nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices using a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, nano flakes, films, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices.

The present subject matter can optionally provide wherein the nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices for for electricity that include a combination of two or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) plastics structures or other forms of nanocrystals of cellulose composites or nanomaterials or nanocrystalline (NC) nanotubes or nanoparticles or nanocrystalline (NC) layers that can optionally be combined with nanocrystalline (NC) materials to produce electricity for nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices using a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, Nano flakes, films, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices.

The present subject matter can optionally provide wherein the materials reflect specific wavelengths that can optionally penetrate one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, nano flakes, films, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices.

The present subject matter can optionally provide for absorption of electromagnetic wave radiation using nanocrystalline magnetic materials to reduce the harmful effects of electromagnetic waves on the human body through electromagnetic shielding and other nearby devices causing them to malfunction.

### Definitions

The following definitions are provided as non-limiting examples of terms used herein, which further include how these terms are known in the relevant arts and provided by contemporary publications, reference materials, and the like, in printed or electronic form, e.g., as provided on the internet or in libraries. The organization of the definitions is for convenience only and is not intended to limit any of the definitions to any particular category.

In the event that the above definitions or a description stated elsewhere in this application is inconsistent with a meaning (explicit or implicit) which is commonly used, in a dictionary, or as known in the relevant arts and provided by contemporary publications, reference materials, and the like, in printed or electronic form, e.g., as provided on the internet or in printed and electronic books or reference materials provided in one or more libraries, which are incorporated by reference into this application.

Amorphous Metal (also known metallic glass or glassy metal) is a solid metallic material, usually an alloy, with a disordered atomic-scale structure. Most metals are crystalline in their solid state, which means they have a highly ordered arrangement of atoms. Amorphous metals are non-crystalline, and/or have a glass-like structure. But unlike common glasses, such as window glass, which are typically insulators, amorphous metals have good electrical conductivity. There are several ways in which amorphous metals can optionally be produced, including cooling, physical, solid-state reaction, ion irradiation, and/or mechanical alloying. In the past, small batches of amorphous metals have been produced through a variety of quick-cooling methods. For instance, amorphous metal ribbons have been produced by sputtering molten metal onto a spinning metal disk (melt spinning). The rapid cooling, on the order of millions of degrees a second, is too fast for crystals to form and/or the material is “locked” in a glassy state. More recently several alloys with critical cooling rates low enough to allow formation of amorphous structure in thick layers (over 1 millimeter) had been produced; these are known as bulk metallic glasses (BMG). Liquid metal sells a number of titanium-based BMGs, developed in studies originally performed at Caltech. More recently, batches of amorphous steel have been produced that demonstrate strengths much greater than conventional steel alloys.

Amorphous Solid. Amorphous solid is a solid, which lacks a crystalline structure. That is, it does not have long range ordered arrangement of atoms, molecules, or ions within the structure. Glass, gels, thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, solar plastic products and nano structures materials are some examples for amorphous solids. Glass is primarily made with sand (silica/SiO₂), and bases like sodium carbonate, and calcium carbonate. At high temperatures, these materials melt together, and when they are cooled, a rigid glass is formed rapidly. When cooling, the atoms are arranged in a disordered manner to produce glass; thus, it is referred to as amorphous. However, atoms can have a short-range order due to chemical bonding characteristics. Likewise, other amorphous materials can optionally be prepared by rapidly cooling molten material. Amorphous solids don't have a sharp melting point They liquefy over a broad range of temperature. Amorphous solids like rubber are used in tire manufacturing. Glass and plastics are used in the making of house ware, laboratory equipment etc.

Artificial Sunlight is the use of a light source to simulate sunlight where the unique characteristics of sunlight are needed, but where sufficient natural sunlight is not available or is not feasible. A light source used to simulate sunlight is a solar simulator.

Black Silicon is a semiconductor material, a surface modification of silicon with very low reflectivity and correspondingly high of visible (and infrared) light.

Crystalline Solid. Crystalline solids or crystals have ordered structures and symmetry. The atoms, molecules, or ions in crystals are arranged in a particular manner, thus, have a long-range order. In crystalline solids, there is a regular, repeating pattern; by definition, a crystal is “a homogenous chemical compound with a regular and periodic arrangement of atoms. Examples are halite, salt (NaCl), and quartz (SiO₂). But crystals are not restricted to minerals: they include most solid matter such as sugar, cellulose, nanocrystalline (NC) metals and alloys, bones and even DNA.” Crystals are naturally occurring on earth as large crystalline rocks such as quartz, granite. Crystals are formed by living organisms. For example, calcite is produced by mollusks. There are water-based crystals in the form of snow, ice or glaciers. Crystals can be categorized according to their physical and chemical properties. They are covalent crystals (e.g.: diamond), metallic crystals (e.g.: pyrite), ionic crystals (e.g.: sodium chloride) and molecular crystals (e.g. sugar). Crystals can have different shapes and colors. Crystals have an aesthetic value, and it is believed to have healing properties; thus, people use them to make jewelry.

Bamboo Pulp is a tribe of flowering perennial evergreen plants in the grass family Poaceae, subfamily Bambusoideae, tribe Bambuseae; although, the forestry services and departments of many countries where bamboo is utilized as a building consider bamboo to be a forestry product, and it is specifically harvested as a tree exclusively for the wood it produces, which in many ways is a wood superior in strength and resilience to other natural, fibrous buildings. In bamboos, the internodal regions of the stem are hollow and the vascular bundles in the cross section are scattered throughout the stem instead of in a cylindrical arrangement. The dicotyledonous woody xylem is also absent. The absence of secondary growth wood causes the stems of monocots, even of palms and large bamboos, to be columnar rather than tapering. Bamboos are some of the fastest-growing plants in the world, due to a unique rhizome-dependent system. Certain species of bamboo can grow 35 inches within a 24-hour period, at a rate of 0.00003 km/h (a growth of approximately 1 millimeter (or 0.02 inches) every 2 minutes). Bamboos are of notable economic and cultural significance in South Asia, Southeast Asia and East Asia, being used for buildings, as a food source, and as a versatile taw product. Bamboo has a higher compressive strength than wood, brick or concrete and a tensile strength that rivals steel.

Battery Types can include, but not limited to, (a) primary cells or non-rechargeable solar energy batteries, solar energy consumer products, solar powered products for the home, alkaline battery, aluminum-air battery, aluminum-ion battery, atomic battery, bendable battery, betavoltaics, optoelectric nuclear battery, nuclear micro-battery, bunsen cell, chromic acid cell (Poggendorff cell), cell phone battery, Clark cell, Daniell cell, Dry cell, Earth battery, flexible battery, Frog battery, Galvanic cell, Grove cell, Leclanché cell, Lemon battery, Lithium battery, Lithium air battery, Mercury battery, Molten salt battery, Nickel oxyhydroxide battery, Oxyride battery, Pulvermacher's chain, Reserve battery, Silver-oxide battery, Solid-state battery, Voltaic pile, wearable battery, Weston cell, Zinc-air, battery, Zinc-carbon battery, Zinc chloride battery; (b) Secondary cells or rechargeable solar energy batteries: Flow battery, Vanadium redox battery, Zinc-bromine battery, Zinc-cerium battery, Fuel cell, Lead-acid battery, Deep cycle battery, VRLA battery, AGM battery, Gel battery, Lithium air battery, Lithium-ion battery, Beltway battery, Lithium ion manganese oxide battery (IMR), Lithium ion polymer battery, Lithium iron phosphate battery, Lithium-sulfur battery, Lithium-titanate battery, Molten salt battery, Nickel-cadmium battery, Nickel-cadmium battery vented cell type, Nickel hydrogen battery, Nickel-iron battery, Nickel metal hydride battery, Low self-discharge NiMH battery, Nickel-zinc battery, Organic radical battery, Polymer-based battery, Polysulfide bromide battery, Potassium-ion battery, Rechargeable alkaline battery, Rechargeable fuel battery, Silicon air battery, Silver-zinc battery, Silver calcium battery, Sodium-ion battery, Sodium-sulfur battery, Sugar battery, Super iron battery, Ultra Battery; and/or (c) Batteries by application: e.g., Backup battery, Battery (vacuum tube), Battery pack, Battery room, Biobattery, Button cell, Car battery, CMOS battery, Common battery, Commodity cell, Electric vehicle battery, Home battery, Business battery, Laptop battery, Smart battery, Solar battery, Flow battery, Inverter battery, Lantern battery, Nanobatteries, Nanowire battery, Local battery, Polapulse battery, Photoflash battery, Smart battery system, Thin film rechargeable lithium battery, Traction battery, Watch battery, Water-activated battery, Wet cell, and/or Zamboni pile.

Renewable, Recycled, Fossil Fuel, Biodegradable, Plant Derived, and Other Plastics optionally usable in optional embodiments of the present subject matter can include one or more of those:
derived from renewable biomass sources, such as vegetable fats and/or oils, corn starch, pea starch or microbiota;
made from agricultural byproducts and/or also from used plastic bottles or plastic water bottles or other types of bottles or other containers using microorganisms;
as common plastics, such as fossil-fuel plastics (also called petrol based polymers), derived from petroleum;
as bio based polymers (plastics);
as biodegradable, optionally in anaerobic or aerobic environments;
as composed or made from or with one or more of starches, cellulose, polymers, liquid polymers, liquid crystal polymers, liquid carbon polymers, composite gel polymers, and/or a variety of nanocrystalline (NC) metals and alloys.

Carbon Nanotubes (CNTs) are allotropes of carbon with a cylindrical nanostructure. These cylindrical carbon molecules have unusual properties, which are valuable for nanotechnology, electronics, optics and other fields of materials science and technology. Owing to the material's exceptional strength and stiffness, carbon nanotubes have been constructed with length-to-diameter ratio of up to 132,000,000: significantly larger than for any other material. In addition, owing to their extraordinary thermal conductivity, mechanical, and electrical properties, carbon nanotubes find applications as additives to various structural materials. For instance, carbon nanotubes form a tiny portion of the material(s) in some (primarily carbon fiber) baseball bats, golf clubs, car parts or damascus steel. Carbon nanotubes are members of the fullerene structural family. Their name is derived from their long, hollow structure with the walls formed by one-atom-thick sheets of carbon, called graphene. These sheets are rolled at specific and discrete (“chiral”) angles, and the combination of the rolling angle and radius decides the nanotube properties; for example, whether the individual nanotube shell is a metal or semiconductor. Carbon nanotubes are categorized as single-walled carbon nanotubes (SWNTs) and multi-walled carbon nanotubes (MWNTs). Individual carbon nanotubes naturally align themselves into “ropes” held together by van der Waals forces, more specifically, pi-stacking. Applied quantum chemistry, specifically, orbital hybridization best describes chemical bonding in carbon nanotubes. The chemical bonding of carbon nanotubes is composed entirely of sp bonds, similar to those of graphite. These bonds, which are stronger than the sp³ bonds found in alkanes and diamond, provide carbon nanotubes with their unique strength.

Carboxymethyl Cellulose (CMC) or other cellulose gum is a cellulose derivative with carboxymethyl groups (—CH₂—COOH) bound to some of the hydroxyl groups of the glucopyranose monomers that make up the cellulose backbone. It is often used as its sodium salt, sodium carboxymethyl cellulose.

Catalytic Properties of Nanocrystal line. The gas-condensation technique is used to produce the nanocrystalline (NC) WO₃₋ₓ, Pt/WO₃₋ₓ, and Pd/WO₃₋ₓ powders under different atmosphere and pressure. HRTEM images show that a coherently bonded interface exists between Pt or Pd and WO₃₋ₓ. The nanocrystal WO₃₋ₓ, Pt/WO₃₋ₓ, and Pd/WO₃₋ₓ grow into a needle shape with a plate inside when these as-evaporated powders are compacted and sintered at 900° C. for 2 h. The plate grows preferentially in {220} plane along the <0011> direction. However, the mean particles size of nanophase Pt and Pd increases only from <10 nm to 30 nm and 50 nm, respectively. The results of CO oxidation show that nanophase Pt/WO₃₋ₓ powders have better catalytic effects on converting CO to CO₂ than nanophase WO₃₋ₓ and Pd/WO₃₋ₓ powders.

Cellulose is an organic compound and/or a polysaccharide formed of a linear chain of several hundred to many thousand/ors of β(1→4) linked D-glucose units. Cellulose is an important structural component of the primary cell wall of green plants, many forms of algae and/or the oomycetes. Some species of bacteria secrete it to form biofilms. Cellulose is the most abundant organic polymer on Earth. The cellulose content of cotton fiber is 90%, that of wood is 40%-50% and/or that of dried hemp is approximately 45%. Cellulose is mainly used to produce paper board and/or paper. Smaller quantities are converted into a wide variety of derivative products such as cellophane and/or rayon. Conversion of cellulose from energy crops into biofuels such as cellulosic ethanol is under investigation as an alternative fuel source.

Cellulose Acetate is the acetate ester of cellulose. Cellulose acetate can optionally be used as a film base in photography, as a component in some coatings, and as a frame material for eyeglasses. Cellulose acetate can optionally be used as a synthetic fiber in the manufacture of cigarette filters and playing cards.

Cellulose for Commercial Use is mainly obtained from wood pulp and/or cotton. Cellulose, one of the world's most abundant, natural and/or renewable polymer resources, is widely present in various forms of biomasses, such as trees, plants, tunicate and/or bacteria. Cellulose molecule is formed of β-1,4-D-linked glucose chains with molecular formula of (C₆H₁₀O₅)ₙ (n ranging from 10,000 to 15,000) through an acetal oxygen covalently bonding C1 of one glucose ring and/or C4 of the adjoining ring. In plant cell walls, approximately 36 individual cellulose molecule chains connect with each other through hydrogen bonding to form larger units known as elementary fibrils, which are packed into larger micro fibrils with 5-50 nm in diameter and/or several micrometers in length. These micro fibrils have disordered (amorphous) regions and/or highly ordered (crystalline) regions. In the crystalline regions, cellulose chains are closely packed together by a strong and/or highly intricate intra- and/or intermolecular hydrogen-bond network, while the amorphous domains are regularly distributed along the microfibrils. When lignocellulosic biomass is subjected to pure mechanical shearing, and/or a combination of chemical, mechanical and/or enzymatic treatment, the amorphous regions of cellulose microfibrils are selectively hydrolyzed under certain conditions because they are more susceptible to be attacked in contrast to crystalline domains. Consequently, these microfibrils break down into shorter crystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar films, dye-sensitized solar cells, solar energy batteries, solar energy consumer products, solar powered products for the home, solar energy storage systems, solar products or solar energy devices, solar components, electronics with high crystalline degree, which are generally referred to as cellulose nanocrystals (CNCs). CNCs are also named as microcrystals, whiskers, nanocrystalline (NC) superlattice solar cells, solar panels, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices for for electricity that include a combination of one or more of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, nano flake, nanoparticles, nanocomposite, nanomaterials, nanostructures or nanocrystalline (NC) layers for for electricity by creating magnetic fields from light at specific wavelengths to produce electricity by nanocrystalline solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, micro crystallites, nanofibers, or nanofibrils in the liturautes, all of which are called “cellulose nanocrystals.”

Cellulose Fibers are fibers made with ether or esters of cellulose, which can optionally be obtained from the bark, wood or leaves of plants, or from a plant-based material. Besides cellulose, these fibers are compound of hemicellulose and/or lignin, and/or different percentages of these components are responsible for different mechanical properties observed. The main applications of cellulose fibers are in textile industry, as chemical filter, and/or fiber-reinforcement composite, due to their similar properties to engineered fibers, being another option for bio composites and/or polymer composites.

Cellulose Nanocrystals (CNC) are cellulose-based nanoparticles that can be extracted by acid hydrolysis from a wide variety of natural source materials (e.g., trees, annual plants, tunicates, algae, bacteria). These rod-like or whisker-shaped particles (3-20 nm wide, 50-2000 nm long) have a unique combination of characteristics: high axial stiffness (˜150 GPa), high tensile strength (estimated at 7.5 GPa), low coefficient of thermal expansion (˜1 ppm/K), thermal stability up o ˜300° C., high aspect ratio (10-100), low density (˜1.6 g/cm3), lyotropic liquid crystalline behavior, and shear thinning rheology in CNC suspensions. The exposed —OH groups on CNC surfaces can be readily modified to achieve different surface properties and have been used to adjust CNC self-assembly and dispersion for a wide range of suspensions and matrix polymers and to control interfacial properties in composites (e.g., CNC-CNC and CNC-matrix). This unique set of characteristics results in new capabilities compared to more traditional cellulose based particles (wood flakes, films, plant fibers, pulp fibers, etc.) and the development of new composites that can take advantage of CNCs' enhanced mechanical properties, low defects, high surface area to volume ratio, and engineered surface chemistries. CNCs have been successfully added to a wide variety of natural and synthetic polymers and have been shown to modify composite properties (mechanical, optical, thermal, barrier). Additionally, CNCs are a particularly attractive nanoparticle because they have low environmental, health, and safety risks, are inherently renewable, sustainable, and carbon-neutral like the sources from which they are extracted, and have the potential to be processed in industrial-scale quantities at low costs.

Cellulose Insulation. The word cellulose comes from the French word for a living cellule and glucose, which is sugar. Building insulation is low-thermal-conductivity material used to reduce building thermal loss and gain, and reduce noise transmission. Cellulose Insulation is plant fiber used in wall and roof cavities to insulate, draught proof and reduce noise.

Classification of Cellulose-Based Polymers. CELLULOSE. Pure cellulose is available in different forms in the market with very different mechanical and pharmaceutical properties. The difference between various forms of cellulose is related to the shape, size and degree of crystallinity of their particles (fibrous or agglomerated).

CELLULOSE ETHER DERIVATIVES. Cellulose ethers are high molecular weight compounds produced by replacing the hydrogen atoms of hydroxyl groups in the anhydroglucose units of cellulose with alkyl or substituted alkyl groups. The commercially important properties of cellulose ethers are determined by their molecular weights, chemical structure and distribution of the substituent groups, degree of substitution and molar substitution (where applicable). These properties generally include solubility, viscosity in solution, surface activity, thermoplastic film characteristics and stability against biodegradation, thermal, hydrolysis and oxidation. Viscosity of cellulose ether solutions is directly related with their molecular weights. Examples of mostly used cellulose ethers are: Methyl cellulose (MC), Ethyl cellulose (EC), Hydroxyethyl cellulose (HEC), Hydroxypropyl cellulose (HPC), hydroxypropylmethyl cellulose (HPMC), carboxymethyl cellulose (CMC) and sodium carboxymethyl cellulose (NaCMC).

Cellulose Triacetate, also known simply as triacetate, CTA and TAC, is manufactured from cellulose and a source of acetate esters, typically acetic anhydride. Triacetate is typically used for the creation of fibers and film. It is similar chemically to cellulose acetate, with the distinguishing characteristics being that in triacetate, according to the Federal Trade Commission definition, at least “92% of the hydroxyl groups are acetylated.” During the manufacture of triacetate, the cellulose is completely acetvlated whereas in regular cellulose acetate or other cellulose, it is only partially acetvlated. Triacetate is significantly more thermal resistant than cellulose acetate.

Chemical Vapor Deposition (CVD) is a type of chemical process used to produce high quality, high-performance, solid materials. The process is often used in the semiconductor industry to produce thin film. In typical CVD, the wafer (substrate) is exposed to one or more volatile precursors, which react and/or decompose on the substrate surface to produce the desired deposit. Frequently, volatile by-products are also produced, which are removed by gas flow through the reaction chamber. Micro fabrication processes widely use CVD to deposit materials in various forms, including: monocrystalline, polycrystalline, amorphous, and epitaxial. These materials include: silicon, carbon fiber, carbon nanofibers, fluorocarbons, filaments, carbon nanotubes, SiO₂, silicon-germanium, tungsten, silicon carbide, silicon nitride, silicon oxynitride, titanium nitride, and various high-k dielectrics. CVD is also used to produce synthetic nanocrystalline (NC) diamonds.

Coating Applications and Thin film solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles can optionally include, but not limited to, being applied to structural bulk materials to improve the desired properties of the surface, such as wear resistance, friction, corrosion resistance and others, yet keeping the bulk properties of the material unchanged. A typical example is nitriding and carbonitriding of steel parts for engines and other machines at relatively low temperatures of about 500° C. to increase the hardness of the surface and reduce wear. Modern nanostructured coating applications and thin film for structural and functional applications, which were developed during the past 10-15 years, are used mainly for wear protection of machining tools and for the reduction of friction in sliding parts. One distinguishes between nanocrystalline (NC) coating applications and thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, where a few nanometers thin layers of two different materials are deposited subsequently, and nanocomposites, which are, in the optimum case, isotropic. The ultra hard (NC) nanocomposites, such as nc-OTi₁₋ₓAlx)N/a-Si₃N₄ (nc- and a-stand for making nanocrystalline and X-ray amorphous, respectively), show superior cutting performance as compared with conventional, state-of-the art hard coating applications (Ti₁₋ₓAlx)N that presently dominate the applications for dry machining. The costs of their large-scale industrial production are comparable with those of the conventional coating applications. Also, the heterostructures and multilayer coating applications are successfully applied on industrial scale. Low-friction nanostructured coating applications including a hard transition-metal carbide or nitride in combination with a solid lubricant, such as diamond-like carbon (DLC), MoS₂, WS₂ and others that combine with a high hardness and low friction. They are applied in a variety of bearings and sliding parts operating without liquid lubricants, which is an important advantage particularly in a hostile environment, and when the movable parts have to stop and go very frequently, e.g. in the textile industry. The recent development of nanocomposites of a hard transition-metal nitride or carbide in combination with soft and ductile metal is likely to find numerous applications in a variety of machine parts. The hardness of these coating applications varies between about 13 and 30 GPa depending on the composition. When deposited under energetic ion bombardment and temperatures below about 350° C., an enhancement of the hardness up to about 50 GPa was found, in a similar way as for hard transition-metal nitrides (e.g. 100 GPa for TiAlVN and 80 GPa for TiN). However, this hardness enhancement is of a little use because, upon annealing to ≥500° C., these coating applications soften. Unfortunately, these nanocomposites were often confused with the thermally highly stable ultra hard (NC) nanocomposites prepared according to the generic design principle. The nanocrystalline (NC) coating applications should be subdivided into multilayers and superlattices. When a 3-4 μm thick monolytic layer of a hard ceramic material, such as TiN, is replaced by a stack of 20-100 nm thin multilayers of TiN and another hard nitride, boride or carbide, the resistance against brittle failure strongly increases because the crack cannot propagate through the whole layer. Usually, also an increase of the hardness above that of the rule-of-mixtures is found. Similar enhancement was found also in metallic multilayers, for example Fe/Cu and Ni/Cu and Ni₃Al/Ni, and in metal/nitride multilayers, for example Ti/TiN. The majority of hard protecting coating applications applied to machining tools nowadays are such multilayers.

Coatings Applications can optionally include, but not limited to, the nanocrystalline metal oxides require dispersion into a liquid medium, such as a solvent, or blended directly into the resin system. As produced, the metal oxide powders disperse well in aqueous environments wherein hydrogen bonding is sufficiently strong to disrupt the loose agglomerates and provide stable dispersions of the primary crystalline particles. The affinity of nanocrystalline powders for aqueous environments is often sufficient to allow the powders to be used in many waterborne coating formulations. However, because the powders do not disperse well in non-aqueous media, several specialized surface treatments have been developed that reduces particles agglomerates and yield stable dispersions in hydrocarbon solvents. Such treatments also prevent reagglomeration and thus enable the oxides to be used in a variety of solvent borne coating applications. Coating Applications is a covering that is applied to the surface of an object, usually referred to as the substrate. The purpose of applying the coating can optionally be decorative, functional, or both. The coating itself can optionally be an all-over coating, completely covering the substrate, or it can optionally only cover parts of the substrate. An example of all of these types of coating is a product label on many drinks, plastic bottles, plastic water bottles one side has an all-over functional coating (the adhesive) and the other side has one or more decorative coating applications in an appropriate pattern (the printing) to form the words and images. Paints and lacquers are coating applications that mostly have dual uses of protecting the substrate and being decorative, although some artist's paints are only for decoration, and the paint on large industrial pipes is presumably only for the function of preventing corrosion. Functional coating applications can optionally be applied to change the surface properties of the substrate, such as adhesion, wettability, corrosion resistance, or wear resistance. In other cases, e.g. semiconductor device fabrication (where the substrate is a wafer), the coating adds a completely new property such as a magnetic response or electrical conductivity and forms an essential part of the finished product. A major consideration for most coating processes is that the coating is to be applied at a controlled thickness, and a number of different processes are in use to achieve this control, ranging from a simple brush for painting a wall, to some very expensive machinery applying coating applications in the electronics industry. A further consideration for ‘non-all-over’ coating applications is that control is needed as to where the coating is to be applied. A number of these non-all-over coating processes are printing processes. Many industrial coating processes involve the application of a thin film of functional material to a substrate, such as paper, fabric, film, foil, or sheet stock. If the substrate starts and ends the process wound up in a roll, the process can optionally be termed “roll-to-roll” or “web-based” coating. A roll of substrate, when wound through the coating machine, is typically called a web. Coating applications can optionally be applied as liquid, non-liquids, gases or solids.

Colloidal Gold is a sol or colloidal suspension of submicrometre-size nanoparticles of gold in a fluid, usually water. The liquid is usually either an intense red color (for particles less than 100 nm) or blue/purple (for solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar films, dye-sensitized solar cells, solar energy batteries, solar energy consumer products, solar powered products for the home, solar energy storage systems, solar products or solar energy devices for larger particles). Due to the unique optical, electronic, and molecular-recognition properties of gold nanoparticles, they are the subject of substantial research, with applications in a wide variety of areas, including electron microscopy, electronics, nanotechnology, and materials science. The properties of colloidal gold nanoparticles, and thus their applications, depend strongly upon their size and shape. For example, rod like particles have both transverse and longitudinal absorption peak, and anisotropy of the shape affects there self-assembly.

Copper is a chemical element with symbol Cu (from Latin: cuprum) and atomic number 29. It is a ductile metal with very high thermal and electrical conductivity. Pure copper is soft and malleable; a freshly exposed surface has a reddish-orange color. It is used as a conductor of thermal and electricity, a building, and a constituent of various metal silicon, polycrystalline, copper indium diselenide, cadmium telluride, gallium arsenide, gallium phosphide, carbon solar cells, perovskite solar cells, copper alloy, cobalt alloy, and silver alloy. The metal and its silicon, polycrystalline, copper indium diselenide, cadmium telluride, gallium arsenide, gallium phosphide, carbon solar cells, perovskite solar cells, copper alloy, cobalt alloy, silver alloy or other types of alloys have been used for thousands of years. In the Roman era, copper was principally mined on Cyprus, hence the origin of the name of the metal as cyprium (metal of Cyprus), later shortened to cuprum. Its compounds are commonly encountered as copper (II) salts, which often impart blue or green colors to minerals such as azurite and turquoise and have been widely used historically as pigments. Architectural structures built with copper corrode to give green verdigris (or patina). Decorative art prominently features copper, both by itself and as part of pigments.

Crystal is a crystal or crystalline solid is a solid material whose constituent atoms, molecules, or ions are arranged in an orderly repeating pattern extending in all three spatial dimensions. This orderly repeating pattern is called a “crystal lattice.” Essentially these molecules are arranged in an orderly formation. In other words a crystal is in-formation. Computers store and/or transmit information on silicone crystals. Crystals, which are basically, sand/or in formation and/or so can optionally hold memory. Crystalline water or structured water is in-formation and/or so can optionally also store and/or transmit information.

Crystallite is a small or even microscopic crystal, which forms, for example, during the cooling of many materials. The orientation of crystallites can be random with no preferred direction, called random texture, or directed, possibly due to growth and processing conditions. Fiber texture is an example of the latter. Crystallites are also referred to as grains. The areas where crystallite grains meet are known as grain boundaries. Polycrystalline or multicrystalline materials, or polycrystals are solids that are composed of many crystallites of varying size and orientation. Most inorganic solids are polycrystalline, including all common metals, many ceramics, rocks and ice. The extent to which a solid is crystalline (crystallinity) has important effects on its physical properties. Sulfur, while usually polycrystalline, may also occur in other allotropic forms with completely different properties. Although crystallites are referred to as grains, powder grains are different, as they can be composed of smaller polycrystalline grains themselves. While the structure of a (monocrystalline) crystal is highly ordered and its lattice is continuous and unbroken, amorphous materials, such as glass and many polymers, are non-crystalline and do not display any structures as their constituents are not arranged in an ordered manner. Polycrystalline structures and paracrystalline phases are in between these two extremes.

Crystalline Forms. Each of the Earth's minerals has a crystalline form. Synthetic nanocrystalline (NC) diamonds are crystalline carbon; emeralds are crystalline beryllium; and/or rubies are crystalline corundum. The difference between corundum and/or a ruby is the way the molecules are organized or structured (see images of corundum and/or ruby). Each crystal has a specific structural pattern. Minerals form crystals when circumstances (for example: thermal and/or pressure) cause the molecules to form a repeating pattern. Most people know that extreme pressure is required to form a diamond. Pressure forces molecules to arrange themselves in a different configuration to withstand/or the pressure. Structural organization changes the characteristics of the substance. Some of these changes are obvious-like the visible difference between carbon and/or a diamond.

Crystalline Silicon (c-Si) is an umbrella term for the crystalline forms of silicon encompassing multicrystalline silicon (multi-Si) and monocrystalline silicon (mono-Si), the two dominant semiconducting materials used in photovoltaic technology for the production of solar using semiconducting materials, that are assembled into a solar panel and part of a solar cell or photovoltaic system to generate solar power from sunlight. In electronics, the term crystalline silicon typically refers to monocrystalline form silicon, as the sole material used for producing microchips, containing much lower impurity levels than those required for solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles. Production of semiconductor grade silicon involves a chemical purification to produce hyper pure polysilicon followed by a recrystallization process to grow monocrystalline silicon. The cylindrical boules are then cut into wafers for further processing. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles made of crystalline silicon are often called conventional, traditional, or first-generation solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, as they were developed in the 1950s and remained the most common type up to the present time. Because they are produced from about 160 μm thick solar wafers-slices from bulks of solar grade silicon-they are sometimes called wafer-based solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles made from c-Si are single-junction cells and are generally more efficient than their rival technologies, which are the second-generation solar glass, solar windows, solar powered cars, solar powered lights, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar film, the most important being CdTe, CIGS, and amorphous silicon (a-Si). Amorphous silicon is an allotropic variant of silicon, and amorphous means “without shape” to describe its non-crystalline form.

Electromagnetic Wave Absorption nanocrystalline (NC) carbon, nanocrystalline (NC) carbon nanotubes, nanocrystalline (NC) carbon, nanocrystalline (NC) carbon nanotubes, nanocrystalline Magnetic Materials is used in high-frequency electronic and communication devices has led to a rise in the amount of electromagnetic (EM) waves, causing harmful effects on human body and other nearby devices to malfunction. As concern about the effect of EM wave grows, the devices are required to have electromagnetic compatibility (EMC). Fe-based nanocrystalline magnetic materials such as Finemet alloys have excellent soft magnetic properties including large saturation magnetization and high relative permeability in the high frequency range. One application of the Finemet type alloy is an EM wave absorber, which absorbs the generated EM waves to transform into thermals. FeSiBNbCu alloys exhibit excellent soft magnetic properties when nanocrystalline bcc-Fe(Si) phases that was formed by the crystallization annealing were embedded uniformly in the amorphous matrix. Numerous studies have been made on the effect of grain size of crystalline bcc-Fe(Si) phase on the magnetic properties of FeSiBNbCu alloy, in which the optimum magnetic properties can be acquired when the grain size is controlled to the range 10˜15 nm.

Electrostatic Spray Assisted Vapor Deposition (ESAVD) is a technique (developed by a company called IMPT) to deposit both thin and thick layers of a coating onto various substrates. In simple terms chemical precursors are sprayed across an electrostatic field towards a heated substrate, the chemicals undergo a controlled chemical reaction and are deposited on the substrate as the required coating. Electrostatic spraying techniques were developed in the 1950s for the spraying of ionized particles on to charged or heated substrates. ESAVD (branded by IMPT as Layatec) is used for many applications in many markets including: thermal barrier coating applications for jet engine turbine blades, various thin layers in the manufacture of flat panel solar powered displays and photovoltaic panels, electronic components, solar energy batteries, solar energy consumer products, solar powered products for the home, thin film coating applications, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles coating applications. The process has advantages over other techniques for layer deposition (Plasma, Electron-Beam) in that it does not require the use of any vacuum, electron beam or plasma so reduces the manufacturing costs. It also uses less power and raw materials making it more environmentally friendly. Also the use of the electrostatic field means that the process can coat complex 3D parts easily.

Fiber (or fibre; from the Latin fibre) is a natural or synthetic string or used as a component of coating applications, composite materials, or, when matted into sheets, used to make products such as paper, papyrus, or felt. Fibers are often used in the manufacture of nanocrystalline (NC) metals and alloys. The strongest engineering materials often incorporate fibers, for example carbon fiber and/or ultra-high-molecular-weight polyethylene.

Frequency is the number of occurrences of a repeating event per unit time. It is also referred to as temporal frequency, which emphasizes the contrast to spatial frequency and angular frequency. The period is the duration of time of one cycle in a repeating event, so the period is the reciprocal of the frequency. For example, if a newborn baby's heart beats at a frequency of 120 times a minute, its period—the time interval between beats—is half a second (that is. 60 seconds divided by 120 beats). Frequency is an important parameter used in science and engineering to specify the rate of oscillatory and vibratory phenomena, such as mechanical vibrations, audio (sound) signals, radio waves, and light.

Frequencies non-limiting partial list of examples of optional frequencies include: 01=174 Hz02=285 HzUt=3% HzRe=417 HzMi=528 HzFa=639 HzSol=741 HzLa=852 Hz09=963 Hz. The numerical values of the Solfeggio Frequencies are generated by starting with the vector 1, 7, 4 and/or adding the vector 1, 1, 1 MOD 9. Each higher frequency is found by adding 1, 1, 1 MOD 9 to the previous lower frequency. The final frequency, when 1, 1, 1 can optionally be added to is, returns the frequency to the lowest tone 1, 7, 4.Ut=3% Hz which reduces to 9 (reducing numbers: 3+9=12=1+2=3; 3+6=9)Re=417 Hz which reduces to 3Mi=528 Hz which reduces to 6Fa=639 Hz which reduces to 9Sol=741 Hz which reduces to 3La=852 Hz which reduces to 6. The belief the frequency assigned to Mi for “Miracles,” 528 Hz, is said by proponents of the idea to be the exact frequency used by genetic engineers throughout the world to repair DNA. The Ancient “Solfeggio frequencies” are cyclic variation of the numbers 369,147 and/or 258. It is claimed that each frequency has specific spiritual and/or physical healing properties. It is also claimed that they are part of a process that can optionally assist you in creating the possibility of life without stress, illness, and/or sickness. Other non-limiting partial list of examples of frequencies includes 7.83 Hz, 126.22 Hz, 136.1 Hz, 144 Hz and/or 528 Hz.

Gallium Arsenide (GaAs) is a compound of the elements gallium and arsenic. It is a III-V direct bandgap semiconductor with a zinc blende crystal structure. Gallium arsenide is used in the manufacture of devices such as microwave frequency circuits, monolithic, infrared light-emitting diodes, laser diodes, solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles and optical solar windows. GaAs is often used as a substrate material for the epitaxial growth of other III-V semiconductors including: gallium arsenide, gallium phosphide, aluminum gallium arsenide and others.

Graphene (/′græsf.i:n/) is an allotrope of carbon in the form of a two-dimensional, atomic-scale, honeycomb lattice in which one atom forms each vertex. It is the basic structural element of other allotropes, including graphite, charcoal, carbon nanotubes and fullerenes. It can also be considered as an indefinitely large aromatic molecule, the ultimate case of the family of flat polycyclic aromatic hydrocarbons. Graphene has many extraordinary properties. It is about 100 times stronger than the strongest steel with a hypothetical thickness of 3.35 Å, which is equal to the thickness of the graphene sheet. It conducts thermal and electricity efficiently and is nearly transparent. Researchers have identified the bipolar transistor effect, ballistic transport of charges and large quantum oscillations in the material. Scientists have theorized about graphene for decades. It has likely been unknowingly produced in small quantities for centuries, through the use of pencils and other similar applications of graphite. It was originally observed in electron in 1962, but not studied further. The material was later rediscovered, isolated and characterized in 2004 by Andre Geim and Konstantin Novoselov at the University of Manchester. Research was informed by existing theoretical descriptions of its composition, structure and properties. High-quality graphene proved to be surprisingly easy to isolate, making more research possible. This work resulted in the two winning the Nobel Prize in Physics in 2010 “for groundbreaking experiments regarding the two-dimensional material grapheme. The global market for graphene is reported to have reached $9 million by 2014 with most sales in the semiconductor, electronics, battery energy and composites industries.

Indium is a chemical element with symbol In and atomic number 49. It is a metallic element that is rare in Earth's crust. The metal is very soft, malleable and easily fusible, with a melting point higher than sodium, but lower than lithium or tin. Chemically, indium is similar to gallium and thallium, and it is largely intermediate between the two in terms of its properties. It has no obvious role in biological processes and common compounds are not toxic. It is most notably used in low melting point metal alloys such as solders, in soft metal high vacuum seals, and in the production of transparent conductive coatings of indium tin oxide (ITO) on glass.

Macrofibril or Mkrofibril is a very fine fibril, or fiber-like strand, having glycoproteins and cellulose. It is usually, but not always, used as a general term in describing the structure of protein fiber, e.g. hair and sperm tail. Its most frequently observed structural pattern is the 9+2 pattern in which two central protofibrils are surrounded by nine other pairs. Cellulose inside plants is one of the examples of non-protein compounds that are using this term with the same purpose. Cellulose microfibrils are laid down in the inner surface of the primary cell wall. As the cell absorbs water, its volume increases and the existing microfibrils separate and new ones are formed to help increase cell strength.

Metals. Non-limiting partial list of examples of metals include, but not limited to, the alkali metals, alkaline earth metals, transition metals, basic metals, and rare earth elements. Hydrogen in its metallic state (considered a nonmetal), Lithium, Sodium, Potassium, Rubidium, Cesium, Francium, Beryllium, Magnesium, Sodium, Calcium, Strontium, Barium, Radium, Aluminum, Gallium, Indium, Tin, Thallium, Lead, Bismuth, Element 113—Ununtrium, Flerovium, Element 115, Ununpentium, Livermorium, Scandium, Titanium, Vanadium, Chromium, Manganese, Iron, Cobalt, Nickel, Copper, Zinc, Yttrium, Zirconium, Niobium, Molybdenum, Technetium, Ruthenium, Rhodium, Palladium, Silver, Cadmium, Lanthanum, Hafnium, Tantalum, Tungsten, Rhenium, Osmium, Iridium, Platinum, Gold, Mercury, Actinium, Rutherfordium, Dubnium, Seaborgium, Bohrium, Hassium, Meitnerium, Darm stadtium, Roentgenium, Copemicium, Cerium, Praseodymium, Neodymium, Promethium, Samarium, Europium, Gadolinium, Terbium Dysprosium, Holmium, Erbium, Thulium, Ytterbium, Lutetium, Thorium. Protactinium, Uranium Neptunium, Plutonium, Americium, Curium, Berkelium, Californium, Einsteinium, Fermium, Mendelevium, Nobelium and Lawrencium.

Nanoparticles are a class of nanoparticle, which can be manipulated using magnetic field gradients. Such particles commonly include magnetic elements such as iron, nickel and cobalt and their chemical compounds. While nanoparticles are smaller than 1 micrometer in diameter (typically 5-500 nanometers), the larger microbeads are 0.5-500 micrometer in diameter. Magnetic nanoparticle clusters, which are composed of a number of individual nanoparticles are known as magnetic nanobeads with a diameter of 50-200 nanometers. The nanoparticles have been the focus of much research recently because they possess attractive properties which could see potential use in catalysis including nanomaterial-based catalysts, biomedicine and tissue specific targeting, magnetically tunable colloidal photonic crystals, microfluidics, magnetic resonance imaging, magnetic particle imaging, data storage, environmental remediation, nanofluids, and optical filters, defect sensor and cation sensors and solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar films, solar energy devices, solar energy storage systems, applications, products and services for for electricity.

Magnetism is a class of physical phenomena that are mediated by magnetic fields. Electric currents and the magnetic of elementary particles give rise to a magnetic field, which acts on other currents and magnetic moments. Every material is influenced to some extent by a magnetic field. The most familiar effect is on permanent magnets, which have persistent magnetic moments caused by ferromagnetism. Most materials do not have permanent moments. Some are attracted to a magnetic field (paramagnetism); others are repulsed by a magnetic field (diamagnetism); others have a more complex relationship with an applied magnetic field (glass behavior and antiferromagnetism). Substances that are negligibly affected by magnetic fields are known as non-magnetic substances. These include copper, aluminum, gases, and plastic. Pure oxygen exhibits magnetic properties when cooled to a liquid state. The magnetic state (or magnetic phase) of a material depends on temperature and other variables such as pressure and the applied magnetic field. A material can optionally exhibit more than one form of magnetism as these variables change. Magnetic Field is the magnetic influence of electric currents and/or magnetic materials. The magnetic field at any given point is specified by both a direction and/or a magnitude (or strength); as such it is a vector field The term is used for two distinct but closely related fields denoted by the symbols B and/or H, where H is measured in units of amperes per meter (symbol: A·m⁻¹ or A/m) in the SI. B is measured in teslas (symbol: T) and/or newtons per meter per ampere (symbol: N·m⁻¹ A⁻¹ or N/(m·A)) in the SI. B is most commonly defined in terms of the Lorentz force it exerts on moving electric charges. Magnetic fields are produced by moving electric charges and/or the intrinsic magnetic moments of elementary products associated with a fundamental quantum property, their spin. In special relativity, electric and/or magnetic fields are two interrelated aspects of a single object, called the electromagnetic tensor, the split of this tensor into electric and/or magnetic fields depends on the relative velocity of the observer and/or charge. In quantum physics, the electromagnetic field is quantized and/or electromagnetic interactions result from the exchange of photons.

Metals (from Greek μ\acute{ε}ταλλov métallon, “mine, quarry, metal” is a material (an element, compound, or alloy) that is typically hard, opaque, shiny, and/or has good electrical and/or thermal conductivity. Metals are generally malleable—that is, they can optionally be hammered or pressed permanently out of shape without breaking or cracking—as well as fusible (able to be fused or melted) and/or ductile (able to be drawn out into a thin wire). About 91 of the 118 elements in the periodic table are metals (some elements appear in both metallic and/or non-metallic forms). The meaning of “metal” differs for various communities In addition, many elements, coating applications, solar plastic products and/or compounds that are not normally classified as metals become metallic under high pressures; these are formed as metallic allotropes of non-metals, synthetic metals, plastics, polymers, liquid polymers, liquid crystal polymers, liquid carbon polymers, composite gel polymers, multiscale structures, thin film, nanocrystalline ceramics, nanocrystalline coatings, perovskites, photovoltaic, photothermal and photoelectrochemical solar materials, silicon crystals, metal hydrides, amorphous metals.

Microcrystalline Cellulose (MCC) is known in the art as typically a purified, partially depolymerized cellulose that is prepared by treating alpha cellulose, in the form of a pulp manufactured from fibrous plant material, with mineral acids. See, e.g., U.S. Pat. No. 4,744,987, each entirely incorporated herein by reference. It is a generally white, odorless, tasteless, relatively free flowing powder that is generally insoluble in water, organic solvents, dilute alkalis and dilute acids. U.S. Pat. Nos. 2,978,446 to Battista et al. and 3,146,168 to Battista, each entirely incorporated herein by reference., describe microcrystalline cellulose and its manufacture; the latter patent concerns microcrystalline cellulose (MCC) for pharmaceutical applications. Microcrystalline Cellulose (MCC) can optionally include a term for refined wood pulp and is used as a texturizer, an anticaking agent, a fat substitute, an emulsifier, an extender, and a bulking agent in food production. The most common form is used in vitamin supplements or tablets. It is also used in plaque assays for counting viruses, as an alternative to carboxymethylcellulose. In many ways cellulose makes the ideal excipient A naturally occurring polymer, it is composed of glucose units connected by a 1-4 beta glucosidic bond. These linear cellulose chains are bundled together as microfibril spiraled together in the walls of plant cell. Each microfibril exhibits a high degree of three-dimensional internal bonding resulting in a crystalline structure that is insoluble in water and resistant to reagents. There are, however, relatively weak segments of the microfibril with weaker internal bonding. These are called amorphous regions; some argue that they are more accurately called dislocations, because of the single-phase structure of microfibrils. The crystalline region is isolated to produce microcrystalline cellulose. Microcrystalline Cellulose (MCC) can optionally include free-flowing crystalline powder (a non-fibrous microparticles). It is insoluble in water, dilute acids and most organic solvents, but slightly soluble in the alkali solution of 20%. It has a wide range of uses in the pharmaceutical excipients and can be directly used for tableting of dry powder. It is widely used as pharmaceutical excipients, flow aids, fillers, disintegrating agents, anti-sticking agents, adsorbents, and capsule diluents. Microcrystalline cellulose (MCC) is a pure product of cellulose depolymerization, an odorless and tasteless crystalline powder prepared from the natural cellulose.

Metallization can optionally refer to one of coating a covering applied an object's surface that improves surface properties; adhesion, resistance to corrosion or wear or scratches. Metallizing (also metalize) to coat, treat, or combine with a metal. Thermal spraying melted (or heated) materials are sprayed onto a surface. Vacuum deposition is a family of processes used to deposit layers as thin as one atom to millimeters thick in a vacuum. Vacuum metallizing the metallic coating of an object takes place in a vacuum chamber. Vacuum coating a mechanized process for applying coatings to lengths of materials. Transition of a nonmetal to a metallic substance due to a change of allotrope or closure of a bandgap, usually at very high pressures.

Metal Matrix Composite (MMC) is composite material with at least two constituent parts, one being a metal necessarily, the other material can optionally be a different metal or another material, such as a ceramic or organic compound. When at least three materials are present, it is called a hybrid composite. An MMC is complementary to a cermet. MMCs are made by dispersing a reinforcing material into a metal matrix. The reinforcement surface can be coated to prevent a chemical reaction with the matrix. For example, carbon fibers are commonly used in aluminum matrix to synthesize composites showing low density and high strength. However, carbon reacts with aluminum to generate a brittle and water-soluble compound Al₄C₃ on the surface of the fibre. To prevent this reaction, the carbon fibers are coated with nickel or titanium boride. The matrix is the monolithic material into which the reinforcement is embedded, and is completely continuous. This means that there is a path through the matrix to any point in the material, unlike two materials sandwiched together. In structural applications, the matrix is usually a lighter metal such as aluminum, magnesium, or titanium, and provides a compliant support for the reinforcement. In high-temperature applications, cobalt and cobalt-nickel alloy matrices are common. The reinforcement material is embedded into a matrix. The reinforcement does not always serve a purely structural task (reinforcing the compound), but is also used to change physical properties such as wear resistance, friction coefficient, or thermal conductivity. The reinforcement can be either continuous, or discontinuous. Discontinuous MMCs can be isotropic, and can be worked with standard metalworking techniques, such as extrusion, forging, or rolling. In addition, they can optionally be machined using conventional techniques, but commonly would need the use of polycrystaline diamond tooling (PCD). Continuous reinforcement uses monofilament wires or fibers such as carbon fiber or silicon carbide. Because the fibers are embedded into the matrix in a certain direction, the result is an anisotropic structure in which the alignment of the material affects its strength. One of the first MMCs used boron filament as reinforcement. Discontinuous reinforcement uses “whiskers”, short fibers, or particles. The most common reinforcing materials in this category are alumina and silicon carbide.

Microcrystalline Cellulose (MCC) is the most known cellulose, which extensively used in pharmaceutical industries. MCC grades are multifunctional pharmaceutical excipients, which can optionally be used as compressibility enhancer, binder in wet and dry granulation processes, thickener and viscosity builder in liquid dosage forms and free-flowing agents in solid dosage forms. Mechanical properties of MCC grades are greatly influenced by their particles size and degree of crystallization. In recent years the new grades of MCC are prepared with improved pharmaceutical characteristics such as silisified MCC (SMCC) and second-generation MCC grades or MCC type II (MCC-II). These grades are prepared by co-processing of cellulose with other substances such as colloidal silicon dioxide or by special chemical procedures. Other types of available pure cellulose are powdered cellulose (PC) and low crystallinity powdered cellulose (LCPC). Regenerated cellulose is one of the other forms of processed cellulose, which produced by chemical processing on natural cellulose. In the first step, cellulose dissolves in alkali and carbon disulfide to make a solution called “viscose.” Viscose reconverted to cellulose by passing through a bath of dilute sulfuric acid and sodium sulphate. Reconverted cellulose passed through several more baths for sulfur removing, bleaching and adding a plasticizer (glycerin) to form a transparent film called cellophane. Cellophane has several applications in pharmaceutical packaging due to its suitable characteristics such as good compatibility, durability, transparency and elasticity.

Microfluidics is a multidisciplinary field intersecting engineering, physics, chemistry, biochemistry, nanotechnology, and biotechnology, with practical applications to the design of systems in which small volumes of fluids will be handled. Microfluidics emerged in the beginning of the 1980s and is used in the development of inkjet print heads, DNA chips, lab-on-a-chip technology, micro-propulsion, and micro-thermal technologies. It deals with the behavior, precise control and manipulation of fluids that are geometrically constrained to a small, typically sub-millimeter, and scale. Typically, micro means one of the following features: small volumes (μL, nL, pL, fL), small size, low energy consumption, and effects of the micro domain. Typically fluids are moved, mixed, separated or otherwise processed. Numerous applications employ passive fluid control techniques like capillary forces. In some applications external actuation devices or methods are additionally used for a directed transport of the media. Examples are rotary drives applying centrifugal forces for the fluid transport on the passive chips.

Active Microfluidics refers to the defined manipulation of the working fluid by active (micro) components such as micro pumps or micro valves. Micro pumps supply fluids in a continuous manner or are used for dosing. Micro valves determine the flow direction or the mode of movement of pumped liquids. Often processes, which are normally carried out in a lab, are miniaturized on a single chip in order efficiency and mobility as well as reducing sample and reagent volumes.

Microcrystal line Cellulose (MCC) is particularly used because it contains cellulose, which is perhaps the most widely used fillers. Celluloses are biocompatible, chemically inert and have good-tablet forming and disintegrating properties. They are therefore used also as dry binders and disintegrants in tablets. Microcrystalline Cellulose is prepared by hydrolysis of cellulose is followed by spray drying. The particles thus formed are aggregates of smaller cellulose fibers. Hence, aggregates of different particles size can be prepared which have different flowablities. The flow properties of the material are generally good, and the direct compression characteristics are excellent. MCC is a unique diluent for producing cohesive compacts. The material also acts as a disintegrating agent. Microcrystalline cellulose (MCC) can be combined with nanocrystalline (NC) materials such as lubricants or disintegrants.

Monocrystalline Silicon (or “single-crystal silicon”, “single-crystal Si”, “mono c-Si”, or just mono-Si) is the base material for silicon chips used in virtually all electronic equipment today. Mono-Si also serves as photovoltaic, light-absorbing material in the manufacture of solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles. It has silicon in which the crystal lattice of the entire solid is continuous, unbroken to its edges, and free of any grain boundaries. Mono-Si can be prepared intrinsic, having only exceedingly pure silicon, or doped, containing very small quantities of other elements added to change its semiconducting properties. Most silicon monocrystals are grown by the Czochralski process into ingots of up to 2 meters in length and weighing several hundred kilogrammes. These cylinders are then sliced into thin wafers of a few hundred microns for further processing. Single-crystal silicon is perhaps the most important technological material of the last few decades—the “silicon era”, because its availability at an affordable cost has been essential for the development of the electronic devices on which the present day electronic and informatic revolution is based. Monocrystalline silicon differs from other allotropic forms, such as the non-crystalline amorphous—used in solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar film, and polycrystalline silicon, that has small crystals, also known as crystallites.

Nanocrystalline Cellulose (NCC) are solid-state systems constituting crystals of sizes less than 100 nm in at least one dimension. The understanding of the extraordinary behavior of nanostructured materials requires detailed studies of the correlations between the processing, structure, and properties. These studies rely on the identification and development of appropriate processing methods and suitable characterization methods and analytical tools for the nanocrystalline cellulose (NCC). This review has shown that PVD and CVD methods have the capability of producing nanophase materials. However, most of these vapor-processing techniques involve the use of a vacuum system and sophisticated deposition chamber. Therefore, the drawbacks of these vapor-processing techniques are the high production costs and the difficulty of fabricating nanophase materials cost effectively in large quantity. The recent development of novel and cost-effective vapor processing methods, especially those based on the aerosol and flame synthesis methods, offer cheaper alternatives to the conventional CVD and PVD techniques and can optionally widen the scope of commercial applications of vapor processing of nanostructured materials.

Nanocrystalline Cellulose (NCC) or Nanocrystalline (NC) Materials can be prepared in several ways. Methods are typically categorized based on the phase of matter the material transitions through before forming the nanocrystalline final product Solid-State Processing. Solid-state processes do not involve melting or evaporating the material and are typically done at relatively low temperatures. Examples of solid-state processes include mechanical alloying using a high-energy ball mill and certain types of severe plastic deformation processes. Liquid Processing. Nanocrystalline (NC) metals and alloys can be produced by rapid solidification from the liquid using a process such as melt spinning. This often produces an amorphous metal, which can be transformed into an NC metal by annealing above the crystallization temperature. Vapor-Phase Processing. Thin film of nanocrystalline (NC) materials can be produced using vapor deposition processes such as MOCVD. Solution processing. Some metals, particularly nickel and nickel alloys, can be made into nanocrystalline foils using electrode position. Nanocrystalline Cellulose (NCC) Material or Nanocrystalline (NC) Materials are a polycrystalline material with a crystallite size of only a few nanometers. These materials fill the gap between amorphous materials without any long-range order and conventional coarse-grained materials. Definitions vary, but nanocrystalline material is commonly defined as a crystallite (grain) size below 100 nm. Grain sizes from 100-500 nm are typically considered “ultrafine” grains. The grain size of a NC sample can be estimated using x-ray diffraction. In materials with very small grain sizes, the diffraction peaks will be broadened. This broadening can be related to a crystallite size using the Scherrer equation (applicable up to ˜50 nm), a Williamson-Hall plot, or more sophisticated methods such as the Warren-Averbach method or computer modeling of the diffraction pattern. The crystallite size can be measured directly using microscopy. Nanocrystalline Cellulose (NCC) or Nanocrystalline (NC) Materials are single or multi-phase polycrystalline solids with a grain size of a few nanometers (1 nm=10-9 m=10 Å), typically less than 100 nm. Since the grain sizes are so small, a significant volume of the microstructure in nanocrystalline (NC) materials is composed of interfaces, mainly grain boundaries, i.e., a large volume fraction of the atoms resides in grain boundaries. Consequently, nanocrystalline (NC) materials exhibit properties that are significantly different from, and often improved over, their conventional coarse-grained polycrystalline counterparts. Materials with microstructural features of nanometric dimensions are referred to in the literature as nanocrystalline (NC) materials (a very generic term), nanocrystals, nanostructured materials, nanophase materials, nanometer-sized crystalline solids, or solids with nanometer-sized microstructural features. Nanostructured solids is perhaps the most accurate description, even though nanocrystalline (NC) materials will be the appropriate term if one is dealing with solids with grains made up of crystals. Nanocrystalline (NC) materials can be classified into different categories depending on the number of dimensions in which the material has nanometer modulations. Thus, they can be classified into (a) layered or lamellar structures, (b) filamentary structures, and (c) equiaxed nanostructured materials. A layered or lamellar structure is a one-dimensional (1D) nanostructure in which the magnitudes of length and width are much greater than the thickness that is only a few nanometers in size. One can also visualize a two-dimensional (2D) rod-shaped nanostructure that can be termed filamentary and in this the length is substantially larger than width or diameter, which are of nanometer dimensions. The most common of the nanostructures, however, is basically equiaxed (all the three dimensions are of nanometer size) and are termed nanostructured crystallites (three-dimensional [3D] nano structures). The nanostructured materials can optionally contain crystalline, quasicrystalline, or amorphous phases and can be metals, solar ceramic products, polymers, liquid polymers, liquid crystal polymers, liquid carbon polymers, composite gel polymers, or composites. If the grains are made up of crystals, the material is called nanocrystalline. On the other hand, if they are made up of quasicrystalline or amorphous (glassy) phases, they are termed nanoquasicrystals and nanoglasses, respectively. Nanocrystalline (NC) materials can be synthesized either by consolidating small clusters or breaking down the bulk material into smaller and smaller dimensions. Synthesized nano crystalline materials can optionally be with the inert gas condensation technique to produce nanocrystalline powder particles and consolidated them in situ into small disks under ultra-high vacuum (UHV) conditions. Since then a number of techniques have been developed to prepare nanostructured materials starting from the vapor, liquid, or solid states. Nanostructured materials have been synthesized in recent years by methods including inert gas condensation, mechanical alloying, spray conversion processing, severe plastic deformation, electrode position, rapid solidification from the melt, physical vapor deposition, chemical vapor processing, co-precipitation, sol-gel processing, sliding wear, spark erosion, plasma processing, auto-ignition, laser ablation, hydrothermal pyrolysis, thermophoretic forced flux system, quenching the melt under high pressure, biological templating, sonochetnical synthesis, and devitrification of amorphous phases. Actually, in practice any method capable of producing very fine grain-sized materials can optionally be used to synthesize nanocrystalline (NC) materials. The grain size, morphology, and texture can be varied by suitably modifying/controlling the process variables in these methods. Each of these methods has advantages and disadvantages and one should choose the appropriate method depending upon the requirements. If a phase transformation is involved, e.g., liquid to solid or vapor to solid, then steps need to be taken to increase the nucleation rate and decrease the growth rate during formation of the product phase. In fact, it is this strategy that is used during devitrification of metallic glasses to produce nano crystalline materials.

Nanocellulose is a term referring to nano-structured cellulose. This may be either cellulose nanofibers (CNF) also called microfibrillated cellulose (MFC), nanocrystalline cellulose (NCC), or bacterial nanocellulose, which refers to nano-structured cellulose produced by bacteria. CNF is a material composed of nanosized cellulose fibrils with a high aspect ratio (length to width ratio). Typical lateral dimensions are 5-20 nanometers and longitudinal dimension is in a wide range, typically several micrometers. It is pseudo-plastic and exhibits the property of certain gels or fluids that are thick (viscous) under normal conditions, but flow (become thin, less viscous) over time when shaken, agitated, or otherwise stressed. This property is known as thixotropy. When the shearing forces are removed the gel regains much of its original state. The fibrils are isolated from any cellulose containing source including wood-based fibers (pulp fibers) through high-pressure, high temperature and high velocity impact homogenization, grinding or microfluidization (see manufacture below). Nanocellulose can also be obtained from native fibers by an acid hydrolysis, giving rise to highly crystalline and rigid nanoparticles (often referred to as CNC or nanowhiskers), which are shorter (100 s to 1000 nanometers) than the nanofibrils obtained through the homogenization, microfluiodization or grinding routes. The resulting material is known as nanocrystalline cellulose (NCC).

Nano Flake is a type of semiconductor nanostructure with potential uses for solar energy creation. The crystalline structure of the flakes allows the crystals to absorb all light, potentially allowing a higher energy conversion rate than more common silicon semiconductor technology.

Nanocomposite is a multiphase solid material where one of the phases has one, two or three dimensions of less than 100 nanometers (run), or structures having nano-scale repeat distances between the different phases that make up the material. In the broadest sense this definition can include porous media, colloids, gels and polymers, liquid polymers, liquid crystal polymers, liquid carbon polymers, composite gel polymers, but is more usually taken to mean the solid combination of a bulk matrix and nano-dimensional phase(s) differing in properties due to dissimilarities in structure and chemistry. The mechanical, electrical, thermal, optical, electrochemical, catalytic properties of the nanocomposite will differ markedly from that of the component materials. Size limits for these effects have been proposed, <5 nm for catalytic activity, <20 nm for making a hard magnetic material soft, <50 nm for refractive index changes, and <100 nm for achieving superparamagnetism, mechanical strengthening or restricting matrix dislocation movement. Nanocomposites are found in nature, for example in the structure of the abalone shell and bone. The use of nanoparticle-rich materials long predates the understanding of the physical and chemical nature of these materials. In mechanical terms, nanocomposites differ from conventional composite materials due to the exceptionally high surface to volume ratio of the reinforcing phase and/or its exceptionally high aspect ratio. The reinforcing material can be made up of particles (e.g. minerals), sheets (e.g. exfoliated clay stacks) or fibers (e.g. carbon nanotubes or electrospun fibers). The area of the interface between the matrix and reinforcement phase(s) is typically an order of magnitude greater than for conventional composite materials. The matrix material properties are significantly affected in the vicinity of the reinforcement Ajayan et al. note that with polymer nanocomposites, properties related to local chemistry, degree of thermoset cure, polymer chain mobility, polymer chain conformation, degree of polymer chain ordering or crystallinity can all vary significantly and continuously from the interface with the reinforcement into the bulk of the matrix. This large amount of reinforcement surface area means that a relatively small amount of nanoscale reinforcement can have an observable effect on the macroscale properties of the composite. For example, adding carbon nanotubes improves the electrical and thermal conductivity. Other kinds of nanoparticulates can optionally result in enhanced optical properties, dielectric properties, thermal resistance or mechanical properties such as stiffness, strength and resistance to wear and damage. In general, the nano reinforcement is dispersed into the matrix during processing. The percentage by weight (called mass fraction) of the nanoparticulates introduced can remain very low (on the order of 0.5% to 5%) due to the low filler percolation threshold, especially for the most commonly used non-spherical, high aspect ratio fillers (e.g. nanometer-thin platelets, such as clays, or nanometer-diameter cylinders, such as carbon nanotubes). The orientation and arrangement of asymmetric nanoparticles, thermal property mismatches at the interface, interface density per unit volume of nanocomposite, and polydispersity of nanoparticles significantly affect the effective thermal conductivity of nanocomposites.

Nanocrystalline (NC) or a nanocrystalline (NC) material is a polycrystalline material with a crystallite size of only a few nanometers. These materials fill the gap between amorphous materials without any long range order and conventional coarse-grained materials. Definitions vary, but nanocrystalline material is commonly defined as a crystallite (grain) size below 100 nm. Grain sizes from 100-500 nm are typically considered “ultrafine” grains. The grain size of a NC sample can be estimated using x-ray diffraction. In materials with very small grain sizes, the diffraction peaks will be broadened. Nanocrystalline materials can be prepared in several ways. Methods are typically categorized based on the phase of matter the material transitions through before forming the nanocrystalline final product Solid-state processing. Solid-state processes do not involve melting or evaporating the material and are typically done at relatively low temperatures. Examples of solid state processes include mechanical alloying using a high-energy ball mill and certain types of severe plastic deformation processes. Liquid processing. Nanocrystalline metals can be produced by rapid solidification from the liquid using a process such as melt spinning. This often produces an amorphous metal, which can be transformed into an nc metal by annealing above the crystallization temperature. Vapor-phase processing. Thin films of nanocrystalline materials can be produced using vapor deposition processes such as MOCVD. Solution processing. Some metals, particularly nickel and nickel alloys, can be made into nanocrystalline foils using electrodeposition.

Nanocrystal Solar cells are optionally solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles based on a substrate with a coating of nanocrystals, which can be solid or liquid nanocrystals. The nanocrystals are typically based on silicon, CdTe or CIGS and the substrates are generally silicon or various organic conductors. Quantum dot solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles are a variant of this approach, but take advantage of quantum mechanical effects to extract further performance. Dye-sensitized solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles are another related approach, but in this case the nano-structuring is part of the substrate. Previous fabrication methods relied on expensive molecular beam epitaxy processes, but colloidal synthesis allows for cheaper manufacture. A thin film of nanocrystals is obtained by a process known as “spin-coating.” This involves placing an amount of the quantum dot solution onto a flat substrate, which is then rotated very quickly. The solution spreads out uniformly, and the substrate is spun until the required thickness is achieved. Quantum dot based photovoltaic cells based on dye-sensitized colloidal TiO₂ films were investigated in 1991 and were found to exhibit promising efficiency of converting incident light energy into electrical current, and to be incredibly encouraging due to the low cost of materials used. A single-nanocrystal (channel) architecture in which an array of single particles between the electrodes, each separated by ˜1 exciton diffusion length, was proposed to improve the device efficiency and research on this type of solar cell is being conducted by groups at Stanford, Berkeley and the University of Tokyo. Although research is still in its infancy, in the future nanocrystal photovoltaics may offer advantages such as flexibility (quantum dot-polymer composite photovoltaics) lower costs, clean power generation and an efficiency of 65%, compared to around 20 to 25% for first-generation, crystalline silicon-based photovoltaics. It is argued that many measurements of the efficiency of the nanocrystal solar cell are incorrect and that nanocrystal solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles are not suitable for large scale manufacturing. Recent research has experimented with lead selenitic (PbSe) semiconductor, as well as with cadmium telluride photovoltaics (CdTe), which has already been well established in the production of second-generation thin film solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles.

Nanomaterials are experiencing a rapid development in recent years due to their existing and/or potential applications in a wide variety of technological areas such as electronics, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, flexible solar products, flexible nanoproducts, flexible electronic solar energy displays, flexible solar energy devices, solar energy batteries, solar energy consumer products, solar powered products for the home, solar magnetic data storage, solar powered telecommunication and data communication components, etc. To meet the technological demands in these areas, the size of the materials should be reduced to the nanometer scale. For example, the miniaturization of functional electronic devices demands the placement or assembly of nanometer scale components into well-defined nanostructures. As the size reduces into the nanometer range, the materials exhibit peculiar and interesting mechanical and physical properties, e.g. increased mechanical strength, enhanced diffusivity, higher specific thermal and electrical resistivity compared to conventional coarse grained counterparts. Nanomaterials can be classified into nanocrystalline (NC) materials and nanoparticles. The former are polycrystalline bulk materials with grain sizes in the nanometer range (less than 100 run), while the latter refers to ultrafine dispersive particles with diameters below 100 nm. Nanoparticles are generally considered as the building blocks of bulk nanocrystalline (NC) materials.

Nanocrystalline Silver (NCS) has proven to be an important wound dressing particularly in chronic infected wounds. However, debate still rages around its use in the case of partially epithelialized wounds, particularly when these are non-infected. Much of the debate has revolved around seemingly contradictory research publications that blurred the use of NCS in these clinical situations, primarily based on reported cytotoxic effects of NCS on cell lines in vitro. MMPs, in particular MMP-9 (gelatinase) have been demonstrated to be pivotal in the progression from keratinocyte cleavage, to migration and re-epithelialisation. High levels promote increases in TNF-α; IL-8 and TGFβ, all associated with exaggerated ongoing inflammation and chronicity. Low levels impede the process of keratinocyte migration. Thus, as in so many clinical situations, a balance of MMP level is extremely important NCS has been demonstrated to decrease these undesirable high levels of MMP-9 making it an ideal dressing for chronic infected wounds, acute inflamed wounds and burn wounds of all types which are associated with protracted raised MMP-9 levels. The converse applies too—NCS used in a situation of minimal inflammation can optionally undesirably decrease the low levels of MMP-9 and adversely affect epithelialisation. NCS would be contra-indicated in conjunction with cell lines in vitro, cell cultured lines in vivo and integrated artificial matrices with added cell lines.

Nanocrystalline (NC) Silicon (nc-Si), sometimes also known as microcrystalline silicon (μc-Si), is a form of porous silicon. It is an allotropic form of silicon with paracrystalline structure—is similar to amorphous silicon (a-Si), in that it has an amorphous phase. Where they differ, however, is that nc-Si has small grains of crystalline silicon within the amorphous phase. This is in contrast to polycrystalline silicon (poly-Si), which is solely of crystalline silicon grains, separated by grain boundaries. The difference comes solely from the grain size of the crystalline grains. Most materials with grains in the micrometer range are actually fine-grained polysilicon, so nanocrystalline (NC) silicon is a better term. The term nanocrystalline (NC) silicon refers to a range of materials around the transition region from amorphous to microcrystalline phase in the silicon thin film. The crystalline volume fraction (as measured from Raman spectroscopy) is another criterion to describe the materials in this transition zone. nc-Si has many useful advantages over a-Si, one being that if grown properly it can have a higher electron mobility, due to the presence of the silicon crystallites. It also shows increased absorption in the red and infrared wavelengths, which make it an important material for use in a-Si solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles. One of the most important advantages of nanocrystalline (NC) silicon, however, is that it has increased stability over a-Si, one of the reasons being because of its lower hydrogen concentration. Although it currently cannot attain the mobility that poly-Si can, it has the advantage over poly-Si that it is easier to fabricate, as it can be deposited using conventional low temperature a-Si deposition techniques, such as PECVD, as opposed to laser annealing or high temperature CVD processes, in the case of poly-Si.

Nanocrystalline Thin film Solar Cell (TFSC) is also called a thin film photovoltaic cell (TFPV), is a second generation solar cell that is made by depositing one or more thin layers, or thin film (TF) of photovoltaic material on a substrate, such as glass, plastic or metal. Thin film solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles are commercially used in several technologies, including cadmium telluride (CdTe), copper indium gallium diselenide (CIGS), and amorphous and other thin film (a-Si, TF-Si). Film thickness varies from a few nanometers (run) to tens of micrometers (μm), much thinner than thin film's rival technology, the conventional, first-generation crystalline silicon solar cell (c-Si), that uses silicon wafers of up to 200 μm. This allows thin film cells to be flexible, lower in weight, and have less drag. It is used in building integrated photovoltaics and as semi-transparent, photovoltaic glazing material that can be laminated onto windows. Other commercial applications use rigid thin film solar panels (sandwiched between two panes of glass) in some of the world's largest photovoltaic power stations. Thin film has always been cheaper but less efficient than conventional c-Si technology. However, they significantly improved over the years, and lab cell for CdTe and CIGS are now beyond 21%, outperforming multicrystalline silicon, the dominant material currently used in most solar PV systems. Despite these enhancements, market-share of thin film never reached more than 20% in the last two decades and has been declining in recent years to about 9% of worldwide photovoltaic production in 2013. Other thin film technologies, that are still in an early stage of ongoing research or with limited commercial availability, are often classified as emerging or third generation photovoltaic cells and include, organic, dye-sensitized, and solar glass, solar windows, solar fuel, solar powered fuel cells, solar powered gadgets, solar powered roof tiles, solar powered shingles, solar powered roadways, solar film, as well as

Nanocrystalline ZnO Thin Film. Nanocrystalline ZnO thin film can optionally be used as filters to purify liquids for water purification and making saltwater drinkable via evaporation of Zn metal on a glass sheet following by calcination (oxidation) process for photocatalytic purification of water. The influences of calcination parameters such as temperature and time on the surface morphology and phase structure of ZnO films were investigated by scanning electron microscopy (SEM) and X-ray diffraction (XRD), respectively. The analysis of XRD patterns indicated that the growth of ZnO nano-structure was controlled by calcination time and temperature. Optimum ZnO nano-fibers can be formed uniformly after 2 h of oxidation at 550° C. Nanostructured ZnO catalyst exhibited a significantly greater superiority for the photodegradation of 2,4,6-Trichlorophenol (TCP) as a model pollutant in water over photolysis via irradiation with UV of 254 nm wavelength.

Nanocellulose Dimensions and Crystallinity can optionally include an ultrastructure of cellulose derived from various sources has been extensively studied. Techniques such as transmission electron microscopy (TEM), scanning electron microscopy (SEM), atomic force microscopy (AFM), wide angle X-ray scattering (WAXS), small incidence angle X-ray diffraction and solid state C cross-polarization magic angle spinning (CP/MAS) nuclear magnetic resonance (NMR) spectroscopy have been used to characterize nanocellulose morphology. These methods have typically been applied for the investigation of dried nanocellulose morphology. Although a combination of microscopic techniques with image analysis can provide information on nanocellulose fibril widths, it is more difficult to determine nanocellulose fibril lengths because of entanglements and difficulties in identifying both ends of individual nanofibrils. It has been reported that nanocellulose suspensions can optionally not be homogeneous and that they are of various structural components for making solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, thin film coating applications as a semiconductor nanostructure for thin film solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, including cellulose nanofibrils and nanofibril bundles. Most methods have typically been applied to investigation of dried nanocellulose dimensions, although a study was conducted where the size and size-distribution of enzymatically pre-treated nanocellulose fibrils in a suspension was studied using cryo-TEM. The fibrils were found to be rather mono-dispersed mostly with a diameter of ca. 5 nm although occasionally thicker fibril bundles were present. It should be noted that, some newly published results indicated that by combining ultrasonication with an “oxidation pretreatment,” cellulose microfibrils with a lateral dimension that belows 1 nm is observed by AFM. The lower end of the thickness dimension is around 0.4 nm, which is related to the thickness of a cellulose monolayer sheet. The aggregate widths can be determined by CP/MAS NMR developed by Innventia AB, Sweden, which also has been demonstrated to work for nanocellulose (enzymatic pre-treatment). An average width of 17 nm has been measured with the NMR-method, which corresponds well with SEM and TEM. Using TEM, values of 15 nm have been reported for nanocellulose from carboxymethylated pulp. However, also thinner fibrils can be detected. Wågberg et al. reported fibril widths of 5-15 nm for a nanocellulose with a charge density of about 0.5 meq./g. The group of Isogai reported fibril widths of 3-5 nm for TEMPO-oxidized cellulose having a charge density of 1.5 meq./g. The influence of cellulose pulp chemistry on the nanocellulose microstructure has been investigated using AFM to compare the microstructure of two types of nanocellulose prepared at Innventia AB (enzymatically pre-treated nanocellulose and carboxymethylated nanocellulose). Due to the chemistry involved in producing carboxymethylated nanocellulose, it differs significantly from the enzymatically pre-treated one. The carboxymethylation pre-treatment makes the fibrils highly charged and, hence, easier to liberate, which results in smaller and more uniform fibril widths (5-15 nm) compared to the enzymatically pre-treated nanocellulose, where the fibril widths were 10-30 nm. The degree of crystallinity and the cellulose crystal structure of nanocellulose were also studied at the same time. The results clearly showed the nanocellulose exhibited cellulose crystal I organization and that the degree of crystallinity was unchanged by the preparation of the nanocellulose. Typical values for the degree of crystallinity were around 63%. Viscosity. The unique rheology of nanocellulose dispersions was recognized by the early investigators. The high viscosity at low nanocellulose concentrations makes nanocellulose very interesting as a non-caloric stabilizer and gellant in food applications, the major field explored by the early investigators. The dynamic rheological properties were investigated in great detail and revealed that the storage and loss modulus were independent of the angular frequency at all nanocellulose concentrations between 0.125% to 5.9% The storage modulus values are particularly high (104 Pa at 3% concentration) compared to results for other cellulose nanowhiskers (102 Pa at 3% concentration). There is also a particular strong concentration dependence as the storage modulus increases 5 orders of magnitude if the concentration is increased from 0.125% to 5.9% Nanocellulose gels are also highly shear thinning (the viscosity is lost upon introduction of the shear forces). The shear-thinning behavior is particularly useful in a range of different coating applications. Mechanical Properties. Crystalline cellulose has interesting mechanical properties for use in material applications. Its tensile strength is about 500 MPa, similar to that of aluminum. Its stiffness is about 140-220 GPa, comparable with that of Kevlar and better than that of glass fiber, both of which are used commercially to reinforce plastics. Films made from nanocellulose have high strength (over 200 MPa), high stiffness (around 20 GPa) and high strain (12%). Its strength/weight ratio is 8 times that of stainless steel. Barrier Properties. In semi-crystalline polymers, liquid polymers, liquid crystal polymers, liquid carbon polymers, composite gel polymers, the crystalline regions are considered to be gas impermeable. Due to relatively high crystallinity, in combination with the ability of the nanofibers to form a dense network held together by strong inter-fibrillar bonds (high cohesive energy density), it has been suggested that nanocellulose might act as a barrier material. Although the number of reported oxygen permeability values are limited, reports attribute high oxygen barrier properties to nanocellulose films. One study reported an oxygen permeability of 0.0006 (cm³ μm)/(m² day kPa) for a ca. 5 μm thin nanocellulose film at 23° C. and 0% RH. In a related study, a more than 700-fold decrease in oxygen permeability of a polylactide (PLA) film when a nanocellulose layer was added to the PLA surface was reported. The influence of nanocellulose film density and porosity on film oxygen permeability has recently been explored. Some authors have reported significant porosity in nanocellulose films, which seems to be in contradiction with high oxygen barrier properties, whereas Aulin et al. measured a nanocellulose film density close to density of crystalline cellulose (cellulose IB crystal structure, 1.63 g/cm³) indicating a very dense film with a porosity close to zero. Changing the surface functionality of the cellulose nanoparticles can also affect the permeability of nanocellulose films. Films constituted of negatively charged cellulose nanowhiskers could effectively reduce permeation of negatively charged ions, while leaving neutral ions virtually unaffected. Positively charged ions were found to accumulate in the membrane. Foams. Nanocellulose can optionally be used to make aerogels/foams, either homogeneously or in composite formulations. Nanocellulose-based foams are being studied for packaging applications in order to replace polystyrene-based foams. Svagan et al. showed that nanocellulose has the ability to reinforce starch foams by using a freeze-drying technique. The advantage of using nanocellulose instead of wood-based pulp fibers is that the nanofibrills can reinforce the thin cells in the starch foam. Moreover, it is possible to prepare pure nanocellulose aerogels applying various freeze-drying and super critical CO drying techniques. Aerogels and foams can optionally be used as porous templates. A wide range of mechanical properties including compression was obtained by controlling density and nanofibrill interaction in the foams. Cellulose nanowhiskers could also be made to gel in water under low power sonication giving rise to aerogels with the highest reported surface area (>600 m2/g) and lowest shrinkage during drying (6.5%) of cellulose aerogels. In another study by Aulin et al., the formation of structured porous aerogels of nanocellulose by freeze-drying was demonstrated. The density and surface texture of the aerogels was tuned by selecting the concentration of the nanocellulose dispersions before freeze-drying. Chemical vapor deposition of a fluorinated silane was used to uniformly coat the aerogel to tune their wetting properties towards non-polar liquids/oils. It is possible to switch the wettability behavior of the cellulose surfaces between super-wetting and super-repellent, using different scales of roughness and porosity created by the freeze-drying technique and change of concentration of the nanocellulose dispersion. Structured porous cellulose foams can however also optionally be obtained by utilizing the freeze-drying technique on cellulose generated by Gluconobacter strains of bacteria, which bio-synthesize open porous networks of cellulose fibers with relatively large amounts of nanofibrills dispersed inside. Olsson et al. demonstrated that these networks can be further impregnated with metalhydroxide/oxide precursors, which can readily be transformed into grafted nanoparticles along the cellulose nanofibers. The magnetic cellulose foam can optionally allow for a number of novel applications of nanocellulose and the first remotely actuated magnetic super sponges absorbing 1 gram of water within a 60 mg cellulose aerogel foam were reported. Notably, these highly porous foams (>98% air) can be compressed into strong magnetic nanopapers, which can optionally find use as functional membranes in various applications.

Plasmonic Solar cells are a class of photovoltaic devices that convert light into electrical current by using plasmons. Plasmonic solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles are a type of thin film solar cell, which are typically 1-2 μm thick. They can use substrates, which are cheaper than silicon, such as glass, plastic or steel. The biggest problem for thin film solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles is that they don't absorb as much light as thicker solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles. Methods for trapping light are crucial in order to make thin film solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles viable. Plasmonic cells improve absorption by scattering light using metal nanoparticles excited at their surface plasmon resonance. This allows light to be absorbed more directly without the relatively thick additional layer required in other types of thin film solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles.

Plasmonic Nanoparticles are particles whose electron density can couple with electromagnetic radiation of wavelengths that are far larger than the particle due to the nature of the dielectric-metal interface between the medium and the particles: unlike in a pure metal where there is a maximum limit on what size wavelength can be effectively coupled based on the material size. What differentiates these particles from normal surface plasmons is that plasmonic nanoparticles also exhibit interesting scattering, absorbance, and coupling properties based on their geometries and relative positions. These unique properties have made them a focus of research in many applications including solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, spectroscopy, signal enhancement for imaging, and cancer treatment Plasmons are the oscillations of free electrons that are the consequence of the formation of a dipole in the material due to electromagnetic waves. The electrons migrate in the material to restore its initial state; however, the light waves oscillate, leading to a constant shift in the dipole that forces the electrons to oscillate at the same frequency as the tight. This coupling only occurs when the frequency of the tight is equal to or less than the plasma frequency and is greatest at the plasma frequency that is therefore called the resonant frequency. The scattering and absorbance cross-sections describe the intensity of a given frequency to be scattered or absorbed. Many fabrication processes exist for fabricating such nanoparticles, depending on the desired size and geometry. The nanoparticles can form clusters to form plasmonic molecules and interact with each other to form cluster states. The symmetry of the nanoparticles and the distribution of the electrons within them can affect a type of bonding or antibonding character between the nanoparticles similarly to molecular orbitals. Since light couples with the electrons, polarized light can be used to control the distribution of the electrons and alter the mulliken term symbol for the irreducible representation. Changing the geometry of the nanoparticles can be used to manipulate the optical activity and properties of the system, but so can the polarized light by lowering the symmetry of the conductive electrons inside the particles and changing the dipole moment of the cluster. These clusters can be used to manipulate light on the nano scale.

Cellulose Applications.

Activate the dissolution of cellulose in different solvents, regenerated cellulose products, such as fibers films, cellulose derivatives, tobacco filter additive, organometallic modified nanocellulose in battery separators, reinforcement of conductive materials, loud-speaker membranes, high-flux membrane, solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, flexible solar products, flexible nano solar energy products, flexible electronic solar energy display s, flexible solar energy devices, computer components, lightweight body armor and ballistic glass.

Wood Pulp.

Nanocellulose/CNF or NCC can be prepared from any cellulose source material, but wood pulp is normally used. The nanocellulose fibrils can optionally be isolated from the wood-based fibers using mechanical methods, which expose the pulp to high shear forces, ripping the larger wood-fibers apart into nanofibers. For this purpose high-pressure homogenizers, ultrasonic homogenizers, grinders or microfluidizer. The homogenizers are used to delaminate the cell walls of the fibers and liberate the nanosized fibrils. This process is responsible for the high-energy consumptions associated with the fiber delamination. Values over 30 MWh/tonne are not uncommon. Pre-treatments are sometimes used to address this problem. Examples of such pre-treatments are enzymatic/mechanical pre-treatment and introduction of charged groups e.g. through carboxymethylation or TEMPO-mediated oxidation. Cellulose nanowhiskers, a more crystalline form of nanocellulose, are formed by the acid hydrolysis of native cellulose fibers commonly using sulfuric or hydrochloric acid. The amorphous sections of native cellulose are hydrolysed and after careful timing, the crystalline sections can be retrieved from the acid solution by centrifugation and washing. Cellulose nanowhiskers are rod like highly crystalline particles (relative crystallinity index above 75%) with a rectangular cross section. Their dimensions depend on the native cellulose source material, and hydrolysis time and temperature.

Nanocrystalline Powder.

Consolidation of nanocrystalline powders can optionally be achieved by electrodischarge compaction, plasma-activated sintering, shock (explosive) consolidation, hot-isostatic pressing (HIP), Ceracon processing (the Ceracon process (CERAmic CONsolidation) involves taking a heated preform and consolidating the material by pressure against a granular ceramic medium using a conventional forging press), hydrostatic extrusion, strained powder rolling, and sinter forging. By utilizing the combination of high temperature and pressure, HIP can achieve a particular density at lower pressure when compared to cold isostatic pressing or at lower temperature when compared to sintering. It should be noted that because of the increased diffusivity in nanocrystalline (NC) materials, nanocrystalline (NC) components, sintering ((falsification) takes place at temperatures much lower than in coarse-grained materials. This is likely to reduce the grain growth. Nanocrystalline (NC) materials have been shown to exhibit increased strength/hardness, enhanced diffusivity, reduced density, higher electrical resistivity, increased specific thermal, higher coefficient of thermal expansion, lower thermal conductivity, insulation, and superior soft magnetic properties in comparison to their coarse-grained counterparts. But, subsequent careful investigations on fully dense nanocrystalline ma-C. Suryanarayana, C.C. Koch/Nanocrystalline (NC) materials, nanocrystalline (NC) components, e.g., those produced by electrodeposition methods, have indicated that at least some of the “significant” changes in these properties could be attributed to the presence of porosity, cracks, and other discontinuities in the processed materials. Thus, it becomes important to obtain fully dense materials while simultaneously retaining nanometer-sized grains to unambiguously demonstrate the improvement in properties due to nanostructure processing.

Nanotechnology or Nanorobotics is the technology field creating machines or robots whose components are at or close to the scale of ananometer (10⁹ meters). More specifically, nanorobotics refers to the nanotechnology engineering discipline of designing and/or other building nanorobots, with devices ranging in size from 0.1-10 micrometers and/or constructed of nanoscale or molecular components.

Nanobots, nanoids, nanites, nanomachines or nanomites have also been used to describe these devices currently under research and/or development. Another definition is a robot that allows precision communications with nanoscale objects, or can optionally manipulate with nanoscale resolution. Such devices are more related to microscopy or scanning probe microscopy, instead of the description of nanorobots as molecular machine. Following the microscopy definition even a large apparatus such as an atomic force microscope can optionally be considered a nanorobotic instrument when configured to perform nanomanipulation. For this perspective, macroscale robots or microrobots that can optionally move with nanoscale precision can optionally also be considered nanorobots. Nanotechnology can optionally be used for the detection of diseases and/or conditions.

Nanostructure, a non-limiting example of a nanostructure is a structure of intermediate size between microscopic and molecular structures. Nanostructural detail is microstructure at nanoscale. In describing nanostructures it is necessary to differentiate between the number of dimensions on a thenanoseale. Nanotextured surfaces have one dimension on the nanoscale, i.e., only the thickness of the surface of an object is between 0.1 and 100 nm. Carbon nanotubes have two dimensions on the nanoscale. i.e., the diameter of the tube is between 0.1 and 100 nm: its length could be much greater. Finally, spherical nanoparticles have three dimensions on the nanoscale, i.e., the particle is between 0.1 and 100 nm in each spatial dimension. The terms nanoparticles and ultrafinc particles (UFP) often are used synonymously although UFP can reach into the micrometre range. The term ‘nanostructure’ is often used when referring to magnetic technology. Nanoscale structure in biology is often called ultrastructure.

Nanocrystalline Coating Applications. The deposition of ultra hard nanocrystalline (NC) coating applications based on titanium nitride by a vacuum arc method with plasma assistance, investigations of their structural features, physical and mechanical properties are presented. The materials of the evaporated cathode were the sintered Ti—Al and Ti—Cu system materials. It should be noted that one of the chosen additional elements (Al) forms nitride compounds, and another (Cu) doesn't form that at the conditions of coating synthesis. Obtaining of experimental data for explanation of formation model of ultra hard nanocrystalline (NC) coating applications based on titanium nitride at addition of different elements in their structure was the main purpose of work. For achievement of that the methods such as the scanning electron microscopy, transmission electron microscopy, Auger spectrometry, the X-ray fluorescent and X-ray diffraction analysis with the use of synchrotron radiation were used. In addition the experimental results on research of near-edge fine structure of X-ray absorption spectrum (X-ray Absorption Near-Edge Structure, XANES) and extended fine structure of X-ray absorption (Extended X-ray Absorption Fine Structure, EXAFS) in the field of K-edge of titanium absorption in the samples of titanium nitride coating applications at copper and aluminum addition are also presented. Transmission electron diffraction microscopy and X-ray diffraction analysis with the use of synchrotron radiation has revealed the fact that ultra hard (NC) Ti—Cu—N coating of randomly oriented nanocrystallites of the main phase δ-TiN. The average size of crystallites of the main phase is d=18 nm. The presence of crystal phases of copper in the coating applications wasn't observed. But by the X-ray fluorescent analysis the availability of copper in the coating with concentration of 12 at. % was revealed. That corresponds to concentration of additional element in the evaporated cathode. The carried-out measurements of XAFS spectrum confirm that atoms of copper are concentrated in the fine films limiting the sizes of TiN crystallites and don't possess the regular structure. For the first time it was succeeded to directly show the main role of an additional element in formation of nanocrystalline structure of coating applications based on titanium nitride as the result of the complex experiment researches. According to the model nanocrystallization in Ti—Cu—N coating is due to the added atoms (Cu), which form an amorphous sheath with thickness of 2-3 monolayers (0.74 nm) around TiN grains that restrict the grain growth. Experimental data about structure of coating applications based on TiN with aluminum addition in synthesized coating applications of Ti—Al—N by vacuum arc deposition with plasma assistance have been obtained by transmission electron microscopy and X-ray powder diffraction with a synchrotron radiation. These testified that the coating applications have multiphase structure, which depends on modes of coating deposition. Thus the processes of formation and breakdown of crystallographic phases in synthesized Ti—Al—N coating applications are non-equilibrium, thereof the main crystallographic phase of areas of coherent dispersion-TiN, and area of localization of crystallographic phases of aluminum nitride and the intermetallic phases of AlTi-boundaries of the main phase of a coating.

Nanocrystalline (NC) Material is a polycrystalline material with a crystallite size of only a few nanometers. These materials fill the gap between amorphous materials without any long range order and/or conventional coarse-grained materials. Definitions vary, but nanocrystalline material is commonly defined as a crystallite (grain) size below 100 nm. Grain sizes from 100-500 nm are typically considered “ultrafine” grains. The grain size of a NC sample can optionally be estimated using x-ray diffraction. In materials with very small grain sizes, the diffraction peaks can optionally be broadened. This broadening can optionally be related to a crystallite size using the Scherrer equation (applicable up to ˜50 nm), a Williamson-Hall plot, or more sophisticated methods such as the Warren-Averbach method or computer modeling of the diffraction pattern. The crystallite size can optionally be measured directly using transmission electron microscopy. Other properties of nanocrystalline (NC) metals and alloys, apart from increased strength and/or hardness, including higher electrical resistance, increased specific thermal capacity, thermal expansion, tensile strength or hardness, ductility & toughness, electrical properties, magnetic and chemical properties, absorption properties, catalytic properties, barrier properties, nanocrystalline cores for solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices.

Nanocrystals can optionally include a material product having at least one dimension smaller than 100 nanometers (a nanoproduct) and/or composed of atoms in either a single- or poly-crystalline arrangement. The size of nanocrystals distinguishes them from larger crystals. For example, silicon nanocrystals can optionally provide efficient light emission while bulk silicon does not and/or can optionally be used for memory components. When embedded in solids nanocrystals can optionally exhibit much more complex melting behavior than conventional solids and/or can optionally form the basis of a special class of solids. They can optionally behave as single-domain systems (a volume within the system having the same atomic or molecular arrangement throughout) that can optionally help explain the behavior of macroscopic samples of a similar material without the complicating presence of grain boundaries and/or other defects. Semiconductor nanocrystals having dimensions smaller than 10 nm are also described as quantum dots. Nanocrystalline cellulose (NCC) exhibit remarkable thermal, optical, mechanical, elastic, strength, toughness, magnetic and chemical properties, which can be exploited in a wide variety of structural and/or nanostructural applications. Potential uses have been identified in the automotive, electronic, aerospace, flexible solar screens, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, flexible solar products, flexible nanoproducts, flexible electronic solar energy displays, flexible solar energy devices, flat panel solar powered displays, bendable solar energy batteries, solar energy consumer products, solar powered products for the home, wearable batteries, ultra absorbent aerogels, clothing, transportation fuels, biofuels, liquid fuels, chemical, fuel, and/or lubrication industries with applications ranging from flat panel solar powered displays to disposable medical equipment, coatings for medical applications, medical implants, breast implant devices, microchip implants or other types of implants, artificial heart valves, artificial ligaments, hip joints, and the like, and other medical coating applications. Nanocrystalline (NC) Materials can optionally include, without limitation, e.g., phosphors, carbides, nickel, yttrium, solar ceramic products, composite, grains, silicon, etc. Nanocrystalline material can optionally be classified into different categories depending on the number of dimensions in which the material has nanometer modulations. Thus, they can be classified into (a) layered or lamellar structures, (b) filamentary structures, and (c) equiaxed nanostructured materials. A layered or lamellar structure is a one-dimensional (1D) nanostructure in which the magnitudes of length and width are much greater than the thickness that is only a few nanometers in size. One can also visualize 8 C. Suryanaravana, C.C. Koch/Nanocrystalline (NC) materials Table 1 Classification of nanocrystalline (NC) materials. Dimensionality Designation Typical method(s) of synthesis One-dimensional (1D) Layered (lamellar) Vapor deposition Electrodeposition Two-dimensional (2D) Filamentary Chemical vapor deposition Three-dimensional (3D) Crystallites Gas condensation (equiaxed).

Nanocrystalline Cores have very high permeability over low frequency to high frequency up to 30 Mhz. They are very suitable for common mode choke to used as EMC filter to compress conducted common mode noise. Compared to traditional ferrite core, nanocrystalline core has a lot of advantages as high inductance, good filter effective, small size and volume, lower turns of copper wire, lower power consumption and high efficiency. Nanocrystalline cores have high curie temperature about 560° C., much higher than traditional ferrite core about 200° C. High curie temperature make nanocrystalline core excellent thermal stability, and can continuous working at up to 120° C. environment Nanocrystalline cores are the best choice for application of common mode choke. Features, Material: Fe-based Nanocrystalline core, Saturation flux density induction: 1.25 T, Permeability @10 KHz: >50000, Permeability @ 100 KHz: >10500, Curie temperature (° C.): 560, Stacking factor: 0.78. Saturation magnetostriction (*10\hat{ }-6): <2, Resistivity (μΩ·cm): 115, Ribbon thickness: 25 μm. Core shapes: Troidal core. Applications for nano crystalline cores include: EMC Filter, Switched mode power supply, Computer power supply, Communication and network power supply, Laser and X-ray power supply, Welding equipment and Electrical plating power supply, Solar energy equipment and Wind power generator, Household electrical appliance, Uninterruptable power supply (UPS), Frequency converted, Inducted heating equipment, high-speed railway power supplies.

Nanocrystalline Copper. Nanocrystalline copper electrodes can optionally be used as the catalyzes for the electrochemical conversion of carbon monoxide to alcohols. The electrochemical conversion of CO2 and H2O into liquid fuel is ideal for high-density renewable energy storage and could provide an incentive for CO2 harness. However, efficient electrocatalysts for reducing CO2 and its derivatives into a desirable fuel are not available at present. Although many catalysts can reduce CO2 to carbon monoxide (CO), liquid fuel synthesis requires that CO is reduced further, using H2O as a H⁺ source. Copper (Cu) is the only known material with an appreciable CO electroreduction activity, but in bulk form its efficiency and selectivity for liquid fuel are far too low for practical use. In particular, H2O reduction to H2 outcompetes CO reduction on Cu electrodes unless extreme over potentials are applied, at which point gaseous hydrocarbons are the major CO reduction products. Nanocrystalline Cu prepared from Cu2O (‘oxide-derived Cu’) produces multi-carbon oxygenates (ethanol, acetate and n-propanol) with up to 57% Faraday efficiency at modest potentials (−0.25 volts to −0.5 volts versus the reversible hydrogen electrode) in CO-saturated alkaline H2O. By comparison, when prepared by traditional vapor condensation, Cu nanoparticles with an average crystallite size similar to that of oxide-derived copper produce nearly exclusive H2 (96% Faraday efficiency) under identical conditions. Our results demonstrate the ability to change the intrinsic catalytic properties of Cu for this notoriously difficult reaction by growing interconnected nanocrystallites from the constrained environment of an oxide lattice. The selectivity for oxygenates, with ethanol as the major product, demonstrates the feasibility of a two-step conversion of CO2 to liquid fuel that could be powered by renewable electricity.

Nanometer Dimensions are at the atomic dimension scale. Nanotechnology refers to the study, creation and/or application of molecular materials with a product size that is typically less than one nanometer (nm) is one billionth, or 10-9, of a meter. By comparison, typical carbon to carbon bond lengths, or the spacing between these atoms in a molecule, are in the range 0.12-0.15 nm. The significance of a polymer nano-coating is that it can optionally form a very tight bond with the surface of most materials; including glass, paint, plastic, rubber, aluminum, chrome, aluminum, stainless steel, kevlar, cast iron, fabrics, and/or leather will have surface imperfections i.e. peaks and/or valleys, micro-fissures when viewed under high magnification. These undulations allow a nano-coating polymer to form a tight molecular bond with the surface it's applied to. Surfaces sealed with nanotechnology sealants repel water, oil and/or dirt, have antistatic characteristics and/or protect against chemical and/or biological damage. Water, oil and/or dirt can optionally be removed easily, but if the car is very dirty it can optionally be cleaned with a high pressure hose and/or a microfiber cloth. Nanotechnology polymers form a very tight matrix chain-link structure, which forms both a very strong bond and/or one that is not easily breached by chemicals or detergents. This type of nanotechnology coating with its small particulate size are much smaller than those of water, making them hydrophobic (water resistant). Due to their size they fill any surface irregularities (micro fissures), which results in a flat surface, one that reflects light without hindrance.

Nanocrystalline Cellulose Acetate (NCCA). Highly flexible nanocomposite films of nanocrystalline cellulose acetate (NCCA) and graphene oxide (GO) were synthesized by combining NCCA and GO sheets in a well-controlled manner. By adjusting the GO content, various NCCA/GO nanocomposites with 0.3-1 wt % GO were obtained. Films of these nanocomposites were prepared using the solvent casting method. Microscopic and X-ray diffraction (XRD) measurements demonstrated that the GO nanosheets were uniformly dispersed in the NCCA matrix. Mechanical properties of the composite films were also studied. The best GO composition of the samples tested was 0.8 wt %, giving tensile strength of 157.49 MPa, which represents a 61.92% enhancement compared with NCCA. On the other hand, the composite films showed improved barrier properties against water vapor. This simple process for preparation of NCCA/GO films is attractive for potential development of high-performance films for electrical and electrochemical applications.

Nanocrystalline Hydroxyapatite (HAp) Powders can optionally be synthesized using a simple method with chitosan-polymer complex solution. To obtain HAp nanopowders, the prepared precursor was calcined in air at 400-800° C. for 2 h. The phase composition of the calcined samples was studied by X-ray diffraction (XRD) technique. The XRD results confirmed the formation of HAp phase with a small trace of monotite phase. With increasing calcination temperature, the crystallinity of the HAp increased, showing the hexagonal structure of HAp with the lattice parameter a in a range of 0.94030-0.94308 nm and c of 0.68817-0.68948 nm. The particles sizes of the powder were found to be 55.02-73.36 nm as evaluated by the XRD line broadening method. The chemical composition of the calcined powders was characterized by FTIR spectroscopy. The peaks of the phosphate carbonate and hydroxyl vibration modes were observed in the FTIR spectra for all the calcined powders. TEM investigation revealed that the prepared HAP samples of rod-like nanoparticles having the particles size in the range of 100-300 nm. The corresponding selected-area electron diffraction (SAED) analysis further confirmed the formation of hexagonal structure of HAp.

Nanocrystalline TiO₂ can optionally be used as a photocatalysts to deal with environmental pollutions, such as water purification and making saltwater drinkable, wastewater treatment and air purification. Here a sonochemical method for directly preparing anatase nanocrystalline TiO₂ has been established. Nanocrystalline TiO₂ were synthesized by the hydrolysis of titanium tetrabutyl in the presence of water and ethanol under a high-intensity ultrasonic irradiation (20 kHz, 100 W/cm²) at 363 K for 3 h. The structure and particles sizes of the product were dependent upon the reaction temperature, the acidity of the medium and the reaction time. Characterization was accomplished by using various different techniques, such as powder X-ray diffraction (XRD), transmission electron microscopy (TEM), thermogravimetry differential thermal analysis (TG-DTA) and Fourier transform infrared (FTIR) spectroscopy. The TEMimages showed that the particles of TiO₂ were columnar in shape and the average sizes were ca. 3 nm×7 nm. The formation mechanism of nanocrystalline TiO₂ under a high intensity ultrasonic irradiation was also investigated. The hydrolytic species of titanium tetrabutyl in water condensed to form a large number of tiny gel nuclei, which aggregated to form larger clusters. Ultrasound irradiation generated a lot of local hot spots within the gel and the crystal structural unit was formed near the hot spots with the decrease of the gel nuclei, which lead to form nanocrystal particles.

Nanocrystalline TiO₂ Coated-Fabric for UV Shielding and Antibacterial Functions. Due to excellent photocatalytic and optical properties of titanium dioxide (TiO2), it has been applied in several products such as food packaging plastics, materials to produce vehicles or for buildings and sunscreen-protecting cosmetics. In this present work, the synthesized as well as commercial TiO2 was coated onto a household curtain fabric for anti-microbial, and other health properties in sunscreens, cleansers, complexion treatments, creams and lotions, shampoos, and specialized makeup, and ultraviolet (UV) shielding functions. The coating was performed by inducing the deposition of TiO2 layer from the Ti precursor onto the fabric surface pre-treated with silane adhesive agent so as to improve the adhesion. Ag nanoparticles were also incorporated in some samples to further improve the antibacterial function. Antibacterial activities of the coated fabric were evaluated by standard qualitative test (the Kirby-Bauer test (AATCC 147)). For UV shielding was evaluated by measuring a UV-Vis reflection of the coated fabrics both before and after subjecting to several washing cycles. The result showed that the TiO2-coated fabrics developed had potential as antibacterial and UV shielding for the garment and curtain industry.

Nanocrystalline Tungsten Carbide (WC) with a high surface area and containing minimal free carbon was synthesized via a polymer route. Its physical properties, including solubility in acid solution, electronic conductivity, and thermal stability, were thoroughly studied at two elevated temperatures: 95° C. and 200° C. Compared to commercially available WC, this in-house synthesized WC showed lower solubility in acidic media at 200° C., higher electronic conductivity (comparable to that of carbon black), as well as higher thermal stability. However, this material exhibited low electrochemical stability in acidic media when subjected to potential cycling at potentials larger than 0.7 V vs. RHE, due to the electrooxidation of WC. The major product of WC electrooxidation is WO3, which was confirmed by X-ray photon spectroscopy measurements. Pt was uniformly deposited on the high surface area WC to form a 20 wt % of Pt supported catalyst for the oxygen reduction reaction (ORR). The ORR mass activity was then obtained using the rotating disk electrode technique.

Plasma-Enhanced Chemical Vapor Deposition (PECVD) is a process used to deposit thin film from a gas state (vapor) to a solid state on a substrate. Chemical reactions are involved in the process, which occur after creation of a plasma of the reacting gases. The plasma is generally created by RF (AC) frequency or DC discharge between two electrodes, the space between which is filled with the reacting gases.

Polymer Nanocomposites (PNC) of a polymer or copolymer having nanoparticles or nanofillers dispersed in the polymer matrix. These can optionally be of different shape (e.g., platelets, fibers, spheroids), but at least one dimension must be in the range of 1-50 nm. These PNC's belong to the category of multi-phase systems (MPS, viz. blends, composites, and foams) that consume nearly 95% of plastics production. These systems require controlled mixing/compounding, stabilization of the achieved dispersion, orientation of the dispersed phase, and the compounding strategies for all MPS, including PNC, are similar. Polymer nanoscience is the study and application of nanoscience to polymer-nanoparticle matrices, where nanoparticles are those with at least one dimension of less than 100 nm. The transition from micro- to nano-particles lead to change in its physical as well as chemical properties. Two of the major factors in this are the increase in the ratio of the surface area to volume, and the size of the particle. The increase in surface area-to-volume ratio, which increases as the particles get smaller, leads to an increasing dominance of the behavior of atoms on the surface area of particle over that of those interior of the particle. This affects the properties of the particles when they are reacting with other particles. Because of the higher surface area of the nano-particles, the interaction with the other particles within the mixture is more and this increases the strength, thermal resistance, etc. and many factors do change for the mixture. An example of a nanopolymer is silicon nanospheres, which show quite different characteristics; their size is 40-100 nm and they are much harder than silicon, their hardness being between that of sapphire and diamond.

Perovskite (pronunciation: /p [symbol] ′r [symbol] vskait/) is a calcium titanium oxide mineral composed of calcium titanate, with the chemical formula CaTiO₃. It lends its name to the class of compounds, which have the same type of crystal structure as CaTiO₃ (^{XII}A^{2+VI}B⁴⁺X²⁻₃) known as the perovskite structure.

Power Inverter, a power inverter, or inverter, is an electronic device or circuitry that changes direct current (DC) to alternating current (AC). The input voltage, output voltage and frequency, and overall power handling depend on the design of the specific device or circuitry. The inverter does not produce any power, the power is provided by the DC source. A power inverter can be entirely electronic or can optionally be a combination of mechanical effects (such as a rotary apparatus) and electronic circuitry. Static inverters do not use moving parts in the conversion process.

Processing of Cellulose Nanocrystals. Although there are many variants of the process to isolate CNCs from a given cellulose source material, this process generally occurs in two primary stages. The first stage is a purification of the source material (plants, tunicates, algae, bacteria, etc.) to remove most of the non-cellulose components in the biomass. These include lignin, hemicellulose, fats and waxes, proteins, and inorganic contaminants. The second stage uses an acid hydrolysis process to deconstruct the “purified” cellulose material into its crystalline components. This is accomplished by preferentially removing the amorphous regions of the cellulose microfibrils. The resulting whisker-like particles (3-20 nm wide, 50-2000 nm long) are ˜100% cellulose, are highly crystalline (62%-90%, depending on cellulose source material and measurement method), and have been referred to in the literature as cellulose nanocrystals (CNCs), nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, and cellulose nanowhiskers (CNW) to name a few. The variations in CNC characteristics. Transmission electron microscopy (TEM) image of CNCs extracted from microcrystalline cellulose. Cellulose Nanocrystals 10 Production and Applications of Cellulose Nanomaterials.

Solar cell (also called photovoltaic cell or photoelectric cell) is a solid state electrical device that converts the energy of light directly into electrical current by the photovoltaic effect. The following are non-limiting, different types of solar cells: Amorphous Silicon solar cell (a-Si); Biohybrid solar cell; Buried contact solar cell; Cadmium telluride solar cell (CdTe); Concentrated PV cell (CVP and HCVP); Copper indium gallium selenide solar cells (CI(G)S); Crystalline silicon solar cell (c-Si); Dye-sensitized solar cell (DSSC); Gallium arsenide germanium solar cell (GaAs); Hybrid solar cell; Luminescent solar concentrator cell (LSC); Micromorph (tandem-cell using a-Si/pc-Si); Monocrystalline solar cell (mono-Si); Multi-junction solar cell (MJ); Nanocrystal solar cell; Organic solar cell (OPV); Perovskite solar cell; Photoelectrochemical cell (PEC); Plasmonic solar cell; Plastic solar cell; Polycrystalline solar cell (multi-Si); Polymer solar cell; Quantum dot solar cell; Solid-state solar cell; Thin-film solar cell (TFSC); Wafer solar cell, or wafer-based solar cell (synonym for crystalline silicon solar cell).

Solar Cell or photovoltaic cell, is an electrical device that converts the energy of light directly into electrical current by the photovoltaic effect, which is a physical and chemical phenomenon. It is a form of photoelectric cell, defined as a device whose electrical characteristics, such as current, voltage, or resistance, vary when exposed to light. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles are the building blocks of photovoltaic modules, otherwise known as solar panels. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles are described as being photovoltaic irrespective of whether the source is sunlight or an artificial light They are used as a photodetector (for example infrared detectors), detecting light or other electromagnetic radiation near the visible range, or measuring light intensity. The operation of a photovoltaic (PV) cell requires 3 basic attributes: the absorption of light generating either electron-hole pairs or excitons; the separation of charge carriers of opposite types; and the separate extraction of those carriers to an external circuit. In contrast a solar thermal collector supplies thermal by absorbing sunlight for the purpose of either direct heating or indirect electricity generation from thermal. A“photoelectrolytic cell” (photoelectrochemical cell), on the other hand, refers either to a type of photovoltaic cell (like that developed by Edmond Becquerel and modern dye-sensitized solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles), or to a device that splits water directly into hydrogen and oxygen using only solar illumination. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles are typically named after the semiconducting material they are made of. These materials must have certain characteristics in order to absorb sunlight Some cells are designed to handle sunlight that reaches the Earth's surface, while others are optimized for use in space. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles can be made of only one single layer of light-absorbing material (single-junction) or use multiple physical configurations (multi-junctions) to take advantage of various absorption and charge separation mechanisms. Solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles can be classified into first, second and third generation cells. The first generation cells—also called conventional, traditional or wafer-based cells—are made of crystalline silicon, the commercially predominant PV technology, that includes materials such as polysilicon and monocrystalline silicon. Second generation cells are solar glass, solar windows, solar fuel, solar powered fuel cells, solar powered gadgets, solar powered roof tiles, solar powered shingles, solar powered roadways, solar film, that include amorphous silicon, CdTe and CIGS cells and are commercially significant in utility-scale photovoltaic power stations, building integrated photovoltaics or in small stand-alone power system. The third generation of solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles includes a number of thin film technologies often described as emerging photovoltaics—most of them have not yet been commercially applied and are still in the research or development phase. Many use organic materials, often organometallic compounds as well as inorganic substances. Despite the fact that their efficiencies had been low and the stability of the absorber material was often too short for commercial applications, there is a lot of research invested into these technologies as they promise to achieve the goal of producing low-cost, high-efficiency solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles.

Solar cell efficiency refers to the portion of energy in the form of sunlight that can be converted via photovoltaics into electricity. The efficiency of the solar cells used in a photovoltaic system, in combination with latitude and climate, determines the annual energy output of the system. For example, a solar panel with 20% efficiency and an area of 1 m² will produce 200 W at Standard Test Conditions, but it can produce more when the sun is high in the sky and will produce less in cloudy conditions and when the sun is low in the sky. In central Colorado, which receives annual insolation of 5.5 kWh/m²/day, such a panel can be expected to produce 440 kWh of energy per year. However, in Michigan, which receives only 3.8 kWh/m²/day, annual energy yield will drop to 280 kWh for the same panel. At more northerly European latitudes, yields are significantly lower: 175 kWh annual energy yield in southern England. Several factors affect a cell's conversion efficiency value, including its reflectance efficiency, thermodynamic efficiency, charge carrier separation efficiency, and conduction efficiency values. Because these parameters can be difficult to measure directly, other parameters are measured instead, including quantum efficiency, V_{OC} ratio, and fill factor. Reflectance losses are accounted for by the quantum efficiency value, as they affect “external quantum efficiency.” Recombination losses are accounted for by the quantum efficiency, V_{OC} ratio, and fill factor values. Resistive losses are predominantly accounted for by the fill factor value, but also contribute to the quantum efficiency and V_{OC} ratio values. As of December 2014, the world record for solar cell efficiency at 46% was achieved by using multi-junction concentrator solar cells, developed from collaboration efforts of Soitec, CEA-Leti, France together with Fraunhofer ISE, Germany.

Solar Energy is radiant light and heat from the Sun that is harnessed using a range of ever-evolving technologies such as solar heating, photovoltaics, solar thermal energy, solar architecture, molten salt power plants and artificial photosynthesis. It is an important source of renewable energy and its technologies are broadly characterized as either passive solar or active solar depending on how they capture and distribute solar energy or convert it into solar power. Active solar techniques include the use of photovoltaic systems, concentrated solar power and solar water heating to harness the energy. Passive solar techniques include orienting a building to the Sun, selecting materials with favorable thermal mass or light-dispersing properties, and designing spaces that naturally circulate air. The large magnitude of solar energy available makes it a highly appealing source of electricity. The United Nations Development Programme in its 2000 World Energy Assessment found that the annual potential of solar energy was 1,575-49,837 exajoules (EJ). This is several times larger than the total world energy consumption, which was 559.8 EJ in 2012. In 2011, the International Energy Agency said that “the development of affordable, inexhaustible and clean solar energy technologies will have huge longer-term benefits. It will increase countries' energy security through reliance on an indigenous, inexhaustible and mostly import-independent resource, enhance sustainability, reduce pollution, lower the costs of mitigating global warming, and keep fossil fuel prices lower than otherwise. These advantages are global. Hence the additional costs of the incentives for early deployment should be considered learning investments; they must be wisely spent and need to be widely shared”.

Solar energy devices, non-limiting examples of solar energy devices or solar products that are powered by sunlight, either directly or through electricity generated by solar panels: solar powered air conditioning, solar balloon, solar powered charger, solar powered backpack, solar cell phone charger, strawberry tree (solar energy devices), solar chimney, solar powered calculator, solar-powered compacting trash can, solar powered devices, solar dryer, solar-powered fan, solar furnace, solar inverter, solar keyboard, solar lamp, solar pond, solar road stud, solar powered street lights, solar powered traffic lights, solar tuki, solar-powered flashlight, solar notebook, solar-powered calculator, solar-powered desalination unit, solar-powered pump, solar-powered fountain, solar-powered radio, solar-powered refrigerator, solar-powered engine, solar-powered watch, solar-pumped laser, solar powered roadways, solar spark lighter, solar still, solar tree, solar powered vehicle, solar powered automobiles, solar powered balloons, solar powered buses, solar powered cars, solar panels on spacecraft, solar sail, solar thermal rocket, solar powered buildings, solar water heating, solar powered water treatment plants, solar water purification, solar, photovoltaic power stations, solar water heating, flexible solar screens, flexible solar panels, solar glass panels, flexible solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadway s, solar film, flexible solar products, flexible nano solar energy products, flexible electronic solar energy display s, flexible solar energy devices, flat panel solar powered displays, bendable solar energy batteries, solar energy consumer products, solar powered products for the home, wearable solar energy batteries, solar energy consumer products, solar powered products for the home, solar smart products, smart glass products, solar powered roof tiles, solar powered shingles, solar powered roadways, solar film, hand-held portable solar powered devices, solar powered stadiums, solar garden lights, solar wall lights, solar spot lights, solar security lights, solar accent lights, solar path lights, solar water products, solar panels, solar glass panels, solar cells, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices, solar energy batteries, solar energy consumer products, solar products for garden & home, solar energy consumer products, solar paint, solar paint additives cells, solar powered roadways, solar powered shingles, photovoltaic solar powered shingles, solar powered roadways, solar powered gadgets, solar powered roof tiles, solar materials, photovoltaic solar powered shingles, photovoltaic solar powered shingles, solar powered roadways, thin film solar windows and/or other solar building applications, solar powered poles, solar powered utility poles, solar powered equipment, solar energy systems, solar charging station for electric cars, transparent solar cell, grapheme solar cell, and the like.

Solar Fuel is a synthetic chemical fuel produced directly/indirectly from solar energy sunlight/solar thermal through photochemical/photobiological (i.e., artificial photosynthesis, experimental as of 2013), thermochemical, and electrochemical reaction. Light is used as an energy source, with solar energy being transduced to chemical energy, typically by reducing protons to hydrogen, or carbon dioxide to organic compounds. A solar fuel can be produced and stored for later usage, when sunlight is not available, making it an alternative to fossil fuels. Diverse photocatalysts are being developed to carry these reactions in a sustainable, environmentally friendly way. The world's dependence on the declining reserves of fossil fuels poses not only environmental problems but also geopolitical ones. Solar fuels, in particular hydrogen, are viewed as an alternative source of energy for replacing fossil fuels especially where storage is essential. Electricity can be produced directly from sunlight through photovoltaics, but this form of energy is rather inefficient to store compared to hydrogen. A solar fuel can be produced when and where sunlight is available, and stored and transported for later usage. The most widely researched solar fuels are hydrogen and products of carbon dioxide reduction. Solar fuels can be produced via direct or indirect processes. Direct processes harness the energy in sunlight to produce a fuel without intermediary energy conversions. In contrast, indirect processes have solar energy converted to another form of energy first (such as biomass or electricity) that can then be used to produce a fuel. Indirect processes have been easier to implement but have the disadvantage of being less efficient than, e.g., water splitting for the production of hydrogen, since energy is wasted in the intermediary conversion. Hydrogen can be produced by electrolysis. To use sunlight in this process, a photoelectrochemical cell can be used, where one photosensitized electrode converts light into an electric current that is then used for water splitting. One such type of cell is the dye-sensitized solar cell. This is an indirect process, since it produces electricity that then is used to form hydrogen. The other major indirect process using sunlight is conversion of biomass to biofuel using photosynthetic organisms; however, most of the energy harvested by photosynthesis is used in life-sustaining processes and therefore lost for energy use. A direct process can use a catalyst that reduces protons to molecular hydrogen upon electrons from an excited photosensitizer. Several such catalysts have been developed as proof of concept, but not yet scaled up for commercial use; nevertheless, their relative simplicity gives the advantage of potential lower cost and increased energy conversion efficiency. One such proof of concept is the “artificial leaf” developed by Nocera and coworkers: a combination of metal oxide-based catalysts and a semiconductor solar cell produces hydrogen upon illumination, with oxygen as the only byproduct. Hydrogen can also be produced from some photosynthetic microorganisms (microalgae and cyanobacteria) using photo bioreactors. Some of these organisms produce hydrogen upon switching culture conditions; for example, Chlamydomonas reinhardtii produces hydrogen anaerobically under sulfurde privation, that is, when cells are moved from one growth medium to another that does not contain sulfur, and are grown without access to atmospheric oxygen. Another approach was to abolish activity of the hydrogen-oxidizing (uptake) hydrogenase enzyme in thediazotrophic cyanobacterium Nostoc punctiforme, so that it would not consume hydrogen that is naturally produced by the nitrogenase enzyme in nitrogen-fixing conditions. This N. punctiforme mutant could then produce hydrogen when illuminated with visible light.

Solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles: Solar glass, transparent solar panels, solar windows, solar tiles, doubled-sided solar panels, solar powered cars, solar powered lights, solar automotive paint solar paint products, solar paint additives, liquid solar cells, printable liquid solar cells, spray-on solar cells, liquid crystal solar cells, solar tiles having an electricity generating coating designed to admit light over most of the visible range but to block light in the ultraviolet and infrared ranges; the coating reflects some of thermal generated within a building so that it remains in the building instead of largely being transmitted through the window, thereby effecting a savings of thermal during the winter, often applied on glazing in a double window construction.

Solar irradiance is the power per unit area received from the Sun in the form of electromagnetic radiation in the wavelength range of the measuring instrument. Irradiance may be measured in space or at the Earth's surface after atmospheric absorption and scattering. It is measured perpendicular to the incoming sunlight. Total solar irradiance (TSI), is a measure of the solar power over all wavelengths per unit area incident on the Earth's upper atmosphere. The solar constant is a conventional measure of mean TSI at a distance of one astronomical Unit (AU). Irradiance is a function of distance from the Sun, the solar cycle, and cross-cycle changes. Irradiance on Earth is also measured perpendicular to the incoming sunlight Insolation is the power received on Earth per unit area on a horizontal surface. It depends on the height of the Sun above the horizon.

Sunlight is a portion of the electromagnetic radiation given off by the Sun, in particular infrared, visible, and ultraviolet light. On Earth, sunlight is filtered through Earth's atmosphere, and is obvious as daylight when the Sun is above the horizon. When the direct solar radiation is not blocked by clouds, it is experienced as sunshine, a combination of bright light and radiant thermal. When it is blocked by clouds or reflects off other objects, it is experienced as diffused light. The World Meteorological Organization uses the term “sunshine duration” to mean the cumulative time during which an area receives direct irradiance from the Sun of at least 120 watts per square meter. Other sources indicate an “Average over the entire earth” of “164 Watts per square meter over a 24 hour day”. The ultraviolet radiation in sunlight has both positive and negative health effects, as it is both a principal source of vitamin D₃ and a mutagen. Sunlight takes about 8.3 minutes to reach Earth from the surface of the Sun. A photon starting at the center of the Sun and changing direction every time it encounters a charged particle would take between 10,000 and 170,000 years to get to the surface. Sunlight is a key factor in photosynthesis, the process used by plants and other autotrophic organisms to convert light energy, normally from the Sun, into chemical energy that can be used to fuel the organisms' activities.

Solar paint, solar paint additives cell can optionally include electrochromic paint, based on particles of paramagnetic iron oxide.

Spherical Cellulose Nanocrystal (SCNC) suspension can optionally be prepared by hydrolysis of microcrystalline cellulose with a mixture of sulfuric acid and hydrochloric acid under ultrasonic treatment. The mechanism of SCNC formation and the liquid, non-liquid crystalline properties of their suspensions were investigated. A suspension of spherical particles was usually inclined to form crystallization colloids rather than liquid, non-liquid crystals at high concentration. However, a SCNC suspension with high polydispersity (49%) was observed to form the liquid, non-liquid crystalline phase, and the liquid, non-liquid crystalline textures changed with increasing concentration. This observation offers an approach to the liquid, non-liquid crystal formation of highly polydisperse spherical nanoparticles.

Substrate: A substrate according to the present subject matter can include one or more of materials including one or more of: silicon, carbon fiber, carbon nanofibers, fluorocarbons, filaments, carbon nanotubes, SiO2, silicon-germanium, tungsten, silicon carbide, silicon nitride, silicon oxynitride, titanium nitride, gallium arsenide (GaAs), graphene, glass, plastic or metal, steel, aluminum, copper, graphite, and various high-k dielectrics, and/or in the form or, or including, paper, plastic, a polymer, a liquid polymer, a liquid crystal polymer, a composite gel polymer, a copolymer, fabric, film, foil, sheet stock, a web, and/or a sheet.

Synthesis of Nanocrystalline Bulk and Powder materials can optionally include the properties of nanocrystalline substances change considerably when the size of crystallites decreases below a threshold value. Such changes arise when the average size of crystal grains does not exceed 100 nm and are most pronounced when grains are less than 10 nm in size. Ultrafine-grain substances should be studied considering not only their composition and structure, but also particles size distribution. Ultrafine-grain substances with grains 300 to 40 nm in size on the average are usually referred to as submicrocrystalline, while those with grains less than 40 nm in size on the average are called nanocrystalline. Nanosubstances and nanomaterials can optionally be classified by geometrical shape and the dimensionality of their structural elements. The main types of nanomaterials with respect to the dimensionality include cluster materials, fibrous materials, films and multilayered materials, and also polycrystalline materials whose grains have dimensions comparable in all the three directions.

Solar thermal energy (STE) is a form of energy and a technology for harnessing solar energy to generate thermal energy or electrical energy for use in industry, and in the residential and commercial sectors.

Solar thermal collector collects thermal by absorbing sunlight. A collector is a device for capturing solar radiation. Solar radiation is energy in the form of electromagnetic radiation from the infrared (long) to the ultraviolet (short) wavelengths. The quantity of solar energy striking the Earth's surface (solar constant) averages about 1,000 watts per square meter under clear skies, depending upon weather conditions, location and orientation. The term “solar collector” commonly refers to solar hot water panels, but may refer to installations such as solar parabolic troughs and solar towers; or basic installations such as solar air heaters. Concentrated solar power plants usually use the more complex collectors to generate electricity by heating a fluid to drive a turbine connected to an electrical generator. Simple collectors are typically used in residential and commercial buildings for space heating.

Thermoplastic Mechanisms: Some films are formed by simple cooling of the binder. For example, encaustic or wax paints are liquid when warm, and harden upon cooling. In many cases, they resoften or liquify if reheated. Paints that dry by solvent evaporation and contain the solid binder dissolved in a solvent are known as lacquers. A solid film forms when the solvent evaporates. Because no chemical crosslinking is involved, the film can re-dissolve in solvent; as such, lacquers are unsuitable for applications where chemical resistance is important. Classic nitrocellulose lacquers fall into this category, as do non-grain raising stains composed of dyes dissolved in solvent. Performance varies by formulation, but lacquers generally tend to have better UV resistance and lower corrosion resistance than comparable systems that cure by polymerization or coalescence. The paint type known as Emulsion in the UK and Latex in the USA is a water-borne dispersion of sub-micrometer polymer particles. These terms in their respective countries cover all paints that use synthetic polymers such as acrylic, vinyl acrylic (PVA), styrene acrylic, etc. as binders. The term “latex” in the context of paint in the USA simply means an aqueous dispersion; latex rubber from the rubber tree is not an ingredient. These dispersions are prepared by emulsion polymerization. Such paints cure by a process called coalescence where first the water, and then the trace, or coalescing, solvent evaporate and draw together and soften the binder particles and fuse them together into irreversibly bound networked structures, so that the paint cannot redissolve in the solvent/water that originally carried it. The residual surfactants in paint as well as hydrolytic effects with some polymers cause the paint to remain susceptible to softening and, over time, degradation by water. The general term of latex paint is usually used in the USA, while the term emulsion paint is used for the same products in the UK and the term latex paint is not used at all.

Thermosetting Mechanisms: Paints that cure by polymerization are generally one- or two-package coatings that polymerize by way of a chemical reaction, and cure into a cross-linked film. Depending on composition they can optionally need to dry first, by evaporation of solvent. Classic two-package epoxies or polyurethanes would fall into this category. The “drying oils”, counter-intuitively, actually cure by a crosslinking reaction even if they are not put through an oven cycle and seem to simply dry in air. The film formation mechanism of the simplest examples involve first evaporation of solvents followed by reaction with oxygen from the environment over a period of days, weeks and even months to create a cross-linked network. Classic alkyd enamels would fall into this category. Oxidative cure coatings are catalyzed by metal complex driers, such as cobalt naphthenate. Recent environmental requirements restrict the use of volatile organic compounds (VOCs), and alternative curing processes and/or apparatuses have been developed, generally for industrial purposes. UV curing paints, for example, enable formulation with very low amounts of solvent, or even none at all. This can optionally be achieved because of the monomers and oligomers used in the coating have relatively very low molecular weight, and are therefore low enough in viscosity to enable good fluid flow without the need for additional thinner. If solvent is present in significant amounts, generally it is mostly evaporated first and then crosslinking is initiated by ultraviolet light Similarly, powder coatings contain little or no solvent. Flow and cure are produced by heating of the substrate after electrostatic application of the dry powder.

Combination mechanisms: So-called “catalyzed” lacquers” or “crosslinking latex” coatings are designed to form films by a combination of methods: classic drying plus a curing reaction that benefits from the catalyst. There are paints called plastisols/organosols, which are made by blending PVC granules with a plasticiser. These are stoved and the mix coalesces. Diluent or Solvent. The main purposes of the diluent are to dissolve the polymer and adjust the viscosity of the paint. It is volatile and does not become part of the paint film. It also controls flow and application properties, and in some cases can affect the stability of the paint while in liquid state. Its main function is as the carrier for the non volatile components. To spread heavier oils (for example, linseed) as in oil-based interior house paint a thinner oil is required. These volatile substances impart their properties temporarily-once the solvent has evaporated, the remaining paint is fixed to the surface. This component is optional: some paints have no diluent. Water is the main diluent for water-borne paints, even the co-solvent types. Solvent-borne, also called oil-based, paints can have various combinations of organic solvents as the diluent including aliphatics, aromatics, alcohols, ketones and white spirit. Specific examples are organic solvents such as petroleum distillate, esters, glycol ethers, and the like. Sometimes volatile low-molecular weight synthetic resins also serve as diluents.

Color-Changing Paint Various technologies exist for making paints that change color. Thermochromic paints and coatings contain materials that change conformation when thermal is applied or removed, and so they change color. Liquid crystals have been used in such paints, such as in the thermometer strips and tapes used in aquaria and novelty/promotional thermal cups and straws. These materials are used to make eyeglasses. Color-changing paints can also be made by adding halochrome compounds or other organic pigments. One patent cites use of these indicators for wall coating applications for light colored paints. When the paint is wet it is pink in color but upon drying it regains its original white color. As cited in patent, this property of the paint enabled two or more coats to be applied on a wall property and evenly. The previous coats having dried would be white whereas the new wet coat would be distinctly pink. Ashland Inc. introduced foundry refractory coatings with similar principle in 2005 for use in foundries. Electrochromic paints change color in response to an applied electric current. When subjected to an electromagnetic field the paramagnetic particles change spacing, modifying their color and reflective properties. The electromagnetic field would be formed using the conductive metal of the car body. Electrochromic paints can be applied to plastic substrates as well, using a different coating chemistry. The technology involves using special dyes that change conformation when an electric current is applied across the film itself. This new technology has been used to achieve glare protection at the touch of a button in passenger airplane windows. Application. Paint can be applied as a solid, a gaseous suspension (aerosol) or a liquid. Techniques vary depending on the practical or artistic results desired. As a solid (usually used in industrial and automotive applications), the paint is applied as a very fine powder, then baked at high temperature. This melts the powder and causes it to adhere to the surface. The reasons for doing this involve the chemistries of the paint, the surface itself, and perhaps even the chemistry of the substrate (the object being painted). This is called “powder coating” an object. As a gas or as a gaseous suspension, the paint is suspended in solid or liquid form in a gas that is sprayed on an object. The paint sticks to the object. This is called “spray painting” an object. The reasons for doing this include: The application mechanism is air and thus no solid object touches the object being painted; The distribution of the paint is uniform, so there are no sharp lines; It is possible to deliver very small amounts of paint; A chemical (typically a solvent) can be sprayed along with the paint to dissolve together both the delivered paint and the chemicals on the surface of the object being painted; Some chemical reactions in paint involve the orientation of the paint molecules. In the liquid application, paint can be applied by direct application using brushes, paint rollers, blades, other instruments, or body parts such as fingers and thumbs. Rollers generally have a handle that allows for different lengths of poles to be attached, allowing painting at different heights. After liquid paint is applied, there is an interval during which it can be blended with additional painted regions (at the “wet edge”) called “open time.” The open time of an oil or alkyd-based emulsion paint can be extended by adding white spirit, similar glycols such as Dowanol (propylene glycol ether) or open time prolongers. This can also facilitate the mixing of different wet paint layers for aesthetic effect. Latex and acrylic emulsions require the use of drying retardants suitable for water-based coatings. Paint application by spray is the most popular method in industry. In this, paint is atomized by the force of compressed air or by the action of high pressure compression of the paint itself, and the paint is turned into small droplets that travel to the article to be painted. Alternate methods are airless spray, hot spray, hot airless spray, and any of these with an electrostatic spray included. There are numerous electrostatic methods available. Dipping used to be the norm for objects such as filing cabinets, but this has been replaced by high speed air turbine driven bells with electrostatic spray. Car bodies are primed using cathodic elephoretic primer, which is applied by charging the body depositing a layer of primer. The unchanged residue is rinsed off and the primer stoved. Many paints tend to separate when stored, the heavier components settling to the bottom, and require mixing before use. Some paint outlets have machines for mixing the paint by shaking the can vigorously for a few minutes. The opacity and the film thickness of paint can optionally be measured using a drawdown card. Water-based paints tend to be the easiest to clean up after use; the brushes and rollers can be cleaned with soap and water. Proper disposal of left over paint is a challenge. Sometimes it can be recycled: Old paint can optionally be usable for a primer coat or an intermediate coat, and paints of similar chemistry can be mixed to make a larger amount of a uniform color. To dispose of paint it can be dried and disposed of in the domestic waste stream, provided that it contains no prohibited substances (see container). Disposal of liquid paint usually requires special handling and should be treated as hazardous waste, and disposed of according to local regulation. Product variance.

Emulsion Paints are water-based paints in which the paint material is dispersed in a liquid that are mainly of water. For suitable purposes this has advantages in fast drying, low toxicity, low cost, easier application, and easier cleaning of equipment, among other factors.

Non-bonding coatings are clear, high-performance coatings, usually catalyzed polyurethanes that do not bond strongly to paints used for graffiti. Graffiti on such a surface can be removed with a solvent wash, without damaging either the underlying surface or the protective non-bonding coating. These coatings work best on smooth surfaces, and are especially useful on decorative surfaces such as mosaics or painted murals, which might be expected to suffer harm from high pressure sprays.

Solar Power is the conversion of energy from sunlight into electrical current, either directly-using photovoltaics (PV), or indirectly using concentrated solar power. Concentrated solar power systems use lenses or mirrors and tracking systems to focus a large area of sunlight into a small beam. Photovoltaic cells convert light into an electric current using the photovoltaic effect. The International Energy Agency projected in 2014 that under its “high renewables” scenario, by 2050, solar photovoltaics and concentrated solar power would contribute about 16 and 11 percent, respectively, of the worldwide electricity consumption, and solar would be the world's largest source of electricity. Most solar installations would be in China and India. Photovoltaics were initially solely used as a source of electricity for small and medium-sized applications, from the calculator powered by a single solar cell to remote homes powered by an off-grid rooftop PV system. As the cost of solar electricity has fallen, the number of grid-connected solar PV systems has grown into the millions and utility-scale solar power stations with hundreds of megawatts are being built. Solar PV is rapidly becoming an inexpensive, low-carbon technology to harness renewable energy from the Sun. Third-generation photovoltaic cells are solar cells, solar glass, transparent solar panels, solar windows, solar tiles, doubled-sided solar panels, solar powered cars, solar powered lights roof, solar automotive paint solar paint products, solar paint additives, liquid solar cells, printable liquid solar cells, spray-on solar cells, liquid crystal solar cells, solar tiles that are potentially able to overcome the Shockley-Queisser limit of 31%-41% power for single bandgap solar cells, solar glass, transparent solar panels, solar windows, solar tiles, doubled-sided solar panels, solar powered cars, solar powered lights, solar automotive paint solar paint products, solar paint additives, liquid solar cells, printable liquid solar cells, spray-on solar cells, liquid crystal solar cells, solar tiles. This includes a range of alternatives to cells made of semiconducting p-n junctions (“first generation”) and thin film cells(“second generation”). Common third-generation systems include multi-layer (“tandem”) cells made of amorphous silicon or gallium arsenide, gallium phosphide, while more theoretical developments include frequency conversion, hot-carrier effects and other multiple-carrier ejection techniques. Emerging photovoltaics include: Copper zinc tin sulfide solar cell (CZTS), and derivates CZTSe and CZTSSe, Dye-sensitized solar cell, also known as “Grätzel cell,” Organic solar cell, Perovskite solar cell, Polymer solar cell, Quantum dot solar cell. Especially the achievements in the research of perovskite cells have received tremendous attention in the public, as their research efficiencies recently soared above 20%. They also offer a wide spectrum of low-cost applications. In addition, another emerging technology, concentrator photovoltaics (CPV), uses high-efficient, multi-junction solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles or solar energy devices in combination with optical lenses and a tracking system.

Thermal energy storage (TES) is achieved with greatly differing technologies that collectively accommodate a wide range of needs. It allows excess thermal energy to be collected for later use, hours, days or many months later, at individual building, multiuser building, district, town, or even regional scale depending on the specific technology. As examples: energy demand can be balanced between daytime and nighttime; summer thermal from solar collectors can be stored interseasonally for use in winter, and cold obtained from winter air can be provided for summer air conditioning. Storage media include: water or ice-slush tanks ranging from small to massive, masses of native earth or bedrock accessed with thermal exchangers in clusters of small-diameter boreholes (sometimes quite deep); deep aquifers contained between impermeable strata; shallow, lined pits filled with gravel and water and top-insulated; and eutectic, phase-change materials. Other sources of thermal energy for storage include thermal or cold produced with thermal pumps from off-peak, lower cost electric power, a practice called peak shaving; thermal from combined thermal and power (CHP) power plants; thermal produced by renewable electrical energy that exceeds grid demand and waste thermal from industrial processes. Thermal storage, both seasonal and short term, is considered important for cheaply balancing high shares of variable renewable electricity production and integration of electricity and heating sectors in energy systems almost or completely fed by renewable energy.

Thermophotovoltaic (TPV) energy conversion is a direct conversion process from thermal into electrical current via photons. A basic thermophotovoltaic system is of a thermal emitter and a photovoltaic diode cell. The temperature of the thermal emitter varies between different systems from about 900° C. to about 1300° C., although in principle TPV devices can extract energy from any emitter with temperature elevated above that of the photovoltaic device (forming an optical thermal engine). The emitter can be a piece of solid material or a specially engineered structure. Thermal is the spontaneous emission of photons due to thermal motion of charges in the material. For normal TPV temperatures, this radiation is mostly at near infrared and infrared frequencies. The photovoltaic diodes can absorb some of these radiated photons and convert them into free charge carrier that is electricity. Thermophotovoltaic systems have few, if any, moving parts and are therefore very quiet and require low maintenance. These properties make thermophotovoltaic systems suitable for remote-site and portable electricity-generating applications. The efficiency-cost properties, however, are often rather poor compared to other electricity-generating technologies. Current research in the area aims at increasing the system efficiencies while keeping the system cost low. In the design of a TPV system, it is usually desired to match the optical properties of thermal emission (wavelength, polarization, direction) with the most efficient conversion characteristics of the photovoltaic cell, since unconverted thermal emission is a major source of inefficiency. Most groups focus on gallium (GaSb) cells. Germanium (Ge) is also suitable. Much research and development in TPVs therefore concerns methods for controlling the emitter's properties. TPV cells have often been proposed as auxiliary power conversion devices for regeneration of lost thermal in other power generation systems, such as steam turbine systems or solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles. A prototype TPV hybrid car was even built. The “Viking 29” (TPV) powered automobile, designed and built by the Vehicle Research Institute (VRI) at Western Washington University. TPV research is a very active area. Among others, the University of Houston TPV Radioisotope Power Conversion Technology development effort is aiming at combining thermophotovoltaic cell concurrently with thermocouples to provide a 3 to 4-fold improvement in system efficiency over current radioisotope.

Thin Film is a layer of material ranging from fractions of a nanometer (monolayer) to several micrometers in thickness. The controlled synthesis of materials as thin films (a process referred to as deposition) is a fundamental step in many applications. A familiar example is the household mirror, which typically has a thin metal coating on the back of a sheet of glass to form a reflective interface. The process of silvering was once commonly used to produce mirrors, while more recently the metal layer is deposited using techniques such as sputtering. Advances in thin film deposition techniques during the 20th century have enabled a wide range of technological breakthroughs in areas such as magnetic recording media, electronic semiconductor devices, LEDs, optical coatings such anti-reflective coatings), hard coatings on cutting tools, and for both energy generation (e.g. thin film solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles and storage (thin film batteries). It is also being applied to pharmaceuticals, via thin film drug delivery. In addition to their applied interest, thin films play an important role in the development and study of materials with new and unique properties. Examples include multiferroic materials, and superlattices that allow the study of quantum confinement by creating two-dimensional electron states. Deposition. The act of applying a thin film to a surface is thin film deposition—any technique for depositing a thin film of material onto a substrate or onto previously deposited layers. “Thin” is a relative term, but most deposition techniques control layer thickness within a few tens of nanometres. Molecular beam epitaxy and atomic layer deposition allow a single layer of atoms to be deposited at a time. It is useful in the manufacture of optics (for reflective, anti-reflective coatings or self-cleaning glass, for instance), electronics (layers of insulators, semiconductors, and conductors form integrated circuits), packaging (i.e., aluminum-coated PET film), and in contemporary art (see the work of Larry Bell). Similar processes are sometimes used where thickness is not important: for instance, the purification of copper by electroplating, and the deposition of silicon and enriched uranium by a CVD-like process after gas-phase processing. Deposition techniques fall into two broad categories, depending on whether the process is primarily chemical or physical. Chemical Deposition. Here, a fluid precursor undergoes a chemical change at a solid surface, leaving a solid layer. An everyday example is the formation of soot on a cool object when it is placed inside a flame. Since the fluid surrounds the solid object, deposition happens on every surface, with little regard to direction; thin films from chemical deposition techniques tend to be conformal, rather than directional. Chemical deposition is further categorized by the phase of the precursor: Plating relies on liquid precursors, often a solution of water with a salt of the metal to be deposited. Some plating processes are driven entirely by reagents in the solution (usually for noble metals), but by far the most commercially important process is electroplating. It was not commonly used in semiconductor processing for many years, but has seen resurgence with more widespread use of chemical-mechanical polishing techniques. Chemical solution deposition (CSD) or chemical bath deposition (CBD) uses a liquid precursor, usually a solution of organometallic powders dissolved in an organic solvent. This is a relatively inexpensive, simple thin film process that is able to produce stoichiometrically accurate crystalline phases. This technique is also known as the sol-gel method because the ‘sol’ (or solution) gradually evolves towards the formation of a gel-like diphasic system. Spin coating or spin casting, uses a liquid precursor, or sol-gel precursor deposited onto a smooth, flat substrate, which is subsequently spun at a high velocity to centrifugally spread the solution over the substrate. The speed at which the solution is spun and the viscosity of the sol determine the ultimate thickness of the deposited film. Repeated depositions can be carried out to increase the thickness of films as desired. Thermal treatment is often carried out in order to crystallize the amorphous spin coated film. Such crystalline films can exhibit certain preferred orientations after crystallization on single crystal substrates. Chemical Vapor Deposition (CVD) generally uses a gas-phase precursor, often a halide or hydride of the element to be deposited. In the case of MOCVD, an organometallic gas is used. Commercial techniques often use very low pressures of precursor gas. Plasma enhanced CVD (PECVD) uses an ionized vapor, or plasma, as a precursor. Unlike the soot example above, commercial PECVD relies on electromagnetic devices and/or methods (electric current, microwave excitation), rather than a chemical reaction, to produce plasma. Atomic layer deposition (ALD) uses gaseous precursor to deposit conformal thin films one layer at a time. The process is split up into two half reactions, run in sequence and repeated for each layer, in order to ensure total layer saturation before beginning the next layer. Therefore, one reactant is deposited first, and then the second reactant is deposited, during which a chemical reaction occurs on the substrate, forming the desired composition. As a result of the stepwise, the process is slower than CVD, however it can be run at low temperatures, unlike CVD.

Thin Film Batteries. Thin film printing technology is being used to apply solid-state lithium polymers to a variety of substrates to create unique batteries for specialized applications. Thin film batteries can be deposited directly onto chips or chip packages in any shape or size. Flexible batteries can be made by printing onto plastic, thin metal foil, or paper.

Thin Film Photovoltaic Cells. Thin film technologies are also being developed as a way of substantially reducing the cost of solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles. The rationale for this is thin film solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles are cheaper to manufacture owing to their reduced material costs; energy costs, handling costs and capital costs. This is especially represented in the use of printed (roll-to-roll) processes. Other thin film technologies, that are still in an early stage of ongoing research or with limited commercial availability, are often classified as emerging or third generation photovoltaic cells and include, organic, dye-sensitized, and solar glass, solar windows, solar fuel, solar powered fuel cells, solar powered gadgets, solar powered roof tiles, solar powered shingles, solar powered roadways, solar film, as well as quantum dot, copper zinc tin sulfide, nanocrystal and perovskite solar cells, solar glass, transparent solar panels, solar windows, solar tiles, doubled-sided solar panels, solar powered cars, solar powered lights, solar powered roofs, solar automotive paint, solar paint products, solar paint additives, liquid solar cells, printable liquid solar cells, spray-on solar cells, liquid crystal solar cells, solar tiles.

Transparent Conducting Films (TCFs) are thin films of optically transparent and electrically conductive material. They are an important component in a number of electronic devices including liquid, OLEDs, touchscreens and photovoltaics. While indium tin oxide (ITO) is the most widely used, alternatives include other transparent conductive oxides (TCOs), polymers, liquid polymers, liquid crystal polymers, liquid carbon polymers, composite gel polymers, metal grids, carbon nanotubes (CNT), graphene, nanowire meshes and ultra thin metal films. TCFs for photovoltaic applications have been fabricated from both inorganic and organic materials. Inorganic films typically are made up of a layer of transparent conducting oxide (TCO), most commonly indium tin oxide (ITO), fluorine doped tin oxide (FTO), or doped zinc oxide. Organic films are being developed using carbon nanotube networks and graphene, which can be fabricated to be highly transparent to infrared light, along with networks of polymers such as poly (3,4-ethylenedioxythiophene) and its derivatives. Transparent conducting films are typically used as electrodes when a situation calls for low resistance electrical contacts without blocking light (e.g. LEDs, photovoltaics). Transparent materials possess wideband gaps whose energy value is greater than those of visible light. As such, photons with energies below the band gap value are not absorbed by these materials and visible light passes through. Some applications, such as solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar film, often require a wider range of transparency beyond visible light to make efficient use of the full solar spectrum.

Utrananocrystalline Diamond (UNCD) as a structural material for complex micro-electro mechanical systems (MEMS) is enormous due to its excellent chemical, mechanical and barrier properties, but it has so far not been extensively explored, mostly due to intrinsic stress problems. The N-UNCD can utilize semiconducting at its thermal and barrier properties. Fifteen pairs of oriented slender beams (from 90 to 200 μm length) provide the driving force and are capable of generating a linear displacement on a central moving shuttle up to almost 2 μm. An ‘in-house’ built optical-based detection system was used to assess the motion of the actuator, with an accuracy of 0.4 nm. These results pave the way for development of diamond-based MEMS technology that could be applicable in many fields, including bio-medicine, optics, and sensors and actuators for space applications, where precision displacement is demanded along with robust materials, as well as general applications that require sliding surfaces.

Ultraviolet (UV) is an electromagnetic radiation with a wavelength from 10 nm (30 PHz) to 400 nm (750 THz), shorter than that of visible light but longer than X-rays. UV radiation constitutes about 10% of the total light output of the Sun, and is thus present in sunlight. It is also produced by electric arcs and specialized lights, such as mercury-vapor lamps, tanning lamps, and black lights. Although it is not considered an ionizing radiation because its photons lack the energy to ionize atoms, long-wavelength ultraviolet radiation can cause chemical reactions and causes many substances to glow or fluoresce. Consequently, the biological effects of UV are greater than simple heating effects, and many practical applications of UV radiation derive from its interactions with organic molecules. Suntan, freckling and sunburn are familiar effects of over-exposure, along with higher risk of skin cancer. Living things on dry land would be severely damaged by ultraviolet radiation from the Sun if most of it were not filtered out by the Earth's atmosphere. More-energetic, shorter-wavelength “extreme” UV below 121 nm ionizes air so strongly that it is absorbed before it reaches the ground. Ultraviolet is also responsible for the formation of bone-strengthening vitamin D in most land vertebrates, including humans. The UV spectrum thus has effects both beneficial and harmful to human health. Ultraviolet rays are invisible to most humans: the lens in a human eye ordinarily filters out UVB frequencies or higher, and humans lack color receptor adaptations for ultraviolet rays. Under some conditions, children and young adults can see ultraviolet down to wavelengths of about 310 nm, and people with aphakia (missing lens) or replacement lens can also see some UV wavelengths. Near-UV radiation is visible to some insects, mammals, and birds. Small birds have a fourth color receptor for ultraviolet rays; this gives birds “true” UV vision. Reindeer use near-UV radiation to see polar bears, which are poorly visible in regular light because they blend in with the snow. UV also allows mammals to see urine trails, which is helpful for prey animals to find food in the wild. The males and females of some butterfly species look identical to the human eye but very different to UV-sensitive eyes—the males sport bright patterns in order to attract the females.

Wet End means that portion of the nanocrystalline (NC) product making process prior to a press section where a liquid medium such as water typically includes more than 45% of the mass of the substrate, additives added in a wet end typically penetrate and distribute within the slurry.

Dry End means that portion of the nanocrystalline (NC) product making process including and subsequent to a press section where a liquid medium such as water typically includes less than 45% of the mass of the substrate, dry end includes but is not limited to the size press portion of a nanocrystalline (NC) product making process, additives added in a dry end typically remain in a distinct coating layer outside of the slurry.

Flocculant means a composition of matter which when added to a liquid carrier phase within which certain products are thermodynamically inclined to disperse, induces agglomerations of those products to form as a result of weak physical forces such as surface tension and adsorption, flocculation often involves the formation of discrete globules of products aggregated together with films of liquid carrier interposed between the aggregated globules, as used herein flocculation includes those descriptions recited in ASTME 20-85 as well as those recited in Kirk-Othmer Encyclopedia of Chemical Technology, 5th Edition, (2005), (Published by Wiley, John & Sons, Inc.).

Surface Strength means the tendency of a substrate, component, or additive to resist damage due to abrasive force.

Dry Strength means the tendency of a substrate, component, or additive to resist damage due to shear force(s), it includes but is not limited to surface strength.

Wet Strength means the tendency of a substrate, component, or additive to resist damage due to shear force(s) when rewet.

Wet Web Strength means the tendency of a substrate, component, or additive to resist shear force(s) while the substrate is still wet.

Substrate means a mass containing paper fibers going through or having gone through a nanocrystalline (NC) product making process, substrates include wet web, paper mat, slurry, paper sheet, and paper products.

Paper Product means the end product of a nanocrystalline (NC) product making process it includes but is not limited to writing paper, printer paper, tissue paper, cardboard, paperboard, and packaging paper.

NCC or NCC Core means nano-crystalline cellulose. NCC Core is a discrete mass of NCC crystal onto which polymers can optionally be grafted, an NCC or NCC core can optionally or can optionally not have been formed by acid hydrolysis of cellulose fibers and NCC or NCC core can optionally or can optionally not have been modified by this hydrolysis to have functional groups appended thereto including but not limited to sulfate esters.

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, Nanocrystalline (NC) Plastics, or other forms of nanocrystals of cellulose composites or nanocrystalline (NC) nanotubes means a composition of matter including at least an NCC or NC material core with at least one polymer chain or polymer or microcrystalline cellulose (MCC) or nanocrystalline composites, cores or other forms of nanocrystalline extending therefrom.

NCC Coupling means a composition of matter including at least two NCC cores, the coupling can optionally be a polymer linkage in which at least in part a polymer chain connects the two NCC cores, or it can optionally be an NCC twin in which two (or more) NCC cores are directly connected to each other by a sub polymer linkage (such as epoxide) and/or direct bonding of one or more of the NCC cores' atoms.

Slurry means a mixture including a liquid medium such as water within which solids such as fibers (such as cellulose fibers) and optionally fillers are dispersed or suspended such that between >99% to 45% by mass of the slurry is liquid medium.

Size Press means the part of the nanocrystalline (NC) product making process machine where the dry component is rewet by applying a water-based formulation containing surface additives such as starch, sizing agents and optical brightening agents, a more detailed descriptions of size press is described in the reference Handbook for Pulp and Paper Technologists, 3rd Edition, by Gary A. Smook, Angus Wilde Publications Inc., (2002).

Vapor-Liquid-Solid Method (VLS) is a mechanism for the growth of one-dimensional structures, such as nanowires, from chemical vapor deposition. The growth of a crystal through direct adsorption of a gas phase on to a solid surface is generally very slow. The VLS mechanism circumvents this by introducing a catalytic liquid alloy phase which can rapidly adsorb a vapor to supersaturation levels, and from which crystal growth can subsequently occur from nucleated seeds at the liquid-solid interface. The physical characteristics of nanowires grown in this manner depend, in a controllable way, upon the size and physical properties of the liquid alloy.

Nanomaterials (nanocrystalline (NC) materials) are materials possessing grain sizes on the order of a billionth of a meter. They manifest extremely fascinating and useful properties, which can be exploited for a variety of structural and non-structural applications.

### Nanomaterials to Produce the Conversion of Thermal and Light to Electrical Current

Understanding how to engineer nanomaterials to produce targeted solar-cell applications is the key to improving their efficiency and could lead to breakthroughs in their design. Proposed mechanisms for the conversion of solar energy into electrical current are those exploiting the particle nature of light in conventional photovoltaic cells, and those using the collective electromagnetic nature, where light is harnessed by antennas and rectified. In both cases, engineered nanomaterials to product the crucial components Examples include arrays of semiconductor nanocrystalline (NC) nanotubes as an intermediate band (intermediate band solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles), semiconductor nanocrystals for multiple exciton generation, or, in antenna-rectifier cells, nanomaterials to produce effective optical frequency rectification.

### Nanocrystalline Coating Applications

In recent years, near-nano (submicron) and nanostructured materials have attracted increasingly more attention from the materials community. Nanocrystalline (NC) materials arc characterized by a microstructural length or grain size of up to about 100 nm. Materials having grain size of ˜0.1 to 0.3 μm are classified as submicron materials. Nanocrystalline (NC) materials exhibit various shapes or forms, and possess unique chemical, physical or mechanical properties. When the grain size is below a critical value (˜10-20 nm), more than 50 vol. % of atoms is associated with grain boundaries or interfacial boundaries. In this respect, dislocation pile-ups cannot form, and the Hall-Petch relationship for conventional coarse-grained materials is no longer valid. Therefore, grain boundaries play a major role in the deformation of nanocrystalline (NC) materials. Nanocrystalline (NC) materials exhibit creep and super plasticity at lower temperatures than conventional micro-grained counterparts. Similarly, plastic deformation of nanocrystalline coatings is considered to be associated with grain boundary sliding assisted by grain boundary diffusion or rotation. In this review paper, current developments in fabrication, microstructure, physical and mechanical properties of nanocrystalline (NC) materials and coatings will be addressed. Particular attention is paid to the properties of transition metal nitride nanocrystalline films formed by ion beam assisted deposition process.

Whilst nanotechnology particularly focuses upon the power of working at the nanoscale, often with reference to particles or atoms, nano-based materials or nanocoatings upon ordinary classed materials, are equally as potent Nanocoatings are prevalent across a multitude of disciplines ranging from engineering through to medicine. A wide range of materials and techniques has been employed to produce nanocoatings for a given purpose. Nanocoatings are used to improve mechanical properties, offer novel functionality such as extreme water repellence (superhydrophobicity) or their implementation in the pharmaceutical, medical and dental industries (e.g. the coating of dental and medical implants).

The present subject matter can optionally provide the nanocrystalline (NC) superlattice solar cells, nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, that can optionally be combined with nanocrystalline (NC) materials, e.g., plastic, aluminum, steel, kevlar, cast iron, fibers, alloys and/or composites that can optionally increase strength and/or hardness and/or multiple nanocrystalline (NC) applications.

The present subject matter can also optionally include, but it not limited to, using or adding nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes with manganese phosphates are of considerable industrial interesting properties nowadays because of their wide applications in laser host, ceramic, dielectric, electric, magnetic, and catalytic processes, including but not limited to, manganese (III) phosphates such as Manganese dihydrogenphosphate dihydrate (Mn(H2PO4)2.2H2O), MnP3O9, MnPO4.H2O, MnPO4, MnHP2O7 and Mn3(PO4)3, which can be made according to known methods, as known in the art, e.g., Danvirutai et al., Journal of Alloys and Compounds 457 (2008) pp. 75-80, entirely incorporated by reference. The present subject matter can also optionally include compositions and methods using the nanocrystalline cellulose ((NCC) materials, nanocrystalline (NC) plastics, nanocrystalline (NC) polymers or nanocrystalline (NC) nanotubes including of cellulose composites or nanocrystalline (NC) nanotubes including of the present subject matter for use in fertilizers, pesticides and/or herbicides and/or with micronutrients added to fertilizers, such as insoluble micronutrients, smart macronutrients or smart micronutrients, optionally in applications including combining them with nitrogen-phosphorus-potassium (NPK) fertilizers and coating them on NPK fertilizers and seeds, and also in and used with controlled-release fertilizer of zinc encapsulated by a manganese hollow core shell (Soil Science and Plant Nutrition, v.61, (2), pp. 319-326 (2015)), e.g., macronutrients can include one or more of sources or compounds including one or more of calcium, carbon, hydrogen, magnesium, nitrogen, oxygen, phosphorus, potassium, or sulphur, and/or micronutrients can include one or more of sources or compounds including one or more of boron, chloride, cobalt, copper, iron, molybdenum, manganese, nickel, silicon, sodium, and/or zinc.

The present subject matter can also include adding using or adding nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes to magnesium chloride, potassium chloride and/or sodium chloride; for use with hydroxyapatite, e.g., one or more of reconstruction of bone or teeth, chromatography, gas sensors, filter to purify liquids, water purification and/or desalination (e.g., polyvinylidenefluoride-co-hexafluoropropylene (PVDF-HFP) membranes containing different amounts of nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, as known in the art, e.g., Lalia et. al., Desalination v.332, pp. 134-141 (2014)), fertilizers, and drug carriers, based on properties including one or more of powder properties, e.g., particles size, surface area, and morphology, which improve the properties thereof, (e.g., as known in the art, e.g., Klinkaewnarong et al. Current Applied Physics 10 (2010) 521-525).

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes can optionally be used in batteries, e.g., NiMH, or Lithium (Li) batteries or rechargeable solar energy batteries or supercapacitors, as nanocrytalline metal hydrides, including, but not limited to, one or more of structure, electrochemical and electronic properties of nanocrystalline and polycrystalline TiFe—, LaNi5- and Mg2Ni-type phases, which can optionally be prepared by mechanical alloying (MA) followed by annealing or by induction melting method, respectively. The properties of hydrogen host materials can be modified substantially by alloying to obtain the desired storage characteristics, e.g., respective replacement of Fe in TiFe by Ni and/or by Mg, Cr, Mn, Co, Mo, Zr, or for Li batteries, e.g., LiMn2O4, γ-Fe₂O₃, fluorine-doped tin oxide and potassium manganese oxyiodide or nanocrystalline solid solutions AlySn1-yO2-y/2 (y=0.57, 0.4) as electrode materials to produce lithium-ion batteries (e.g., Becker et al. Journal of Power Sources, Volume 229, 1 Can optionally 2013, Pages 149-158, which can improve not only the discharge capacity but also the cycle life of these electrodes, e.g., nanocrystalline TiFe0.125Mg0.125Ni(0.75) powder, e.g., cobalt substituting nickel in LaNi4-xMn0.75Al0.25Cox alloy greatly improves the discharge capacity and cycle life of LaNi5 material, e.g., nanocrystalline LaNi3.75Mn0.75Al0.25Co0.25 powder.

Supercapacitors and batteries can optionally include nanocrystalline transition metal nitrides (TMN) based on vanadium nitride, that can optionally deliver a specific capacitance of 1,340 F/g when tested at low scan rates of 2 mV/s and 554 F/g when tested at high charging rates of 100 mV/s in the presence of a 1M KOH electrolyte; and/or using nanostructured vanadium nitride and controlled oxidation of the surface at the nanoscale can optionally be in supercapacitors used in e.g., cars, camcorders and lawn mowers to industrial backup power systems at hospitals and airports.

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) plastics, nanocrystalline (NC) polymers or nanocrystalline (NC) nanotubes including of cellulose composites or nanocrystalline (NC) nanotubes can optionally be used in inverter components and materials such as nanocrystalline soft magnetic materials, e.g., of Fe-based soft magnetic material.

Non-limiting Embodiments of Optional Aspects of the Present Subject Matter

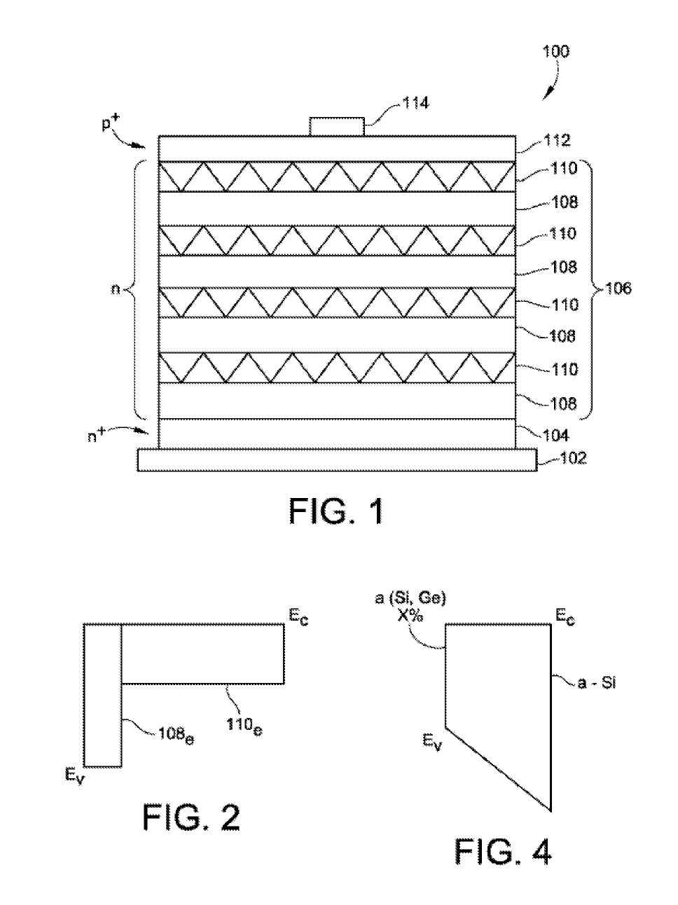

FIG. 1 is a schematic diagram of an embodiment of one such new superlattice solar cells 100. The nanocrystalline superlattice solar cells 100 utilizes a suitable substrate 102, which can be any metal such as steel, Aluminum, silver etc., or an insulator such as plastic or glass coated with a metal, or any other suitable conducting layer such as doped ZnO or ITO. On top of that substrate 102 is coated a layer 104 of n+ amorphous Si, or a n⁺-doped alloy of a-(Si.alloy), or a-(Si,C), or nanocrystalline Si or nanocrystalline(nano) (Si,C) or nano alloy of (Si.alloy) or nano Ge. This layer is identified as an n+ layer in FIG. 1. An advantage of using other back n+ layers 104 such as a-(Si,C) is that more light is transmitted through them to the back reflector, and thus, more light is available for reflection back into the nanocrystalline superlattice 106 (discussed below), thereby further increasing the current produced in the nanocrystalline superlattice solar cells 100.

On top of this doped layer 104 is deposited a superlattice 106. The nanocrystalline superlattice 106 includes alternating amorphous layers 108 of a-Si:H or a-(Si.alloy):H, which is an alloy of Si and Ge, or a-Ge:H, nanocrystalline (NC) carbon, nanocrystalline (NC) carbon nanotubes, nanocrystalline (NC) carbon, nanocrystalline (NC) carbon nanotubes, nanocrystalline (NC) layers 110 of nanocrystalline Si:H, or nanocrystalline (Si.alloy):H, or nanocrystalline Ge:H, or nanocrystalline (Si,C):H. The amorphous layers 108 can optionally have thickness ranging from about 1 nm to about 30 nm, and the nanocrystalline (NC) layers 110 can optionally have thickness ranging from about 1 nm to 100 nm. This cycle of amorphous layer 108 nanocrystalline (NC) carbon, nanocrystalline (NC) carbon nanotubes, nanocrystalline (NC) carbon, nanocrystalline (NC) carbon nanotubes, nanocrystalline layer 110 is repeated until the total desired thickness of this middle undoped or doped “base” layer (the nanocrystalline superlattice 106) of the solar cell 100 is reached. This total desired thickness of this middle base layer (the nanocrystalline superlattice 106) can optionally vary between a few nm to several micrometer (e.g. 10 micrometer). The nanocrystalline superlattice 106 can optionally be doped n type deliberately, or be undoped while acquiring a doping due to a native dopant such as oxygen.

This “base” superlattice 106 layer is followed by a p-doped nanocrystalline or amorphous layer 112 composed of either Si, or an alloy of Si and Ge, or an alloy of Si and C. This layer 112 completes the basic cell structure, namely a p+(or p)−i(or n)-n+(or n) device. The middle i or n layer is the nanocrystalline superlattice 106 layer. The nanocrystalline superlattice solar cells 100 is completed by depositing a final transparent conductor 114 such as doped ZnO or ITO.

As discussed in the incorporated papers, the various layers can be deposited using well known techniques such as plasma-CVD deposition or hot wire deposition or sputtering. The contact layers such as ZnO and ITO can be deposited using other well known techniques such as sputtering, evaporation and CVD.

As discussed above only the basic steel/n+a-Si/{superlattice including a-Si and nc-Si}/p+/ITO structure is disclosed in the incorporated papers, and such structure resulted in only an approximate 8% conversion efficiency. The inclusion of alternative materials such as (SLalloy) in either the amorphous layers 108 or nanocrystalline (NC) layers 110 is completely new. The advantage of such a new development is that a-(Si.alloy) or a-Ge layer, instead of a-Si, absorbs infrared light of wavelength >600 nm much more efficiently than a-Si. Thus, embodiments of the present subject matter benefit from light and conversion of thermal and light to electrical current in both the amorphous layers 108 and the nanocrystalline (NC) layers 110, thereby adding significantly to current generated in the nanocrystalline solar cell 100. Thus, embodiments of the present subject matter are much more efficient solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles than the one described in the above incorporated papers.

The amount of light absorbed by the nanocrystalline solar cell 100 can optionally be tuned by tuning the alloy content Si:Ge. Higher Ge content in the alloy leads to a smaller bandgap and more light and conversion of thermal and light to electrical current as can optionally be seen from the simplified valence diagram of FIG. 2. Yet another advantage of using a-(Si.alloy) instead of a-Si for the nanocrystalline superlattice 106 is that the valence band mismatch between the amorphous layer 108 (bandgap for the amorphous layer 108 shown as 108ₑ in FIG. 2) and the nanocrystalline layer 110 (bandgap for the nanocrystalline layer 108 shown as 110, in FIG. 2) phases is much less in (Si.alloy) alloys than between the two Silicons. Indeed, as the amount of Ge in the amorphous layer 108 is increased, the bandgap 108, decreases, as does the mismatch between it and the bandgap 110, for the nanocrystalline layer 110. This makes for more efficient collection of photo-generated holes in embodiments of the nanocrystalline superlattice solar cells 100 compared to the standard device of the incorporated papers discussed above.

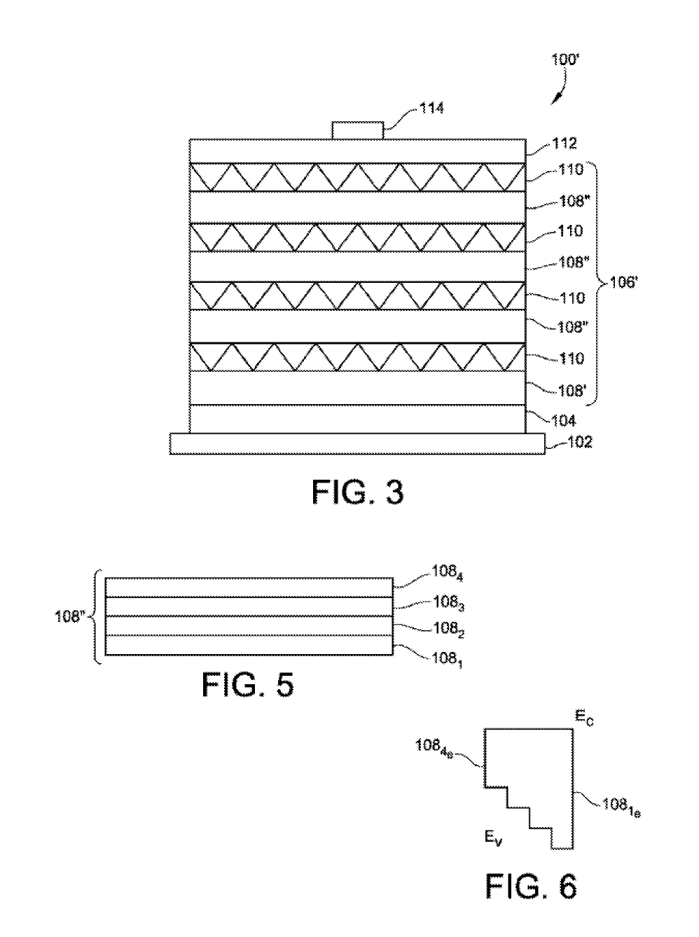

Indeed, while the embodiment of the nanocrystalline superlattice solar cell 100 of FIG. 1 utilizes a homogeneous amorphous layer 108 of a-(Si.alloy):H, in the embodiment of the nanocrystalline superlattice solar cells 100′ shown in FIG. 3, the amount of metal alloy in the amorphous layer 108″ is graded such that its content increases as the amorphous layer 108″ is deposited. This grading can optionally range from 0% Metal alloy content at the initial (lower) boundary with the nanocrystalline layer 110 up to 100% at the upper boundary with the next nanocrystalline layer 110 to be grown. In one embodiment, the grading of the Metal alloy content in the amorphous layer ranges from 0% to approximately 15-20%.

This grading of the Metal alloy content results in a variation in the bandgap between the valence band energy (Eᵥ) and the conduction band energy (E_{c}) across the amorphous layer 108″ as shown by the simplified valence diagram of FIG. 4. As can optionally be seen from an analysis of this FIG. 4, the bandgap at the initial interface with the previous nanocrystalline layer 110 is that of the undoped amorphous Silicon. This bandgap decreases with increasing Metal alloy content until the termination of the amorphous layer 108″ (illustrated as a-(Si.alloy) X percentage in FIG. 4). As discussed above, the amount of bandgap reduction is dependent upon the percentage content of the Metal alloy across the amorphous layer 108″. Indeed, while FIG. 4 illustrates an initial bandgap determined solely by undoped amorphous Silicon, embodiments of the present subject matter can optionally begin the growth of this amorphous layer 108″ with some predetermined starting percentage content of metal alloy such that this initial bandgap at the interface between the amorphous layer 108″ and the preceding nanocrystalline layer 110 can optionally be less than that of undoped amorphous Silicon.

The grading of the Metal alloy content in the amorphous layer 108″ can optionally be continuous, resulting in a continuous variation in the bandgap such as that illustrated in FIG. 4, or can optionally occur in discreet steps of increasing Metal alloy content during the growth of the amorphous layer 108″. FIG. 5 illustrates one such example of an amorphous layer 108″ that utilizes discreet steps of increasing Metal alloy content during the fabrication of the amorphous layer 108″.

As illustrated in this FIG. 5, the amorphous layer 108″ includes a first sub-layer 108i having a first percentage content of metal alloy. This percentage can optionally be zero or higher. After this first sub-layer 108i has been deposited, the Metal alloy content is increased to a second level and held constant during the deposition of the second sub-layer 108₂. Once this second sub-layer 108₂ has been deposited, the percentage content of metal alloy is again increased and then held constant during the deposition of the third sub-layer 108₃. This process is again repeated for the deposition of the fourth sub-layer 108₄ to complete the amorphous layer 108″.

When such a discreet step increase grading of the Metal alloy content is utilized, the decreasing bandgap across this amorphous layer 108″ appears as shown in the simplified valence diagram of FIG. 6. As this FIG. 6 illustrates, the bandgap 108ᵢₑ for the first sub-layer 108₁ is reduced for each subsequent sub-layer until the bandgap 108₄ₑ in discreet steps resulting from the discreet step increases in the Metal alloy content. It should be noted, however, that while the illustration of FIG. 5 shows four sub-layers of increasing Metal alloy content to construct the amorphous layer 108″, more or fewer discreet steps can optionally be employed.

In an exemplary embodiment of the nanocrystalline superlattice solar cells 100′, the nanocrystalline superlattice 106′ was constructed in fifteen cycles, (i.e., thirty alternating layers). However, it should be noted that the present subject matter is not limited to this number of layers and fewer or more layers, e.g., fifty layers, can optionally be utilized. In this exemplary embodiment a first amorphous layer 108′ of undoped amorphous Silicon was grown for 30 seconds using the method described in the above-identified and incorporated papers. The nanocrystalline layer 110 was then deposited for 180 seconds. The amorphous lay ers 108″ were then grown for a total of 60 seconds. Specifically, each individual sub-layer 108₁₋₄ were deposited in 15 second increments utilizing a stepwise increase in the Metal alloy content from 3% in sub-layer 108₁ to 15% in sub-layer 108₄.

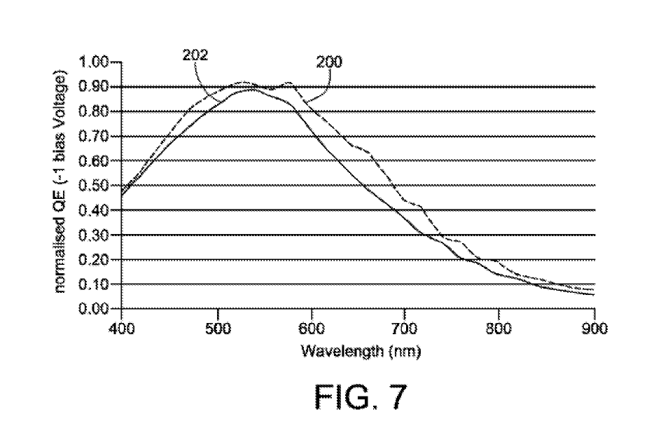

Testing of this exemplary embodiment reveals a significant improvement over the nanocrystalline superlattice solar cells that will add one or more lay ers to the nanocrystalline solar cell that will produce electricity on one or more of the nanocrystalline superlattice lay ers of the solar cell for for electricity that can be used for solar energy devices, solar energy storage systems, applications, products and services, including without limitation, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar tiles constructed in accordance with the teachings of the above-identified and incorporated papers as can optionally be seen from a comparison of trace 200 of FIG. 7 for this exemplary embodiment and trace 202 for a similarly constructed embodiment having no Metal alloy in the amorphous Silicon layers.

Nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes including of the present subject matter can also optionally include using or adding superdispersive iron, cobalt and copper nanocrystalline powders were synthesized in a water-ethanol medium by the reduction method using sodium borohydride as a reducing agent and carboxymethyl cellulose as a stabilizer (for Fe and Co nanoparticles). Transmission electron microscopy micrographs and x-ray diffraction analyses of the freshly prepared nanocrystalline powders indicated that they were in a zerovalent state with particles sizes ranging from 20 to 60 nm. The soybean seeds were treated with an extra low nanocrystalline dose (not more than 300 mg of each metal per hectare) and then sowed on an experimental landfill plot of a farming area of 180 m2. This pre-sowing treatment of soybean seeds, which does not exert any adverse effect on the soil environment, reliably changed the biological indices of the plant growth and development In particular, in laboratory experiments, the germination rates of soybean seeds treated with zerovalent Cu, Co and Fe were 65%, 80% and 80%, respectively.

At least one embodiment of the present subject matter is directed towards adding at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes to a substrate, component, or additive in a nanocrystalline (NC) product making process. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added in the wet end and/or in the dry end. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added as a coating outside of the substrate or can optionally be dispersed within the substrate. A coating can optionally partially or fully enclose the substrate. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally include linear, branched, cyclic, polymers extending from the NCC core and/or can optionally be an NCC Graft Polymer.

Optional NC components that can optionally be in the present subject matter can include NC celluloses such as one or more of naturally occurring crystals such as those present in plant fibers. A typical cellulose bearing fiber includes regions of amorphous cellulose and regions of crystalline cellulose. NCC can optionally be obtained by separating the crystalline cellulose regions from the amorphous cellulose regions of a plant fiber. Because their compact nature makes crystalline cellulose regions highly resistant to acid hydrolysis, NCC is often obtained by acid hydrolyzing plant fibers. NCC crystallites can optionally have 5-10 nm diameter and 100-500 run length. NCC can optionally have a crystalline fraction of no less than 80% and often between 85% and 97%. See, e.g., U.S. 2011/0293932, 2011/0182990, 2011/0196094, and U.S. Pat. No. 8,398,901 (entirely incorporated herein by reference).

In at least one embodiment the composition added to a product substrate optionally includes an NCC core with at least one polymer chain extending from the NCC cote. NCC includes a number of hydroxyl groups, which are possible anchor sites from which polymer chains can optionally extend. Without being limited by a particular theory or design of the present subject matter or of the scope afforded in construing the claims, it is believed that because of one or more of Nanocrystalline cellulose (NCC) unique aspect ratio, density, anchor sites, rigidity and supporting strength, At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes are able to arrange polymer chains in unique arrangements that afford a number of unique properties that enhance product characteristics.

In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is optionally added in the wet end of a nanocrystalline (NC) product making process. In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added as a coating in the size press of a nanocrystalline (NC) product making process. Detailed descriptions of the wet and dry ends of a nanocrystalline (NC) product making process and addition points for chemical additives therein are known in the art, e.g., similar to those described in the reference Handbook for Pulp and Paper Technologists, 3rd Edition, by Gary A. Smock, Angus Wilde Publications Inc., (2002). The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added to the nanocrystalline (NC) product making process at any addition point(s) described therein for any other chemical additive and according to the methods and with any of the apparatuses also described therein.

In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is optionally formed by the derivatization of one or more hydroxyl groups on an NC crystal through condensation polymerization or grafting of vinyl monomers via radical polymerization to meet desired end user requirements.

In at least one embodiment the polymer attached to the NCC core is a polysaccharide. In at least one embodiment the polysaccharide at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is used as viscosity modifier in enhanced oil recovery, as flocculants for wastewater treatment and filler strength agent in a nanocrystalline (NC) product making process.

In at least one embodiment the polymer attached to the NCC core is a vinyl polymer. In at least one embodiment it is a copolymer having structural units of at least two vinyl monomers including but not limited to acrylamide and acrylic acid. Polyacrylamide, polyacrylic acid, and 2-(methacryloyloxy) ethyl trimethylammonium chloride are efficient flocculants for water treatment and various applications. However, vinyl polymers show limited biodegradability and poor shear stability whereas NCC is shear stable but are less efficient as flocculants. Connecting non-ionic, anionic, and/or cationic vinyl monomers on an NCC core yields better performing polyelectrolyte flocculants, and filler materials.

In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added to the nanocrystalline (NC) product making process alongside 2-(methacryloyloxy)-ethyl trimethylammonium chloride. In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes added to a nanocrystalline (NC) product making process is exposed to shear in excess to what a non-at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally endure and still function, and continues to function.

In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is a branched polymer in which from a first chain of polymer structural units extending from the NCC core, one or more distinct other chains branch off from the first polymer chain and/or from other distinct chain branches. In at least one embodiment the first chain is of a different variety of monomer units than one or more of the branch chains. Differences in chain compositions allows for versatile polymer arrangements as a way of imparting a variety of functional groups to a polymer. It also permits one to combine the best properties of two or more polymers in one physical unit. For example the first chain can optionally be selected for its capacity to support or position functionally active polymer branches according to a geometry, which has superior effects.

In at least one embodiment the polymer chain/branch is optionally formed or grown according to one or more of: a grow-to method, a grow-from method, and/or a grow-through method. In the grow-to approach an end group of a pre-formed polymer is coupled with a functional group on the NCC core. In the growing-from approach, the growth of the polymer chain occurs from initiation sites attached to the NCC core. In the growing-through approach a vinyl macro-monomer of cellulose is copolymerized from the NCC core with low molecular weight co-monomer.

Representative examples of vinyl monomers which can optionally be used for any of the three growth or synthesis approaches include, but are not limited to vinyl acetate, acrylic acid, sodium acrylate, ammonium acrylate, methyl acrylate, acrylamide, acrylonitrile, N,N-dimethyl acrylamide, 2-acrylamido-2-methylpropane-1-sulfonic acid, sodium 2-acrylamido-2-methylpropane-1-sulfonate, 3-acrylamidopropyl-trimethyl-ammonium chloride, diallyldimethylammonium chloride, 2-(dimethylamino)ethyl acrylate, 2-(acryloyloxy)-N,N,N-trimethylethanaminium chloride, N,N-dimethylaminoethyl acrylate benzyl chloride quaternary salt, 2-(acryloyloxy)-N,N,N-trimethylethanaminium methyl sulfate, 2-(dimethylamino)ethyl methacrylate, 2-(methacryloyloxy)-N,N,N-trimethylethanaminium chloride, 2-(methacryloyloxy)-N,N,N-trimethylethanaminium methyl sulfate, 3-(dimethylamino)propyl methacrylamide, methacrylic acid, methacrylic anhydride methyl methacrylate, methacryloyloxy ethyl trimethyl ammonium chloride, 3-methacrylamidopropyl-trimethyl-ammonium chloride, hexadecyl methacrylate, octadecyl methacrylate, docosyl acrylate, n-vinyl pyrrolidone, 2-vinyl pyridine, 4-vinyl pyridine, epichlorohydrin, n-vinyl formamide, n-vinyl acetamide, 2-hydroxyethyl acrylate glycidyl methacrylate, 3-(allyloxy)-2-hydroxypropane-1-sulfonate, 2-(allyloxy)ethanol, ethylene oxide, propylene oxide, 2,3-epoxypropyltrimethylammonium chloride, (3-glycidoxypropyl)trimethoxy silane, epichlorohydrin-dimethylamine, vinyl sulfonic acid sodium salt, Sodium 4-styrene sulfonate, caprolactam and any combination thereof.

In at least one embodiment addition of an at least one nanocrystalline cellulose (NCC), nanocrystalline (NC) materials, nanocrystalline (NC) carbon, nanocrystalline (NC) carbon nanotubes, nanocrystalline (NC) lay ers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes to a nanocrystalline (NC) product making process, furnish or slurry can improve at least drainage retention. As shown in the Examples, At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes used alongside starch, a cationic flocculant and an acrylic acid polymer have superior retention performance to such drainage programs lacking the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes. Improved retention of fines, fillers, and other components of the furnish decreases the amount of such components lost to the whitewater and hence reduces the amount of material wastes, the cost of waste disposal and the adverse environmental effects. It is generally desirable to reduce the amount of material employed in a nanocrystalline (NC) product making process.

In at least one embodiment adding the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes to a nanocrystalline (NC) product making process furnish or slurry improves wet strength. As known in the art, e.g., as described in U.S. Pat. No. 8,172,983 (entirely incorporated by reference), a high degree of wet strength in product is desired to allow for the addition of more filler (such as PCC or GCC) to the product. Increasing filler content results in superior optical properties and cost savings (filler is cheaper than fiber).

In at least one embodiment, the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added as a coating or as part of a coating during size press of a nanocrystalline (NC) product making process. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be added as a coating applied during a size press operation and can optionally be added alongside starch, sizing agents or any other additive added during the size press.

In at least one embodiment the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes added to the nanocrystalline (NC) product making process is an NCC graft polymer. The graft polymer can optionally include two or more NCC cores. The NCC graft polymer can optionally include a single polymer chain bridging between the NCC cores. The NCC Graft can optionally also include two or more NCC cores with distinct polymer chains that are cross-linked to each other. As such an at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes can optionally be cross-linked to at least one other at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes where the cross-linkage is located at one of the structural units of the polymer and not at the NCC core. The cross linkage can optionally be achieved by one or more polymer cross-linking agents known in the art. The NCC graft polymer can optionally be in the form of a hydrogel, resin as described in US 2011/0182990 (entirely incorporated herein by reference).

In at least one embodiment at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes including of the present subject matter can optionally be added to a commercial process. The at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes, or nanocrystalline (NC) product, can optionally include a mixture including one or more of: a) at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes mixed with a polymer additive that is not an at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes, b) at least one nanocrystalline cellulose (NCC), nanocrystalline (NC) materials, nanocrystalline (NC) cartoon, nanocrystalline (NC) cartoon nanotubes, nanocrystalline (NC) layers, nanocrystalline (NC) metals and alloys, nanocrystalline (NC) polymers, liquid polymers, liquid crystal polymers, liquid cartoon polymers, composite gel polymers, nanocrystalline (NC) plastics, or other forms of nanocrystals of cellulose composites or nanocrystalline (NC) nanotubes mixed with a polymer additive that is an at least one nanocrystalline cellulose (NCC), nanocrystalline (NC) materials, nanocrystalline (NC) cartoon, nanocrystalline (NC) cartoon nanotubes, nanocrystalline (NC) layers, nanocrystalline (NC) metals and alloys, nanocrystalline (NC) polymers, liquid polymers, liquid crystal polymers, liquid cartoon polymers, composite gel polymers, nanocrystalline (NC) plastics, or other forms of nanocrystals of cellulose composites or cartoon nanotubes, c) a polymer additive which includes at least one nanocrystalline cellulose (NCC), nanocrystalline (NC) materials, nanocrystalline (NC) cartoon, nanocrystalline (NC) carbon nanotubes, nanocrystalline (NC) lay ers, nanocrystalline (NC) metals and alloys, nanocrystalline (NC) polymers, liquid polymers, liquid crystal polymers, liquid cartoon polymers, composite gel polymers, nanocrystalline (NC) plastics, or other forms of nanocrystals of cellulose composites or nanocrystalline (NC) nanotubes. In at least one embodiment the polymer additive is a polymer made up of one or more of at least one nanocrystalline cellulose (NCC), nanocrystalline (NC) materials, nanocrystalline (NC) cartoon, nanocrystalline (NC) cartoon nanotubes, nanocrystalline (NC) layers, nanocrystalline (NC) metals and alloys, nanocrystalline (NC) polymers, liquid polymers, liquid crystal polymers, liquid cartoon polymers, composite gel polymers, nanocrystalline (NC) plastics, or other forms of nanocrystals of cellulose composites or nanocrystalline (NC) nanotubes, non-ionic, water-soluble monomers, anionic monomers, cationic monomers, and any combination thereof. The polymer additives can optionally be manufactured according any process known in the art, e.g., but not limited to, as described in one or more of: Emulsion Polymerization and Emulsion Polymers, liquid polymers, liquid crystal polymers, liquid carbon polymers, composite gel polymers, by Peter A. Lovell et al, John Wiley and Sons, (1997), Principles of polymerization. Fourth Edition, by George Odian, John Wiley and Sons, (2004), Handbook of RAFT Polymerization, by Christopher Bamer-Kowollik, Wiley-VCH, (2008), Handbook of Radical Polymerization, by Krzysztof Matyjaszewski et al, John Wiley and Sons, (2002), Controlled/Living Radical Polymerization: Progress in ATRP, NMP, and RAFT: by K. Matyjaszewski, Oxford University Press (2000), and Progress in Controlled Radical Polymerization: Mechanisms and Techniques, by Krzysztof Matyjaszewski et al, ACS Symposium Series 1023 (2009). The polymer additives can optionally be manufactured according any process including but not limited to Solution, emulsion, inverse-emulsion, dispersion, atom transfer radical polymerization (ATRP), Reversible addition-fragmentation-chain transfer polymerization (RAFT), and ring opening polymerization.

The at least one nanocrystalline cellulose (NCC), nanocrystalline (NC) materials, nanocrystalline (NC) carbon, nanocrystalline (NC) carbon nanotubes, nanocrystalline (NC) lay ers, nanocrystalline (NC) metals and alloys, nanocrystalline (NC) polymers, liquid polymers, liquid crystal polymers, liquid cartoon polymers, composite gel polymers, nanocrystalline (NC) plastics, or other forms of nanocrystals of cellulose composites or nanocrystalline (NC) nanotubes, or product, of the present subject matter can optionally used in any of commercial product or process, such as, but not limited to, one or more of any known product, e.g., but not limited to, as described herein or as known in the art.

Optional examples of components used in making or using a nanocrystalline (NC) product of the present subject matter can optionally include non-ionic, water-soluble monomers suitable for use in a polymer additive can include one or more of: acrylamide, methacrylamide, N,N-dimethylacrylamide, N,N-diethylacrylamide, N-isopropylacrylamide, N-vinylformamide, N-vinylmethylacetamide, N-vinyl pyrrolidone, 2-vinyl pyridine, 4-vinyl pyridine, epichlorohydrin, acrylonitrile, hydroxyethyl methacrylate, hydroxyethyl acrylate, hydroxypropyl acrylate, hydroxypropyl methacrylate, hexadecyl methacrylate, octadecyl methacrylate, glycidyl methacrylate, 3-(glycidoxypropyl)trimethoxy silane, 2-allyloxy ethanol, docosyl acrylate, N-t-butylacrylamide, N-methylolacrylamide, epichlorohydrin-dimethylamine, caprolactam, and the like.

Optional examples of components used in making or using a nanocrystalline (NC) product of the present subject matter can optionally include anionic monomers which can optionally include one or more of: acrylic acid, and its salts, including, but not limited to sodium acrylate, and ammonium acrylate, methacrylic acid, and its salts, including, but not limited to sodium methacrylate, and ammonium methacrylate, 2-acrylamido-2-methylpropanesulfonic acid (AMPS), the sodium salt of AMPS, sodium vinyl sulfonate, styrene sulfonate, maleic anhydride, maleic acid, and it's salts, including, but not limited to the sodium salt, and ammonium salt, sulfonate itaconate, sulfopropyl acrylate or methacrylate, or other water-soluble forms of these or other polymerisable carboxylic or sulphonic acids and crotonic acid and salts thereof. Sulfomethylated acrylamide, allylsulfonate, sodium vinyl sulfonate, itaconic acid, acrylamidomethyl butanoic acid, fumaric acid, vinylphosphonic acid, vinylsulfonic acid, vinylsulfonic acid sodium salt, allylphosphonic acid, 3-(allyloxy)-2-hydroxypropane sulfonate, sulfomethyalted acryamide, phosphono-methylated acrylamide, ethylene oxide, propylene oxide and the like.

Optional examples of components used in making or using a nanocrystalline (NC) product of the present subject matter can optionally include cationic monomers which can optionally include one or more of: dialkylaminoalkyl acrylates and methacrylates and their quaternary or acid salts, including, but not limited to, dimethylaminoethyl acrylate methyl chloride quaternary salt, dimethylaminoethyl acrylate methyl sulfate quaternary salt, dimethylaminoethyl acrylate benzyl chloride quaternary salt, dimethylaminoethyl acrylate sulfuric acid salt, dimethylaminoethyl acrylate hydrochloric acid salt, dimethylaminoethyl methacrylate methyl chloride quaternary salt, dimethylaminoethyl methacrylate methyl sulfate quaternary salt, dimethylaminoethyl methacrylate benzyl chloride quaternary salt, dimethylaminoethyl methacrylate sulfuric acid salt, dimethylaminoethyl methacrylate hydrochloric acid salt, dialkylaminoalkylacrylamides or methacrylamides and their quaternary or acid salts such as acrylamidopropyltrimethylammonium chloride, dimethylaminopropyl acrylamide methyl sulfate quaternary salt, dimethylaminopropylacrylamide sulfuric acid salt, dimethylaminopropyl acrylamide hydrochloric acid salt, methacrylamide propyltrimethylammonium chloride, dimethylaminopropyl methacrylamide methyl sulfate quaternary salt, dimethylaminopropyl methacrylamide sulfuric acid salt, dimethylaminopropyl methacrylamide hydrochloric acid salt, diethylaminoethylacrylate, diethylaminoethylmethacrylate, diallyldiethylammonium chloride, diallyldimethyl ammonium chloride and 2,3-epoxypropyltrimethylainmonium chloride. Alkyl groups are generally C1-4 alkyl.

The present subject matter optionally provides a method of making a composite, including two or more of: (a) providing an aqueous mixture including partially hydrolyzed cellulose in a dissolution media; (b) providing a solution including a aliphatic polyester in a polar organic solvent; (c) combining the mixture with the solution to form a precipitate; and then (d) washing the precipitate with water to remove solvent and dissolution media and produce a wet composite; and (e) drying the wet composite to produce a dry composite.

The washing step can optionally be carried out continuously or as a batch process by any suitable technique, such as by mixing and separating (e.g., by settling, filtration, or centrifugation), washing of a “cake,” dialysis, and combinations thereof. Washing can optionally be carried out with distilled water, or the water can optionally contain additional ingredients such as salts, buffers, etc. Specific washing steps can optionally be repeated and/or continued until the desired degree of washing is achieved. In one or more optional embodiments, the washing step is carried out until the wet composite has a neutral pH (e.g., a pH between 6 and 7).

The drying step can optionally be carried out by any suitable devices and/or methods. In one or more optional embodiments, the drying step is carried out at room temperature, with heating (e.g., baking), or during cooling (e.g., chilling or freezing). The drying step can be carried out at any suitable pressure, including atmospheric pressure or at a reduced pressure (e.g., as in freeze drying).

The dry composite so produced is preferably rigid. In one or more optional embodiments, the composite so produced has (i) a storage modulus represented by an integer between 1 or 5 gigapascals, up to 20, 25, or 35 gigapascals, at a temperature of 20 degrees C., and/or (ii) a storage modulus represented by an integer between 0.1 or 1 gigapascals, up to 10 or 20 gigapascals, at a temperature of 100 degrees Centigrade.

In one or more optional embodiments, the dry composite so produced is porous. In one or more optional embodiments, the dry composite so produced has a density of 0.01, 0.05 or 0.1 grams per cubic centimeter, up to 0.5, 1, 5 or 10 grams per cubic centimeter. In one or more optional embodiments, the composite has a residual weight of about 1%, 2% or 5% to 10%, 15%, or 20% at a temperature of 400 degrees C.

If desired, the combining step, and the optional washing and/or dialyzing step, can be carried out in a form or mold. In this case the method can further includes the step of: (e) releasing the composite from the form or mold to produce a composite product (optionally having a shape corresponding to the shape of the form or mold), optionally followed by the steps of: (f) cutting or grinding the product to further define the features thereof, and/or (g) grinding the product to form a particulate composite.

Thus the method of the present subject matter can optionally be used for the purpose of producing different Nanocrystalline (NC) superlattice solar cells, which can include, but are not limited to, an insulating product, as can optionally be used for architectural or building purposes, or configured for refrigeration, chilling and/or freezing apparatus. In addition, products of the present subject matter can optionally be configured for use as a tissue engineering scaffold, as can optionally be used for bone or soft tissue regeneration in vitro or in vivo. Particulate composites produced by the methods of the present subject matter are useful as, among other things, a pharmaceutical tablet filler or excipient.

### Description of Non-Limiting Exemplary Embodiments and/or Potential Aspects or Elements of the Claimed Subject Matter that can Optionally be Excluded or Negatively Claimed

The present subject matter can optionally also in particular claimed embodiments exclude or negatively claim one or more aspects, e.g., to more particularly recite or exclude embodiments or elements that might occur in cited or other published art, as presented herein. Accordingly, the present subject matter can optionally exclude, not include, or not provide, one of more, or any combination of any element, feature, component or step disclosed herein.

A number of implementations have been described. Nevertheless, it can optionally be understood that various modifications can optionally be made. For example, elements of one or more implementations can optionally be combined, deleted, modified, or supplemented to form further implementations. As yet another example, the logic flows depicted in the figures do not require the particular order shown, or sequential order, to achieve desirable results. In addition, other steps can optionally be provided, or steps can optionally be eliminated, from the described flows, and/or other components can optionally be added to, or removed from, the described systems. Accordingly, other implementations are within the scope of the following claims.

While the present subject matter can optionally be embodied in many different forms, there are described in detail herein specific preferred embodiments of the present subject matter. The present disclosure is an exemplification of the principles of the present subject matter and is not intended to limit the present subject matter to the particular embodiments illustrated. All patents, patent applications, scientific papers, and any other referenced materials mentioned herein are incorporated by reference in their entirety. Furthermore, the present subject matter encompasses any possible combination of some or all of the various embodiments mentioned herein, described herein and/or incorporated herein. In addition the present subject matter encompasses any possible combination that also specifically excludes any one or some of the various embodiments mentioned herein, described herein and/or incorporated herein.

The above disclosure is intended to be illustrative and not exhaustive. This description will suggest many variations and alternatives to one of ordinary skill in this art. All these alternatives and variations are intended to be included within the scope of the claims where the term “comprising” means “including, but not limited to.” Those familiar with the art can optionally recognize other equivalents to the specific embodiments described herein which equivalents are also intended to be encompassed by the claims.

All ranges and parameters disclosed herein are understood to encompass any and all subranges subsumed therein, and every number between the endpoints. For example, a stated range of “1 to 10” should be considered to include any and all subranges between (and inclusive of) the minimum value of 1 and the maximum value of 10; that is, all subranges beginning with a minimum value of 1 or more, (e.g. 1 to 6.1), and ending with a maximum value of 10 or less, (e.g. 2.3 to 9.4, 3 to 8, 4 to 7), and finally to each number 1, 2, 3, 4, 5, 6, 7, 8, 9, and 10 contained within the range. All %, ratios and proportions herein are by weight unless otherwise specified.

### EXAMPLES

The foregoing can optionally be better understood by reference to the following examples, which are presented for purposes of illustration and are not intended to limit the scope of the present subject matter. In particular the examples demonstrate representative examples of principles innate to the present subject matter and these principles are not strictly limited to the specific condition recited in these examples. As a result it should be understood that the present subject matter encompasses various changes and modifications to the examples described herein and such changes and modifications can optionally be made without departing from the spirit and scope of the present subject matter and without diminishing its intended advantages. It is therefore intended that such changes and modifications be covered by the appended claims.

### Example #1

A number of at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes are made according to a growing-from approach. A 4-neck, 1.5 L reactor is fitted with a) an overhead mechanical stirrer connected to a metal shaft and a conical stirrer, b) a nitrogen inlet and sparge tube, c) a claisen adapter fitted with a reflux condenser d) a temperature probe (RTD) inserted through Teflon connector and temperature is controlled by Athena. To the reactor can optionally be added a 562.5 mL of pH adjusted NCC (1.14×10-6 mol, 2.81 g, pH=2) dispersion and purged with N2 for 30 min and then ceric ammonium nitrate (CAN, 1.12×10-3 mol, 6.17 g) is allowed to react with NCC backbone for 15 min under N2 at R.T. The reactor is set to 70° C. and then 52.41 g of acrylamide (7.38×10-1 mol), 17.08 g of acrylic acid (3.16×10-1 mol) and water (84.67 g) are added to reactor at 42° C. Reaction mixture is heated to 70° C. and is maintained at 70° C. for 6 h. At 45 min 160 ppm of sodium hypo phosphite can optionally be added. Reaction is monitored by HNMR analysis of reaction aliquots (quenched with 500-1000 ppm of hydroquinone) and reached 92% conversion in 6 h (Table 2). Post modification is carried out using potassium persulfate (KPS, 500 μmol) and sodium metabisulfite (SBS, 3500 μmol) to burn out residual monomers. The nitrogen sparge is maintained throughout the reaction. The final pH of polymer is adjusted to 3.5 with NaOH and submitted to application testing. All samples are submitted for residual acrylamide and acrylic acid analyses. Results are that at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes are then added to a paper furnish. The alkaline furnish had a pH of 8.1 and is composed of 80% by weight cellulosic fibers and 20% precipitate calcium carbonate diluted to a consistency of 0.5% by weight. The fiber is of ⅔ bleached hardwood kraft and ⅓ bleached softwood kraft. The retention performance of NCC and polymer-grafted NCC is evaluated using the Britt Jar test method.

500 ml of furnish is charged in Britt jar and mixed at 1250 rpm. Starch Solvitose N is then charged at 10 lb./ton dry weight at 5 seconds. Cationic flocculant 61067 is change at 20 seconds. Then at 55 seconds, NCC or At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is charged. Drain started at 60 seconds and ended at 90 seconds. The drain (filtrate) is collected for turbidity measurement. The turbidity of the filtrate is inversely proportional to the furnish retention performance. The turbidity reduction % is proportional to the retention performance of the retention program. The higher the turbidity reduction %, the higher the retention of fines/or fillers. Two commercially available products, Nalco 8677 Plus (a polyacrylic acid polymer) and Nalco 8699 (a silica product), are tested for retention performance as references.

At the tested dosage range of 0.5 lb./ton to 2.0 lb./ton, NCC is expected to provide and an additional 25% to 40% turbidity reduction in comparison to a blank example, which are expected to be more well-performed than the two references 8677 Plus and 8699. At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes with acrylic acid (NCC/AA) and acrylamide/acrylic acid (NCC/AM/AA) is expected to show at least more 25% more turbidity reduction and at least 15% more turbidity reduction respectively than the blank. The results are expected to reveal that both NC cellulose and at least one NC polymers, liquid polymers, liquid crystal polymers, liquid carbon polymers, composite gel polymers, or plastic significantly improve turbidity reduction of tested furnish, which are expected to provide better retention efficiency and cost reduction in Nanocrystalline (NC) product production.

### Example #2

The experiments are to contrast the ability of NCC and at least one polymer, or plastic to increase sheet dry strength in comparison to a conventional polyacrylamide based dry strength agent N-1044. At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes used in this example is 6653-145. The product contains 60% hardwood and 20% softwood and 20% precipitated calcium carbonate (PCC) as filler. 18 lb/ton cationic starch Stalok 310 can optionally be added as conventional dry strength agent, and various doses of NCC, polymer, or plastic and N-1044 are added after cationic starch. 1 lb/ton N-61067 can optionally be added as retention aid. The treated furnish is used to make hand sheet using Noble & Wood hand sheet mold. The composition is pressed using a static press and dried by passing it once through a drum dryer at about 105° C. The resulting hand sheets are allowed to equilibrate at 23° C. and 50% relative humidity for at least 12 hours before testing. Five duplicate hand sheets are made for each condition and the mean values are reported.

Addition of dry strength agents N-1044 and the nanocrystalline (NC) product of the present subject matter are expected to provide improved filler retention and filler content into the sheet. Sheet product properties are compared at fixed ash content 20% based on the relationship of strength and filler content assuming sheet strength (ZDT and tensile index) decreases linearly with ash content NCC alone did not increase sheet strength significantly. On the other side, at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes are expected to increase ZDT and tensile strength by at least 20% as compared to NCC alone. At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes is expected to be more effective than N-1044 especially at low dose 2 lb/ton.

### Example #3

Laboratory experiments are conducted to measure the ability of the NC C alone and at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes to increase the surface strength of paper as a nanocrystalline (NC) product of the present subject matter. Base paper containing 16% ash and that has not been passed through a size press is coated using the drawdown method with solutions containing the desired chemistry. The mass of the paper before and after coating is used to determine specific chemical dose. The paper is dried by passing it once through a drum dryer at about 95° C. and allowed to equilibrate at 23° C. and 50% relative humidity for at least 12 hours before testing.

Surface strength is measured using TAPPI (Technical Association of Pulp and Paper Industries) method T476 om-01. In this measurement, the surface strength is inversely proportional to the amount of mass lost from the surface of the paper after having been systematically “rubbed” on a turn table by two abrasion wheels. The results are reported in mg of lost material per 1000 revolutions (mg/1000 revs): the lower the number the stronger the surface.

A first study compares the performance of the NCC with a copolymer of A A/AM known to increase paper surface strength. As part of the study, two blends of the NCC with the copolymer are tested.

The first three conditions span a range of starch dose within which the conditions containing the NCC, the copolymer and the blends are dosed. After accounting for the strengthening effect of starch, the abrasion loss results are expected to demonstrate that the NCC and the A A/AM copolymer have a similar level of performance. The effect is expected to be further enhanced when the additives are blended in a 50:50 and a 33:67 NCC:AA/AM ratio.

Next, a study is designed to determine whether growing an AA/AM copolymer on to the surface of the NCC improves the paper surface strength and compare its performance with that of the NCC. As part of this study, three at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes varying in the AA/AM monomer ratio are tested. The first three conditions span a range of starch dose within which the conditions containing the NCC and at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes are dosed. After accounting for the starch dose in each of the conditions, the abrasion loss results are expected to demonstrate that the grafting of the A A/AM copolymer on to the surface of the NCC is an improvement over the NCC. The surface strength performance is not expected to be affected, however, by the A A/AM monomer ratio in the 30/70 to 70/30 range.

Next, a study is designed to simultaneously compare surface strength performance as a function of all of the conditions (i.e., unmodified, modified with an anionic polymer of different mole ratios, and blends of the unmodified NCC with the AA/AM copolymer).

The first two conditions only contain starch, while the others contain about 1 or 3 lb/t of the additive. On conditions 15-18, the unmodified NCC:AAAM blends are prepared in a 10:90 mass ratio. The contributions of the multiple variables in this study are better elucidated with a regression analysis of the results. The model for the analysis resulted in a correlation coefficient of 0.80 with all variables (starch, the AA/AM copolymer, NCC, At least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers, liquid polymers, liquid crystal polymers, liquid carbon polymers, composite gel polymers, nanocrystalline (NC) plastics, or other forms of nanocrystals of cellulose composites or nanocrystalline (NC) nanotubes, and the blends of AA/AM copolymer and the NCC) statistically contributing to the model. From highest to lowest, the magnitude of their contribution to strengthening the paper surface is expected to be the following: 1. Blends of AA/AM copolymer and NCC; and then 2. AA/AM copo, showing that Nanocrystalline (NC) superlattice solar cells of the present subject matter are expected to have enhanced strength, performance, and durability as compared to similar known materials, such as NCC alone.

### Example #4

Acid hydrolysis of cellulose is a popular method for isolating nanocrystalline cellulose (NCC) from cellulose fibers. Since the first publication related to the extraction (Mukherjee & Woods, 1953; Revol, Godbout, Dong, Gray, Chanzy & Maret, 1994; Revol, Bradford, Giasson, Marchessault & Gray, 1992) and use of NCC as reinforcing fillers based nanocomposites (Favier, Chanzy & Cavaille, 1995), they have attracted a great deal of interest in the nanocomposites field (Noishiki, Nishiyama, Wada, Kuga & Magoshi, 2002; Qi, Cai, Zhang & Kuga, 2009; Roman & Winter William, 2006) due to their appealing intrinsic properties such as nanoscale dimensions, high surface area, unique morphology, low density, and mechanical strength. Cellulose nanocomposites have been prepared using solution casting (Favier, Chanzy & Cavaille, 1995). In situ polymerization (Wu Q, 2002) and melt intercalation (Chazeau, Cavaillé, Canova, Dendievel & Boutherin, 1999).

Materials. PLA under the commercial name PLA 4060D (poly-D/L-lactide or PDLL A) is provided in the form of pellets. PLA 4060D has about 11% to 13% D-lactide content and has a density of 1.24 g/c.c. It has an amorphous morphology and melting temperature in the range of 150-180 C. Microcrystalline cellulose (MCC) is provided by FMC Bio Polymer (Avicel-PH101). Sulfuric acid, 95%-97%, Reagent Grade, is purchased from Scharlau. Tetrahydrofuran (THF) solvent is purchased from Sigma-Aldrich.

Processing. PLA is dissolved in a solvent such as THF. At the same time, microcrystalline cellulose (MCC) is hydrolyzed in a different container via hydrolyzing with 64%, 65% or 66% H2SO4 at ambient for 30, 60, 120 or 180 minutes. A ratio of 1 g: 10 ml is adopted for the hydrolysis reactions (MCC: H2SO4). The two mixtures are then mixed with constant stirring. Upon mixing and washing, a white material is precipitated. The product is collected and washed with DI water through centrifugation and dialysis. The samples are dried and stored. Using this procedure 4 samples are produced at loading levels of 1%, 5%, 10%, 15%, 30% and 50% (w/w) of MCC (the weight % are taken with reference to the starting material MCC).

Characterization. DMA: The dried nanocomposite samples are ground in a variable speed mill, using a 1 mm Sieve. The fine powder is used for the DMA experiment. The powder is contained in metal pockets (Perkin Elmer part no: N533-0322) and the DMA is run in the single cantilever mode from 25° C. to 240° C. at a tamp rate of 2° C./min at a constant frequency of 1 Hz. This is a comparative test; different tests will give different numbers of the storage modulus of the same material.

TGA and DSC: Thermogravimetric analyzer (TGA): Thermogravimetric analyses of the various samples (about 10-15 mg) are done with Perkin Elmer (TGA 4000) with a heating rate of 10° C./min up to 800° C. in nitrogen environment. Differential scanning calorimeter (DSC): The sample, 6-10 mg, is analyzed 87 by increasing the temperature at a rate of 2° C./min in nitrogen environment.

SEM: The morphology of the nanocomposite is characterized using a FEI SEM under high vacuum mode and low acceleration voltage. The samples are sputter coated with Au or Carbon.

XRD: X-ray diffract grams of the neat polymer and the nanocoating applications or composite material are obtained on an X-ray diffractometer (PANalytical, XTertPro). The scan is conducted for duration of 30 minutes for the scan range of 7-70° 2θ.

Results and Discussion: The coating applications or composite material are expected to form immediately upon mixing. The resulting material is expected to be white, hard and different from MCC and PLA in physical appearance. The conditions used to prepare the acid/cellulose mixture, are chosen to open the cellulose structure and free nanocrystalline cellulose (NCC) whiskers and at the same time minimize hydrolysis of amorphous cellulose. Sulfuric acid concentration is 64%, which is the concentration reported (Revol, Godbout, Dong, Gray, Chanzy & Maret, 1994; Revol, Bradford, Giasson, Marchessault & Gray, 1992) to open the cellulose structure and at which NCC is extracted. After 30 minutes in 64% sulfuric acid, it is expected that cellulose amorphous part is dissolved and separated from NCC. PLA is expected to be soluble in THE and amorphous cellulose is expected to be soluble in sulfuric acid with the NCC dispersed therein. At the same time, upon mixing, the THF is expected to act as anti-solvent for dissolved cellulose. Dissolved cellulose, which exists together with the partially hydrolyzed cellulose, can be precipitated (regenerated) with the addition of an excess of a polar solvent (anti-solvent) like THF (for more information on dissolved cellulose precipitation. Acid mediated networked cellulose:

Preparation and characterization. Carbohydrate Polymers. PLA precipitates as well in the process. The co-precipitating cellulose is expected to enhance bonding between the NCC and the PLA matrix.

DMA, TGA and DSC: Dynamic Mechanical Analysis (DMA) data of the PLA nanocoating applications or composite material are generated with various loading levels of MCC, compared with neat PLA. It is expected to be seen that the storage modulus (E′) of all the blends are significantly improved over a wide range of temperature compared to that of the neat PLA. The storage modulus improvement is expected to be a function of cellulose content. The improvement for all the nanocomposites is expected to be most obvious below the glass transition temperature of PLA (50° C. to 60° C.). The modulus curve is expected to show a drop for all the samples around the glass transition temperature and is expected to flatten out at a much lower temperature for the neat PLA (at 80° C.), whereas for the nanocomposites they flatten out are expected to be at around 130 to 140° C.). The expected steady increase in the storage modulus of the composite, with MCC content is expected to be indicative of the fact that efficient dispersion and blending of cellulose in the PLA matrix is possible even at high loading levels.

Tan δ, also called damping, is a dimensionless property and is the ratio of loss to storage modulus. Tan δ curves for the various samples expected to show that the Tan δ peaks of the nanocomposites will increase in 130 magnitude (highest for NCC50) and shift towards a lower temperature as compared to the neat PLA. Mathew et al (Mathew Aji, Chakraborty, Oksman & Sain, 2006) also noticed this behavior of increase in magnitude of Tan δ peaks in their work with PLA nanocomposites through extrusion method.

The DSC thermograms of various samples are expected to show that the Tg of the nanocomposites are slightly shifted towards a lower temperature as compared to the neat PLA. This is in agreement with the Tan δ peaks shifting towards a slightly lower temperature as compared to the neat PLA. It is also expected to be evident from the thermograms that the introduction of the crystallinity into the otherwise almost completely amorphous PLA, which is indicated by the exothermic activity in the DSC traces for the nanocomposite.

TGA data is expected to reveals that all the nanocomposites have the onset of thermal degradation at a much lower temperature than neat PLA. However the nanocomposites are expected to be seen to be more resilient and have a residual weight of about 5% at 400° C. at which point the PLA is expected to lose all of its weight. The nanocomposites are expected to eventually completely lose their weight at around 750° C.

Nanocrystalline cellulose particles have a greater number of free end chains due to their smaller particles size, introduced as a result of the hydrolysis treatment. The end chains start decomposing at lower temperature (Staggs, 2006), consequently, causing an increase of the char yield of these hydrolyzed samples (Piskorz, Radlein, Scott & Czemik, 1989). Also sulfate groups, introduced during hydrolysis with sulfuric acid could possibly be acting as a flame retardant (Roman & Winter, 2004). It is expected to be observed from the d-TGA curves (derivative weight loss curves), that there is a shift towards the positive direction in terms of the temperature at which maximum weight loss occurs.

SEM images of the nanocomposites are expected to be observed that there is micro/nanoporosity introduced in the polymer matrix, which could be made possible by the solvent escaping/leaching through the matrix during the drying process. Micro/nanoporosity is an important attribute for a potential bio medical application in tissue engineering and scaffolds (Lee et al., 2005; Paul & Robeson, 2008; Traversa et al., 2008). The presence of micro and nanopores could serve as potential active site for cell growth, blood vessel invasion, nutrient and metabolic waste transport. It is worth mentioning here that NCC50 exhibited more pores and variations than NCC30.

Diffraction patterns of Neat PLA and the nanocoating applications, composite material (NCC50) expected to show that the predominantly amorphous PLA is characterized by a broad peak. The nanocomposite is expected to have sharp and intense peaks that are characteristic of crystalline PLA. Thus, the dissolved PLA in THF upon precipitation is expected to be more ordered. This can indicate that PLA precipitates in a slower rate than cellulose and it is possible that cellulose provide the backbone for PLA solidification.

### CONCLUSION

Nanocrystalline (NC) composition and products of the present subject matter, exemplified by polymer blends of poly (lactic acid) (PLA) and cellulose are prepared using a novel solvent mixing method, expecting to yield significant improvement in the mechanical and thermal stability of the generated material as nanocrystalline (NC) compositions and products of the present subject matter. The co-precipitating cellulose during the composite processing method is expected to have enhanced the bonding between the nanocrystalline cellulose (NCC) and PLA matrix. The storage modulus of the nanocomposites is expected to be increased as a function of the cellulose content, indicating good dispersion of cellulose during processing. The nanocomposites are expected to have porous morphology and enhanced crystallinity. The tunable nature of the nanocomposite, prepared using this method, makes it a suitable for various Nanocrystalline (NC) superlattice solar cells, as further described herein.

### REFERENCES (EACH ENTIRELY INCORPORATED HEREIN BY REFERENCE)

Bastioli, C. (2001). Global Status of the Production of Biobased Packaging Materials. Starch-Stärke, 189 53(8), 351-355.
Chazeau, L., Cavaille, J. Y., Canova, G., Dendievel, R., & Boutherin, B. (1999). Viscoelastic properties of plasticized PVC reinforced with cellulose whiskers. Journal of Applied Polymer Science, 71(11), 1797-1808.
Favier, V., Chanzy, H., & Cavaille, J. Y. (1995). Macromolecules, 28, 6365.
Hashaikeh R and Abushammala H. Acid mediated networked cellulose: 194 Preparation and characterization. Carbohydrate Polymers (2010), d. j. c.
Lee, Y. H., Lee, J. H., An, I.-G., Kim, C., Lee, D. S., Lee, Y. K., & Nam, J.-D. (2005). Electrospun dual-porosity structure and biodegradation morphology of Montmorillonite reinforced PLLA nanocomposite scaffolds. Biomatenials, 26(16), 3165-3172.
Lunt, J. (1998). Large-scale production, properties and commercial applications of polylactic acid polymers. Polymer Degradation and Stability, 59 (1-3), 145-152.
Mathew Aji, P., Chakrabortv, A., Oksman, K., & Sain, M. (2006). The Structure and Mechanical Properties of Cellulose Nanocomposites Prepared by Twin Screw Extrusion. Cellulose Nanocomposites (Vol. 938, pp., 114-131): American Chemical Society.
Mukheijee, S. M., & Woods, H. J. (1953). X-ray and electron microscope studies of the degradation of cellulose by sulphuric acid. Biochimica et Biophysica Acta, 10, 499-511.
Noishiki, Y., Nishiyama, Y., Wada, M., Kuga, S., & Magoshi, J. (2002). Mechanical properties of silk fibroin-microcrystalline cellulose composite films. Journal of Applied Polymer Science, 86(13), 3425-3429.
Paul, D. R., & Robeson, L. M. (2008). Polymer nanotechnology: Nanocomposites. Polymer, 49(15), 187-3204.
Piskorz, J., Radlein, D. S. A. G., Scott, D. S., & Czemik, S. (1989). Pretreatment of wood and cellulose for production of sugars by fast pyrolysis. Journal of Analytical and Applied Pyrolysis, 16(2), 127-142.
Qi, H., Cai, J., Zhang, L., & Kuga, S. (2009). Properties of Films Composed of Cellulose Nanowhiskers and a Cellulose Matrix Regenerated from Alkali/Urea Solution. Biomacromolecules, 10(6), 1597-1602.
Revol, J.-F. o., Godbout, L., Dong, X.-M., Gray, D, G., Chanzy, H., & Maret, G. (1994). Chiral nematic suspensions of cellulose crystallites; phase separation and magnetic field orientation. Liquid crystal solar cells, 16(1), 127-134.1
Revol, J. F., Bradford, H., Giasson, J., Marchessault, R. H., & Gray, D. G. (218 1992). Helicoidal self-ordering of cellulose microfibrils in aqueous suspension. International Journal of Biological Macromolecules, 14(3), 170-172.
Roman, M., & Winter William, T. (2006). Cellulose Nanocrystals for Thermoplastic Reinforcement: Effect of Filler Surface Chemistry on Composite Properties. Cellulose Nanocomposites (Vol. 938, pp. 99-113): American Chemical Society.
Roman, M., & Winter, W. T. (2004). Effect of Sulfate Groups from Sulfuric Acid Hydrolysis on the Thermal Degradation Behavior of Bacterial Cellulose. Biomacromolecules, 5(5), 1671-1677.
Sinha Ray, S., Yamada, K., Okamoto, M., Fujimoto, Y., Ogami, A., & Ueda, K. (2003). New polylactide/layered silicate nanocomposites. 5. Designing of materials with desired properties. Polymer, 44(21), 6633-6646.
Staggs, J. E. J. (2006). Discrete bond-weighted random scission of linear polymers. Polymer, 47(3), 897-906.
Tharanathan, R. N. (2003). Biodegradable films and composite nanocrystalline (NC) coating applications: past, present and future. Trends in Food Science & Technology, 14(3), 71-78.
Traversa, E., Mecheri, B., Mandoli, C., Soliman, S., Rinaldi, A., Licoccia, S., Forte, G., Pagliari, F.,
Pagliari, S., Carotenuto, F., Minieri, M, & Di Nardo, P. (2008). Tuning hierarchical architecture of 3D polymeric scaffolds for cardiac tissue engineering. Journal of Experimental Nanoscience, 3(2), 97-110.
Wu Q, L. X, Berglund L A. (2002). In: 23td Risø international symposium on materials science, sustainable natural and polymeric composites-science and technology.

### Example #5

The recent spread of high-frequency electronic and communication devices has led to a rise in the amount of electromagnetic (EM) waves, causing harmful effects on human body and other nearby devices to malfunction. As concern about the effect of EM wave grows, the devices are required to have electromagnetic compatibility (EMC). Fe-based nanocrystalline magnetic materials such as Finemet alloys have excellent soft magnetic properties including large saturation magnetization and high relative permeability in the high frequency range. One application of the Finemet type alloy is an EM wave absorber, which absorbs the generated EM waves to transform into thermal. FeSiBNbCu alloys exhibit excellent soft magnetic properties when nanocrystalline bcc-Fe(Si) phases that is formed by the crystallization annealing are embedded uniformly in the amorphous matrix. Numerous studies have been made on the effect of grain size of crystalline bcc-Fe(Si) phase on the magnetic properties of FeSiBNbCu alloy, in which the optimum magnetic properties can be acquired when the grain size is controlled to the range 10˜15 nm.

The objective of this study is to investigate the effect of the crystallization annealing conditions on the EM wave absorption behavior of a FeSiBNbCu alloy. The relative volume fractions of nanocrystals produced at various crystallization conditions are quantified using a differential scanning calorimeter (DSC) method 2. Experimental procedure Amorphous ribbons with a nominal composition of Fe73Si16B7Nb3Cu1 (at %) alloy are annealed at temperatures ranging from 500° C. to 650° C. for 1 hour under nitrogen atmosphere to investigate the crystallization behavior.

The DSC analysis is carried out using as-fabricated ribbons of 21 mg at temperatures ranging from 300° C. to 720° C. and heating rates ranging from 5 to 2° C./min. After annealing, the ribbons are pulverized and sieved to several classes of particles size. The powder with sizes of <45, 45˜53, and 53˜75 μm are mixed uniformly with the volume ratio of 1:2:7, respectively. Subsequently, the mixture is formed to 2.79 mm thick inductor cores of 6.35 mm outer diameter and 2.79 mm inner diameter under a pressure of 18 ton/cm2 without binder. The permeability is measured under the frequency range of 10˜1000 kHz. In order to identify the interrelations between the crystallization behavior and electromagnetic wave absorption of light, the ribbons are pulverized prior to crystallization annealing. Crystallization annealing is carried out at 500˜650° C. for 1 hour, followed by a tape-casting to produce a thin sheet of 0.5 mm thick after mixing with a binder. The EM wave absorption properties are measured by a two-port coaxial method using a network analyzer (Agilent Technologies, model N5260A). Results and discussion Crystallization behavior shows the variation of initial permeability of annealed FeSiBNbCu alloy on annealing temperature. The initial permeability increased to 540° C. and decreased thereafter. It has been reported that the magnetic properties of FeSiBNbCu alloy are significantly dependent on the grain size of bccFe(Si) phase. Optimized magnetic properties can be acquired when the grain size is controlled to the range of 10-15 nm using annealing temperatures in the range of 500˜600° C.

### Example #6

Fe-based nanocrystalline powder sheets with dielectric TiO₂ powder additives are provided to improve the characteristics of electromagnetic (EM) wave absorption. The amorphous ribbons of Fe₇₃Si₁₆B₇Nb₃Cu₁ (at. %) alloys are prepared by a planar flow casting (PFC) process, and the ribbons are pulverized using an attrition mill. Fe-based flake powder crystallized at 550° C. for 1 h is mixed with a nano-sized and a micro-sized TiO₂ powder. The powder mixtures are then tape-cast with binders to become EM wave-absorbing sheets. The absorbing properties of the fabricated sheet sample, such as complex permittivity and permeability, are measured by a network analyzer. The properties of EM wave absorption of light improved with the increase of TiO₂ powder as micro- or nano-sized powder in the mixture. The mixture with micro-sized TiO₂ powder is slightly more effective in causing power loss of EM waves than the mixture with nano-sized TiO₂ powder.

### Example #7

Nanocrystalline soft magnetic Fe₇₃Si₁₆B₇Nb₃Cu₁ (at. %) powders are mixed with fine multi-walled carbon nanotube (MWNT) powders and polyurethane based binders. The mixtures are tape-cast, dried and then cold-rolled to form EM wave absorption sheets. The MWNT powders are added to the Fe-based powders up to 1 wt. % to improve the EM wave absorption properties. The processed sheets with 0.5 mm in thickness are cut intoroidal shape to measure the S-parameter, permeability, permittivity, and power loss at the high frequency of 10 MHz to 10 GHz.

As a result, improved absorption properties are obtained from the sheets incorporating MWNT. The results are caused by the increase of dielectric loss of the absorption sheets, which is due to the addition of MWNT powder inducing a notable increase in complex permittivity.

### Example #8

The amorphous (at %) alloy strip is pulverized using a jet mill and an attrition mill to get flake-shaped powder. The flake powder is mixed with dielectric powder and its dispersant to increase the permittivity. The powders covered with dielectric powders and its dispersant are mixed with a binder and a solvent and then tape-cast to form sheets. The absorbing properties of the sheets are measured to investigate the roles of the dielectric powder and its dispersant. The results showed that the addition of powders and its dispersant improved the absorbing properties of the sheets noticeably. The powder sheet mixed with 5 wt % of powder and 1 wt % of dispersant showed the best electromagnetic wave absorption rate because of the increase of the permittivity and the electrical resistance.

The foregoing is illustrative of the present subject matter, and is not to be construed as limiting thereof. The present subject matter is defined by the following claims, with equivalents of the claims to be included therein.

1. A method for producing nanocrystalline solar energy devices to provide high efficiency solar energy comprising:
(a) combining at least two nanocrystalline (NC) components with at least one substrate to provide an NCC substrate composition,
wherein said NC component comprises at least one type of nanocrystalline cellulose (NCC),
wherein one or more of said NC components is provided in at least a partially dry form; and
wherein said NCC substrate composition comprises:
(i) an NCC core structure as a central component comprising at least one of said NC component and optionally at least a portion of said substrate; and
(ii) at least one branched polymer comprising:
(A) at least one first polymer chain extending from said NCC core and comprising at least one of said at least two NC components; and
(B) at least one second polymer chain diverting away from the first polymer chain and comprising at least one of said at least two NC components;
(b) processing the NCC substrate composition using at least one of vapor processing, solid state processing, liquid processing, spray pyrolysis, electrochemical deposition, gas phase deposition, and laser processing,
to provide a processed NCC substrate composition;
(c) combining the processed NCC substratecomposition with at least two nanoparticle-based materials to form an NCC substrate product that is configured to process visible and/or UV light wavelengths for generation of an electrical current when incorporated into one or more of said solar energy devices,
wherein the at least two nanoparticle-based materials are selected from at least two of the following nanocrystalline based materials:
metal, non-metal, plastic, polymer, multiscale structure, thin film, ceramic, coating, perovskite, photovoltaic, photothermal or photoelectrochemical solar material, solar crystal, metal hydride, amorphous metal, silicon, polycrystalline, copper indium diselenide, cadmium telluride, gallium arsenide, gallium phosphide, carbon solar cells, perovskite solar cells, copper alloy, cobalt alloy, silver alloy, aluminum, steel, kevlar, cast iron, tungsten, chromium, titanium, indium, gallium and nitrogen, or an alloy thereof; and
wherein crystal structures of the components of the solar energy devices are selected from one or more layers to the nanocrystalline solar cell comprising of solid, liquid, and amorphous.

2. A method according to claim 1, wherein the method further comprises adding to the nanocrystalline (NC) composition at least one of a nanocrystalline (NC) plastic, polymers or nanostructure; a plastic, a form or alloy of metal, a form or alloy of nanocrystalline copper, nanocrystalline aluminum, nanocrystalline steel, kevlar, cast iron, tungsten, chromium, titanium, a fiber, or a composite, wherein the adding results in at least a 10% increase in at least one the tensile strength or hardness of the resulting nanocrystalline (NC) product material.

3. A method according to claim 1, wherein the at least one first polymer chain or the at least one second polymer chain comprises or further comprises one or more monomers selected from the groups consisting of:
vinyl acetate, acrylic acid, sodium acrylate, ammonium acrylate, methyl acrylate, acrylamide, acrylonitrile, N,N-dimethyl acrylamide, 2-acrylamido-2-methylpropane-1-sulfonic acid, sodium 2-acrylamido-2-methylpropane-1-sulfonate, 3-acrylamidopropyl-trimethyl-ammonium chloride, diallyldimethylammonium chloride, 2-(dimethylamino)ethyl acrylate, 2-(acryloyloxy)-N,N,N-trimethylethanaminium chloride, N,N-dimethylaminoethyl acrylate benzyl chloride quaternary salt, 2-(acryloyloxy)-N,N,N-trimethylethanaminium methyl sulfate, 2-(dimethylamino)ethyl methacrylate, 2-(methacryloyloxy)-N,N,N-trimethylethanaminium chloride, 3-(dimethylamino)propyl methacrylamide, 2-(methacryloyloxy)-N,N,N-trimethylethanaminium methyl sulfate, methacrylic acid, methacrylic anhydride, methyl methacrylate, methacryloyloxy ethyl trimethyl ammonium chloride, 3-methacrylamidopropyl-trimethyl-ammonium chloride, hexadecyl methacrylate, octadecyl methacrylate, docosyl acrylate, n-vinyl pyrrolidone, 2-vinyl pyridine, 4-vinyl pyridine, epichlorohydrin, n-vinyl formamide, n-vinyl acetamide, 2-hydroxyethyl acrylate glycidyl methacrylate, 3-(allyloxy)-2-hydroxypropane-1-sulfonate, 2-(allyloxy)ethanol, ethylene oxide, propylene oxide, 2,3-epoxypropyltrimethylammonium chloride, (3-glycidoxypropyl)trimethoxy silane, epichlorohydrin-dimethylamine, vinyl sulfonic acid sodium salt, sodium 4-styrene sulfonate, caprolactam and any combination thereof;
non-ionic, water-soluble monomers selected from one or more of: acrylamide, methacrylamide, N,N-dimethylacrylamide, N,N-diethylacrylamide, N-isopropylacrylamide, N-vinylformamide, N-vinylmethylacetamide, N-vinyl pyrrolidone, 2-vinyl pyridine, 4-vinyl pyridine, epichlorohydrin, acrylonitrile, hydroxyethyl methacrylate, hydroxyethyl acrylate, hydroxypropyl acrylate, hydroxypropyl methacrylate, hexadecyl methacrylate, octadecyl methacrylate, glycidyl methacrylate, 3-(glycidoxypropyl)trimethoxy silane, 2-allyloxy ethanol, docosyl acrylate, N-t-butylacrylamide, N-methylolacrylamide, epichlorohydrin-dimethylamine, caprolactam, and any combination thereof;
anionic monomers selected from one or more of acrylic acid; methacrylic acid, 2-acrylamido-2-methylpropanesulfonic acid (AMPS), sodium vinyl sulfonate, styrene sulfonate, maleic anhydride, maleic acid, sulfonate itaconate, sulfopropyl acrylate, polymerisable carboxylic or sulphonic acids, crotonic acid, sulfomethylated acrylamide, allylsulfonate, sodium vinyl sulfonate, itaconic acid, acrylamidomethyl butanoic acid, fumaric acid, vinylphosphonic acid, vinylsulfonic acid, vinylsulfonic acid sodium salt, allylphosphonic acid, 3-(allyloxy)-2-hydroxypropane sulfonate, sulfomethyalted acryamide, phosphono-methylated acrylamide, ethylene oxide, propylene oxide, and any salts or combinations thereof; and
cationic monomers selected from one or more of dialkylaminoalkyl acrylates, methacrylates and their quaternary or acid salts.

4. A method according to claim 3, wherein at least one second branch of the first polymer chain comprises a different selection of monomers than the at least one first branch of the at least one first polymer chain, the different selection being different in at least one selected from monomer type or monomer ratio.

5. A method according to claim 1, wherein;
the combining step (a) comprises blending the nanocrystalline cellulose (NCC) with a polymer to provide a blend, and adding the blend to the substrate and wherein the at least one nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, comprises nanocrystalline (NC) crystallites have a diameter of about 5-10 nm; and
the at least one nanocrystalline cellulose (NCC) is combined in step (a) at the wet end and/or in the dry end of the combining.

6. (canceled)

7. A method according to claim 1, wherein the nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and nanocrystalline (NC) polymers structures:
are added in the combining step (a) as: (i) a coating outside of the substrate, component, or additive; or (ii) dispersed within the substrate; and
comprise one or more of linear, branched, or cyclic polymers extending from the nanocrystalline cellulose (NCC) core or a nanocrystalline cellulose (NCC) graft polymer.

8. (canceled)

9. A method according to claim 1, wherein the nanocrystalline cellulose (NCC) is selected from one or more of naturally occurring crystals obtained by separating the crystalline cellulose regions from the amorphous cellulose regions of a plant fiber.

10. A method according to claim 5, wherein the nanocrystalline (NC) crystallites are about 100-500 nm in length and comprise between 85% and 97% of the nanocrystalline cellulose (NCC).

11. A method according to claim 1, wherein the combining step (a) comprises:
providing an aqueous mixture comprising partially hydrolyzed forms of at least two of the nanocrystalline cellulose (NCC), nanocrystalline (NC) materials, nanocrystalline (NC) carbon, nanocrystalline (NC) carbon nanotubes, nanocrystalline (NC) layers, nanocrystalline (NC) metals and alloys, nanocrystalline (NC) polymers and/or nanocrystalline (NC) polymers structures, in a dissolution media;
providing a solution comprising the substrate in a polar organic solvent;
combining the mixture with the solution to form a precipitate; and
washing the precipitate with water to remove solvent and dissolution media and to produce a wet composite of the NCC substrate composition; and
drying the wet composite to produce a dry composite as the nanocrystalline cellulose (NCC) substrate composition.

12. A method according to claim 11, wherein the washing step is carried out continuously or as a batch process selected from one or more of mixing and separating; washing of a cake of the NCC composition; dialysis; or combinations thereof.

13. A method according to claim 11, wherein the washing step is carried out until the wet composite has a pH between 6 and 7.

14. A method according to claim 11, wherein the drying step is carried out at one or more selected from room temperature, heating, cooling; atmospheric pressure, and reduced pressure.

15. A method according to claim 11, wherein the dry composite produced is rigid and has (i) a storage modulus of between 1-5 and 20-35 gigapascals, at a temperature of 20 degrees C., or (ii) a storage modulus between 0.1-1 gigapascals and 10-20 gigapascals, at a temperature of 100 degrees Centigrade.

16. A method according to claim 11, wherein the dry composite is porous and has a density of 0.01 to 10 grams per cubic centimeter and a residual weight of about 1-20% at a temperature of 400 degrees C.

17. A method according to claim 2, wherein the alloy or metal is selected from iron, silicon germanium alloy or titanium based nanocrystalline magnetic materials that absorb or reflect electromagnetic energy in the range of 10 to 100 kHz that are provided with crystal diameters in the range of 10-15 nm.

18. A method according to claim 16, wherein the iron or titanium based nanocrystalline magnetic material is selected from a FeSiBNbCu alloy, dialectric TiO2 powder, or BaTiO3 powder.

19. A method according to claim 1, wherein said nanocrystalline (NC) product is selected from one or more of thin films, coatings, solar panels, solar glass panels, solar cells, solar glass, transparent solar panels, solar windows, solar tiles, doubled-sided solar panels, solar powered cars, solar powered lights, solar automotive paint, solar paint products, solar paint additives, liquid solar cells, printable liquid solar cells, spray-on solar cells, liquid crystal solar cells, solar fuel, solar powered fuel cells, solar powered gadgets, solar powered roof tiles, solar powered shingles, solar powered roadways, solar films, dye-sensitized solar cells, solar energy batteries, solar energy consumer products, solar powered products for the home, solar energy storage systems, solar products or solar energy devices.

20. A method according to claim 1, wherein the substrate is selected from one or more of materials comprising one or more of: silicon, carbon fiber, carbon nanofibers, fluorocarbons, filaments, carbon nanotubes, SiO2, silicon-germanium, tungsten, silicon carbide, silicon nitride, silicon oxynitride, titanium nitride, gallium arsenide (GaAs), graphene, glass, plastic or metal, steel, aluminum, copper, graphite, and various high-k dielectrics, and/or in the form or, or including, paper, plastic, a polymer, a liquid polymer, a liquid crystal polymer, a composite gel polymer, a copolymer, fabric, film, foil, sheet stock, a web, and/or a sheet.

21. A solar energy device comprising at least one nanocrystalline (NC) product made according to a method of claim 1.

22. A solar energy device comprising nanocrystalline (NC) solar cells, the solar energy device comprising an NC cellulose (NCC) substrate product configured to process visible and/or UV light wavelengths for generation of an electrical current when incorporated into one or more of said solar energy devices,
the NCC substrate product comprising:
(i) at least one processed NCC substrate composition combined with:
(ii) at least two nanoparticle-based materials selected from at least two of the following nanocrystalline based materials metal, non-metal, plastic, polymer, multiscale structure, thin film, ceramic, coating, perovskite, photovoltaic, photothermal or photoelectrochemical solar material, solar crystal, metal hydride, amorphous metal, silicon, polycrystalline, copper indium diselenide, cadmium telluride, gallium arsenide, gallium phosphide, carbon solar cells, perovskite solar cells, copper alloy, cobalt alloy, silver alloy, aluminum, steel, kevlar, cast iron, tungsten, chromium, titanium, indium, gallium and nitrogen, or an alloy thereof:
wherein the processed NCC substrate composition comprises:
(i) at least two nanocrystalline (NC) components combined with at least one substrate, wherein said NC component comprises at least one type of nanocrystalline cellulose (NCC), wherein one or more of said NC components is in at least a partially dry form;
(ii) an NCC core structure as a central component comprising at least one of said NC component and optionally at least a portion of said substrate; and
(iii) at least one branched polymer comprising: (A) at least one first polymer chain extending from said NCC core and comprising at least one of said at least two NC components; and (B) at least one second polymer chain diverting away from the first polymer chain and comprising at least one of said at least two NC components;
wherein the processed NCC substrate composition includes NCC substrate processed using at least one of vapor processing, solid state processing, liquid processing, spray pyrolysis, electrochemical deposition, gas phase deposition, and laser processing; and
wherein crystal structures of the components of the solar energy devices are selected from one or more layers to the nanocrystalline solar cell comprising of solid, liquid, and amorphous.
